(19) United States
(12) Patent Application Publication
(10) Pub. No.: US 2011/0269071 A1
(43) Pub. Date: Nov. 3, 2011

(54) ACTINIC RAY-SENSITIVE OR RADIATION-SENSITIVE RESIN COMPOSITION, CHEMICAL AMPLIFICATION RESIST COMPOSITION, AND RESIST FILM AND PATTERN FORMING METHOD USING THE COMPOSITION

(75) Inventors: Toru FUJIMORI, Shizuoka (JP); Shinki Yamada, Shizuoka (JP); Takamitsu Tomiga, Shizuoka (JP)

(73) Assignee: FUJIFILM Corporation, Tokyo (JP)

(21) Appl. No.: 13/095,023

(22) Filed: Apr. 27, 2011

(30) Foreign Application Priority Data
Apr. 28, 2010 (JP) 2010-104567
Jun. 17, 2010 (JP) 2010-138513
Jun. 17, 2010 (JP) 2010-138514

(51) Int. Cl. G03F 7/004; G03F 7/20

(52) U.S. Cl. 430/270.1; 430/325

(57) ABSTRACT

An actinic ray-sensitive or radiation-sensitive resin composition of the first invention includes (A1) an acid-decomposable resin, the resin containing three kinds of repeating units each having a specific structure, (B) a photo-acid generator and (C1) a 2-phenylbenzimidazole-based basic compound; an actinic ray-sensitive or radiation-sensitive resin composition of the second invention includes (A2) an acid-decomposable resin, (B) a photo-acid generator and (C2) 2-heteryl benzimidazole-based basic compound; a chemical amplification resist composition of the third invention includes (A3) an acid-decomposable resin, (B) a photo-acid generator and (C3) a benzimidazole-based basic compound having a sulfur atom-containing specific structure; and a resist film and a pattern forming method each use such a composition.

### BACKGROUND OF THE INVENTION

1. Field of the Invention

Each of the first invention and the second invention of the present invention relates to an actinic ray-sensitive or radiation-sensitive resin composition, particularly, an actinic ray-sensitive or radiation-sensitive resin composition suitably usable for the production of a semiconductor integrated circuit device, an integrated circuit production mask, a printed wiring board, a liquid crystal panel and the like, and a resist film and a pattern forming method each using the composition.

The third invention of the present invention relates to a chemical amplification resist composition, particularly, a chemical amplification resist composition suitably usable for the production of a semiconductor integrated circuit device, an integrated circuit production mask, a printed wiring board, a liquid crystal panel and the like, and a resist film and a pattern forming method each using the composition.

2. Description of the Related Art

An early chemical amplification positive resist composition composed of a photo-acid generator and an acid-decomposable group-containing resin is disclosed, for example, in U.S. Pat. No. 4,491,628. This chemical amplification positive resist composition is a pattern forming material of forming a pattern on a substrate by producing an acid in the exposed area upon irradiation with radiation such as far ultraviolet light and through a reaction using the acid as a catalyst, changing the developer solubility of the area irradiated with actinic radiation and that of the non-irradiated area.

Various positive resist compositions containing a resin having an acid-decomposable group have been heretofore known, and for example, JP-A-5-249682 (the term “JP-A” as used herein means an “unexamined published Japanese patent application”) discloses a resist composition using a polyhydroxystyrene resin protected by an alkoxy (acetal) group, JP-A-9-211866 discloses a resist composition using a polyhydroxystyrene resin having two different acid-decomposable groups, and Japanese Patent No. 3,147,268 discloses a resist composition using a resin containing a hydroxystyrene-derived repeating unit and an acid-decomposable group-containing (meth)acrylic repeating unit.

Also, JP-A-2009-244829 discloses a resin further containing a repeating unit such as benzyl methacrylate, in addition to the repeating units disclosed in Japanese Patent No. 3,147,268, and it is stated that by virtue of using a resin containing such a repeating unit, a resist composition reduced in the defect after development and excellent in the plasma etching resistance can be provided.

In addition, Japanese Patent No. 3,948,128 discloses a radiation-sensitive composition essentially containing a combination of a resin having a specific repeating unit and a photo-acid generator having a specific structure, where a nitrogen-containing organic compound is set forth as one of arbitrary additives to the composition. Also, a nitrogen-containing heterocyclic compound is described as one type of the nitrogen-containing organic compound, and 2-phenylbenzimidazole is illustrated as one of specific examples thereof.

However, at the formation of particularly a contact hole pattern, these positive resist compositions disclosed give a pattern lacking in the profile verticality and cannot ensure a sufficient exposure-defocus window (EDW; a window margin showing exposure latitude (EL) and focus latitude (DOF)). At the same time, many blob defects are generated, the coatability of the resist composition is poor, or the coating suitability when using the composition in a small amount is bad, and improvements thereof are demanded. In addition, the sidelobe resistance is insufficient, and improvement thereof is demanded. Furthermore, the change with the passage of time, such as increase of particles in the resist solution after aging and storage is a problem, and more improvement of the aging stability is demanded. Incidentally, an optical latent image directly affects the formation of a contact hole pattern and since the exposure dose at the lower part of the pattern is small, the pattern formed is fundamentally tapered. In particular, it is very difficult to form a rectangular profile in a fine resolution region or a defocused region.

### SUMMARY OF THE INVENTION

An object of each of the first invention and the second invention of the present invention is to provide an actinic ray-sensitive or radiation-sensitive resin composition capable of solving the problems in those conventional techniques, particularly, provide an actinic ray-sensitive or radiation-sensitive resin composition ensuring that at the formation of a contact hole pattern, resolution giving a vertical side wall is achieved, a wide EDW is obtained, the sidelobe resistance is improved, and the number of blob defects is reduced. Another object of each of the first invention and the second invention of the present invention is to provide an actinic ray-sensitive or radiation-sensitive resin composition improved in the coatability by appropriately selecting the solvent in the composition. Still another object of the first invention and the second invention of the present invention is to provide a resist film and a pattern forming method each using the composition.

An object of the third invention of the present invention is to provide a chemical amplification resist composition capable of solving the problems in those conventional techniques, particularly, provide a chemical amplification resist composition ensuring that at the formation of a contact hole pattern, resolution giving a vertical side wall is achieved, a wide EDW is obtained, the sidelobe resistance is improved, and the increase of particles after aging and storage is remarkably reduced. Another object of the third invention of the present invention is to provide a chemical amplification resist composition improved in the coatability by appropriately selecting the solvent in the composition. Still another object of the third invention of the present invention is to provide a resist film and a pattern forming method each using the composition.

The present inventors have found that when a resin containing repeating units represented by formulae (1-I) to (1-III) shown later and a basic compound represented by formula (1-IV) shown later are used in an actinic ray-sensitive or radiation-sensitive resin composition, the object of the first invention can be attained.

The present inventors have found that when a basic compound represented by formula (2-IV) shown later is used in an actinic ray-sensitive or radiation-sensitive resin composition, the object of the second invention can be attained.

The present inventors have found that when a basic compound represented by formula (3-IV) shown later is used in a chemical amplification resist composition, the object of the third invention can be attained.

The first invention of the present invention is as follows.

[1-1] An actinic ray-sensitive or radiation-sensitive resin composition, comprising:

(A1) a resin capable of increasing a solubility of the resin (A1) for an alkali developer by an action of an acid, the resin containing a repeating unit represented by the following formula (1-I), a repeating unit represented by the following formula (1-II) and a repeating unit represented by the following formula (1-III);

(B) a compound capable of generating an acid upon irradiation with an actinic ray or radiation; and

(C1) a basic compound represented by the following formula (1-IV):

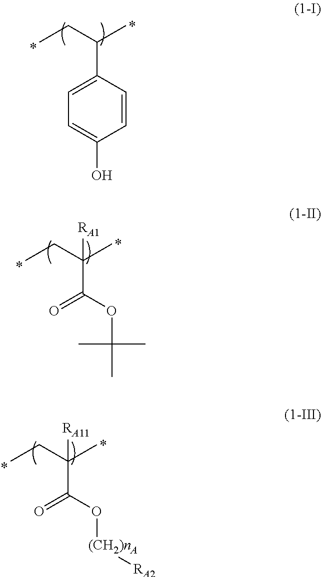

wherein each of R_{A1} and R_{A11} independently represents a hydrogen atom or a methyl group;

R_{A2} represents a phenyl group or a cyclohexyl group; and

n_{A} represents an integer of 0 to 2:

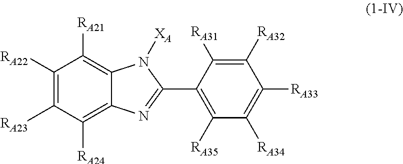

wherein each of R_{A21}, R_{A22}, R_{A23}, R_{A24}, R_{A31}, R_{A32}, R_{A33}, R_{A34} and R_{A35} independently represents a hydrogen atom, an alkyl group, an alkoxy group or an aralkyl group; and

X_{A} represents a hydrogen atom, an alkyl group, an aryl group or an aralkyl group.

[1-2] The actinic ray-sensitive or radiation-sensitive resin composition as described in [1-1] above,

wherein the contents of the repeating unit represented by formula (1-I), the repeating unit represented by formula (1-II) and the repeating unit represented by formula (1-III) in the resin (A1) are from 30 to 80 mol %, from 15 to 50 mol % and from 5 to 20 mol %, respectively, based on all repeating units in the resin (A1) and a total content of the repeating units represented by formulae (1-I) to (1-III) in the resin (A1) is 100 mol % based on all repeating units in the resin (A1).

[1-3] The actinic ray-sensitive or radiation-sensitive resin composition as described in [1-1] or [1-2] above, further comprising:

(G) a sugar derivative capable of decomposing by an action of an acid to generate an alcoholic hydroxyl group.

[1-4] The actinic ray-sensitive or radiation-sensitive resin composition as described in any one of [1-1] to [1-3] above,

wherein in formula (1-IV), X_{A} is a hydrogen atom.

[1-5] The actinic ray-sensitive or radiation-sensitive resin composition as described in any one of [1-1] to [1-4] above,

wherein in formula (1-IV), each of R_{A21}, R_{A22}, R_{A23}, R_{A24}, R_{A31}, R_{A32}, R_{A33}, R_{A34} and R_{A35} independently represents a hydrogen atom or an alkyl group.

[1-6] The actinic ray-sensitive or radiation-sensitive resin composition as described in any one of [1-1] to [1-5] above, further comprising:

a mixed solvent of an alkylene glycol monoalkyl ether carboxylate and an alkyl alkoxy carboxylate.

[1-7] The actinic ray-sensitive or radiation-sensitive resin composition as described in [1-6] above,

wherein the mixed solvent is a mixed solvent of a propylene glycol monoalkyl ether carboxylate and an alkyl alkoxy propionate.

[1-8] The actinic ray-sensitive or radiation-sensitive resin composition as described in any one of [1-1] to [1-7] above, which is used for exposure to KrF excimer laser, electron beam, X-ray or extremely-ultraviolet ray.

[1-9] A resist film, which is formed of the actinic ray-sensitive or radiation-sensitive resin composition as described in any one of [1-1] to [1-8] above.

[1-10] A pattern forming method, comprising:

exposing and developing the resist film as described in [1-9] above.

The first invention of the present invention preferably further includes the following configurations.

[1-11] The actinic ray-sensitive or radiation-sensitive resin composition as described in any one of [1-1] to [1-8] above,

wherein in formula (1-III), n_{A} is 1.

[1-12] The actinic ray-sensitive or radiation-sensitive resin composition as described in any one of [1-1] to [1-8] and [1-11] above,

wherein in formula (1-III), R_{A2} is a phenyl group.

[1-13] The actinic ray-sensitive or radiation-sensitive resin composition as described in any one of [1-3] to [1-8], [1-11] and [1-12] above,

wherein the sugar derivative (G) is a compound having, in the molecule, three or more groups selected from the group consisting of a hydroxyl group and a group capable of decomposing by an action of an acid to generate an alcoholic hydroxyl group and at least one of these groups is a group capable of decomposing by an action of an acid to generate an alcoholic hydroxyl group.

[1-14] The actinic ray-sensitive or radiation-sensitive resin composition as described in any one of [1-6] to [1-8] and [1-11] to [1-13] above,

wherein the mixed solvent is a mixed solvent of propylene glycol monomethyl ether acetate and ethyl 3-ethoxypropionate.

[1-15] The actinic ray-sensitive or radiation-sensitive resin composition as described in any one of [1-6] to [1-8] and [1-11] to [1-14] above,

wherein a mixing ratio of an alkylene glycol monoalkyl ether carboxylate and an alkyl alkoxy carboxylate in the mixed solvent is from 50:50 to 90:10 in terms of a mass ratio.

The second invention of the present invention is as follows.

[2-1] An actinic ray-sensitive or radiation-sensitive resin composition, comprising:

(A2) a resin capable of increasing a solubility of the resin (A2) for an alkali developer by an action of an acid;

(B) a compound capable of generating an acid upon irradiation with an actinic ray or radiation; and

(C2) a basic compound represented by the following formula (2-IV):

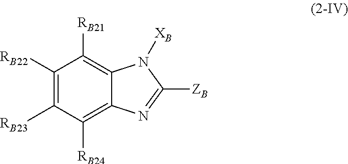

wherein each of R_{B21}, R_{B22}, R_{B23} and R_{B24} independently represents a hydrogen atom, an alkyl group, an alkoxy group or an aralkyl group;

X_{B} represents a hydrogen atom, an alkyl group or an aryl group; and

Z_{B} represents a heterocyclic group.

[2-2] The actinic ray-sensitive or radiation-sensitive resin composition as described in [2-1] above,

wherein the resin (A2) contains a repeating unit stable to an acid, represented by the following formula (V):

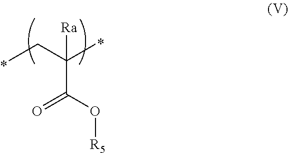

wherein R₅ represents a non-acid-decomposable hydrocarbon group; and

Ra represents a hydrogen atom, an alkyl group or a —CH₂—O—Ra₂ group, wherein Ra₂ represents a hydrogen atom or an alkyl group.

[2-3] The actinic ray-sensitive or radiation-sensitive resin composition as described in [2-1] or [2-2] above,

wherein the resin (A2) contains a repeating unit represented by the following formula (2-I), a repeating unit represented by the following formula (2-II) and a repeating unit represented by the following formula (2-III):

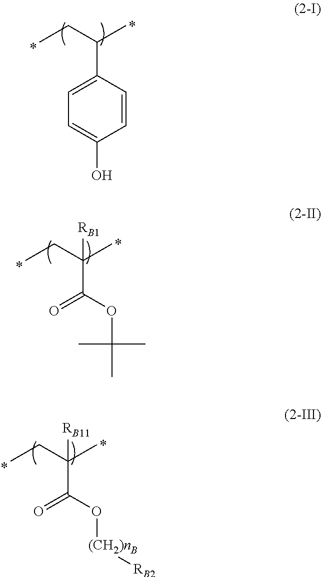

wherein each of R_{B1} and R_{B11} independently represents a hydrogen atom or a methyl group which may have a substituent;

R_{B2} represents a phenyl group which may have a substituent, or a cyclohexyl group which may have a substituent; and

n_{B} represents an integer of 0 to 2.

[2-4] The actinic ray-sensitive or radiation-sensitive resin composition as described in [2-3] above,

wherein the contents of the repeating unit represented by formula (2-I), the repeating unit represented by formula (2-II) and the repeating unit represented by formula (2-III) are from 45 to 80 mol %, from 15 to 50 mol % and from 5 to 20 mol %, respectively, based on all repeating units in the resin (A2).

[2-5] The actinic ray-sensitive or radiation-sensitive resin composition as described in any one of [2-1] to [2-4] above,

wherein the heterocyclic group represented by Z_{B} in formula (2-IV) is a 5- or 6-membered nitrogen-containing heterocyclic ring.

[2-6] The actinic ray-sensitive or radiation-sensitive resin composition as described in any one of [2-1] to [2-5] above, further comprising:

(G) a sugar derivative capable of decomposing by an action of an acid to generate an alcoholic hydroxyl group.

[2-7] The actinic ray-sensitive or radiation-sensitive resin composition as described in any one of [2-1] to [2-6] above, further comprising:

a mixed solvent of an alkylene glycol monoalkyl ether carboxylate and an alkyl alkoxy carboxylate.

[2-8] The actinic ray-sensitive or radiation-sensitive resin composition as described in any one of [2-1] to [2-7] above, which is used for exposure to KrF excimer laser light, electron beam, X-ray or high-energy ray at a wavelength of 50 nm or less.

[2-9] A resist film, which is formed using the actinic ray-sensitive or radiation-sensitive resin composition as described in any one of [2-1] to [2-8] above.

[2-10] A pattern forming method, comprising:

exposing the resist film as described in [2-9] above, so as to form an exposed film; and developing the exposed film.

The second invention of the present invention preferably further includes the following configurations.

[2-11] The actinic ray-sensitive or radiation-sensitive resin composition as described in any one of [2-1] to [2-8] above,

wherein in formula (2-IV), X_{B} is a hydrogen atom or an alkyl group.

[2-12] The actinic ray-sensitive or radiation-sensitive resin composition as described in any one of [2-1] to [2-8] and [2-11] above,

wherein a content of the basic compound represented by formula (2-IV) is from 0.001 to 10 mass % based on a solid content of the composition.

[2-13] The actinic ray-sensitive or radiation-sensitive resin composition as described in any one of [2-2] to [2-8], [2-11] and [2-12] above,

wherein in formula (V), R₅ has a cycloalkyl group, a cycloalkenyl group, an aryl group or an aralkyl group.

[2-14] The actinic ray-sensitive or radiation-sensitive resin composition as described in any one of [2-6] to [2-9] and [2-11] to [2-13] above,

wherein the sugar derivative is a cyclic sugar derivative.

[2-15] The actinic ray-sensitive or radiation-sensitive resin composition as described in any one of [2-7] to [2-9] and [2-11] to [2-14] above,

wherein a mixing ratio (by mass) of an alkylene glycol monoalkyl ether carboxylate and an alkyl alkoxy carboxylate is from 50:50 to 90:10.

The third invention of the present invention is as follows.

[3-1] A chemical amplification resist composition, comprising:

(A3) a resin capable of increasing a solubility of the resin (A3) for an alkali developer by an action of an acid;

(B) a compound capable of generating an acid upon irradiation with an actinic ray or radiation; and

(C3) a basic compound represented by the following formula (3-IV):

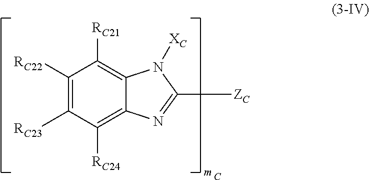

wherein each of R_{C21}, R_{C22}, R_{C23} and R_{C24} independently represents a hydrogen atom, an alkyl group, a cycloalkyl group, an alkoxy group or an aralkyl group, and when a plurality of R_{C21}'s, R_{C22}'s, R_{C23}'s or R_{C24}'s are present, each R_{C21}, R_{C22}, R_{C23} or R_{C24} may be the same as or different from every other R_{C21}, R_{C22}, R_{C23} or R_{C24};

X_{C} represents a hydrogen atom, an alkyl group, an aryl group or an aralkyl group, and when a plurality of X_{C}'s are present, each X_{C} may be the same as or different from every other X_{C};

m_{C} represents 1 or 2; and

Z_{C} represents a mercapto group when m_{C} is 1, and represents a sulfide group or a disulfide group when m_{C} is 2.

[3-2] The chemical amplification resist composition as described in [3-1] above,

wherein the resin (A3) contains a repeating unit stable to an acid, represented by the following formula (V):

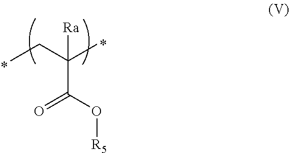

wherein R₅ represents a non-acid-decomposable hydrocarbon group;

Ra represents a hydrogen atom, an alkyl group or a —CH₂—O—Ra₂ group; and

Ra₂ represents a hydrogen atom or an alkyl group.

[3-3] The chemical amplification resist composition as described in [3-1] or [3-2] above,

wherein the resin (A3) contains a repeating unit represented by the following formula (3-I), a repeating unit represented by the following formula (3-II) and a repeating unit represented by the following formula (3-III):

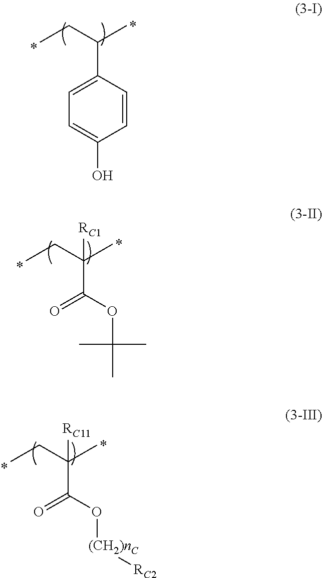

wherein each of R_{C1} and R_{C11} independently represents a hydrogen atom or a methyl group which may have a substituent;

R_{C2} represents a phenyl group which may have a substituent, or a cyclohexyl group which may have a substituent; and

n_{C} represents an integer of 0 to 2.

[3-4] The chemical amplification resist composition as described in [3-3] above,

wherein the contents of the repeating unit represented by formula (3-I), the repeating unit represented by formula (3-II) and the repeating unit represented by formula (3-III) in the resin (A3) are from 45 to 80 mol %, from 15 to 50 mol % and from 5 to 20 mol %, respectively, based on all repeating units in the resin (A3).

[3-5] The chemical amplification resist composition as described in any one of [3-1] to [3-4] above, further comprising:

(G) a sugar derivative capable of decomposing by an action of an acid to generate an alcoholic hydroxyl group.

[3-6] The chemical amplification resist composition as described in any one of [3-1] to [3-5] above,

wherein in formula (3-IV), X_{C} represents a hydrogen atom, an alkyl group or an aryl group.

[3-7] The chemical amplification resist composition as described in any one of [3-1] to [3-6] above,

wherein in formula (3-IV), each of R_{C21}, R_{C22}, R_{C23} and R_{C24} is a hydrogen atom.

[3-8] The chemical amplification resist composition as described in any one of [3-3] to [3-7] above,

wherein a total content of the repeating units represented by formulae (3-I) to (3-III) in the resin (A3) is 100 mol % based on all repeating units in the resin (A3).

[3-9] The chemical amplification resist composition as described in any one of [3-1] to [3-8] above, further comprising:

a mixed solvent of an alkylene glycol monoalkyl ether carboxylate and an alkyl alkoxy carboxylate.

[3-10] The chemical amplification resist composition as described in [3-9] above,

wherein the mixed solvent is a mixed solvent of a propylene glycol monoalkyl ether carboxylate and an alkyl alkoxy propionate.

[3-11] The chemical amplification resist composition as described in any one of [3-1] to [3-10] above, which is used for exposure to KrF excimer laser ray, electron beam, X-ray or high-energy ray at a wavelength of 50 nm or less.

[3-12] A resist film, which is formed of the chemical amplification resist composition as described in any one of [3-1] to [3-11] above.

[3-13] A pattern forming method, comprising:

exposing and developing the resist film as described in [3-12] above.

The third invention of the present invention preferably further includes the following configurations.

[3-14] The chemical amplification resist composition as described in any one of [3-5] to [3-11] above,

wherein the sugar derivative (G) is a compound having, in the molecule, three or more groups selected from the group consisting of a hydroxyl group and a group capable of decomposing by an action of an acid to generate an alcoholic hydroxyl group and at least one of these groups is a group capable of decomposing by an action of an acid to generate an alcoholic hydroxyl group.

[3-15] The chemical amplification resist composition as described in any one of [3-9] to [3-11] and [3-14] above,

wherein the mixed solvent is a mixed solvent of propylene glycol monomethyl ether acetate and ethyl 3-ethoxypropionate.

[3-16] The chemical amplification resist composition as described in any one of [3-9] to [3-11], [3-14] and [3-15] above,

wherein a mixing ratio of an alkylene glycol monoalkyl ether carboxylate and an alkyl alkoxy carboxylate in the mixed solvent is from 50:50 to 90:10 in terms of a mass ratio.

### DETAILED DESCRIPTION OF THE INVENTION

The present invention is described in detail below.

In the present invention, when a group (atomic group) is denoted without specifying whether substituted or unsubstituted, the group includes both a group having no substituent and a group having a substituent. For example, “an alkyl group” includes not only an alkyl group having no substituent (unsubstituted alkyl group) but also an alkyl group having a substituent (substituted alkyl group).

In the present invention, the term “actinic ray” or “radiation” indicates, for example, a bright line spectrum of mercury lamp, a far ultraviolet ray typified by excimer laser, an extreme-ultraviolet ray (EUV light), an X-ray or an electron beam (EB). Also, in the present invention, the “light” means an actinic ray or radiation.

Furthermore, in the present invention, unless otherwise indicated, the “exposure” includes not only exposure to a mercury lamp, a far ultraviolet ray typified by excimer laser, an X-ray, EUV light or the like but also lithography with a particle beam such as electron beam and ion beam.

The actinic ray-sensitive or radiation-sensitive resin composition of the first invention of the present invention comprises:

(A1) a resin capable of increasing the solubility for an alkali developer by the action of an acid, the resin containing a repeating unit represented by formula (1-I) shown later, a repeating unit represented by formula (1-II) shown later and a repeating unit represented by formula (1-III) shown later,

(B) a compound capable of generating an acid upon irradiation with an actinic ray or radiation, and

(C1) a basic compound represented by formula (1-IV) shown later.

The actinic ray-sensitive or radiation-sensitive resin composition of the first invention of the present invention is, for example, a positive composition and is typically a positive resist composition.

The actinic ray-sensitive or radiation-sensitive resin composition of the second invention of the present invention comprises:

(A2) a resin capable of increasing the solubility for an alkali developer by the action of an acid,

(B) a compound capable of generating an acid upon irradiation with an actinic ray or radiation, and

(C2) a basic compound represented by formula (2-IV) shown later.

The actinic ray-sensitive or radiation-sensitive resin composition of the second invention of the present invention is, for example, a positive composition and is typically a positive resist composition.

The chemical amplification resist composition of the third invention of the present invention comprises:

(A3) a resin capable of increasing the solubility for an alkali developer by the action of an acid,

(B) a compound capable of generating an acid upon irradiation with an actinic ray or radiation, and

(C3) a basic compound represented by formula (3-IV) shown later.

The chemical amplification resist composition of the third invention of the present invention is typically a positive chemical amplification resist composition.

The components contained in the actinic ray-sensitive or radiation-sensitive resin composition and the chemical amplification resist composition of the present invention (hereinafter, “the actinic ray-sensitive or radiation-sensitive resin composition” and “the chemical amplification resist composition” of the present invention are sometimes collectively, simply referred to as “the composition” or “the resist composition”) are described below.

### [1] Resins (A1) to (A3)

The resin (A1) contained in the actinic ray-sensitive or radiation-sensitive resin composition of the first invention of the present invention, the resin (A2) contained in the actinic ray-sensitive or radiation-sensitive resin composition of the second invention of the present invention, and the resin (A3) contained in the chemical amplification resist composition of the third invention of the present invention are described.

[1-1] Resin (A1) Capable of Increasing the Solubility for an Alkali Developer by the Action of an Acid, the Resin Containing a Repeating Unit Represented by Formula (1-I), a Repeating Unit Represented by Formula (1-II) and a Repeating Unit Represented by Formula (1-III)

The actinic ray-sensitive or radiation-sensitive resin composition of the first invention of the present invention contains a resin capable of increasing the solubility for an alkali developer by the action of an acid, the resin containing a repeating unit represented by the following formula (1-I), a repeating unit represented by the following formula (1-II) and a repeating unit represented by the following formula (1-III) (hereinafter, sometimes referred to as an “acid-decomposable resin (A1)” or a “resin (A1)”).

The resin (A1) is preferably insoluble or sparingly soluble in an alkali developer.

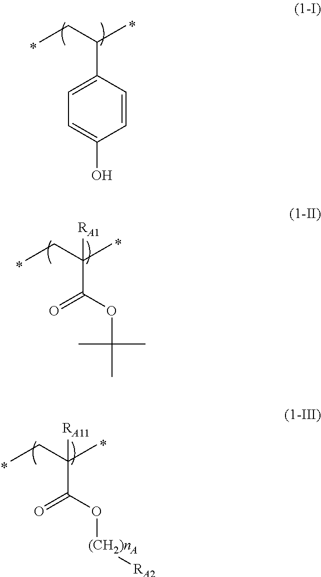

In formulae (1-II) and (1-III), each of R_{A1} and R_{A11} independently represents a hydrogen atom or a methyl.

R_{A2} represents a phenyl group or a cyclohexyl group. In view of etching resistance, R_{A2} is preferably a phenyl group.

n_{A} represents an integer of 0 to 2. In view of the preferred glass transition temperature (Tg) of the resin in pattern formation, n_{A} is preferably 1.

The phenyl group or a cyclohexyl group represented by R_{A2} may have a substituent, and in the case of having a substituent, the substituent includes an alkyl group. The carbon number of this alkyl group is preferably from 1 to 6, more preferably from 1 to 3. When the phenyl group or a cyclohexyl group represented by R_{A2} has an alkyl group, the alkyl group is preferably substituted on the 4-position of the phenyl group or cyclohexyl group.

In view of hydrophilicity/hydrophobicity of the resin, R_{A2} is preferably an unsubstituted phenyl group or an unsubstituted cyclohexyl group.

The resin contains a repeating unit represented by formula (1-III), whereby the sidelobe resistance is improved and the surface profile at the pattern formation becomes uniformly flat. On the other hand, when a contact hole pattern is formed using a resist composition employing the resin containing a repeating unit represented by formula (1-III), there arises a problem that the cross-sectional profile of the pattern is liable to have a tapered shape. In particular, when the depth of focus is changed from the optimal depth of focus to the minus side (defocused), since the pattern is resolved faithfully following an optical image, a tapered shape is readily formed in the region having a low optical contrast. With respect to this problem, in the present invention, it has been found that the problem is solved by using a basic compound represented by formula (1-IV) shown later together with the resin (A1). As a result, even in the formation of a contact hole pattern, not only the above-described effect thanks to the repeating unit represented by formula (1-III) can be obtained but also a pattern having a good cross-sectional profile can be formed.

Specific examples of the repeating unit represented by formula (1-III) are illustrated below, but the present invention is not limited thereto.

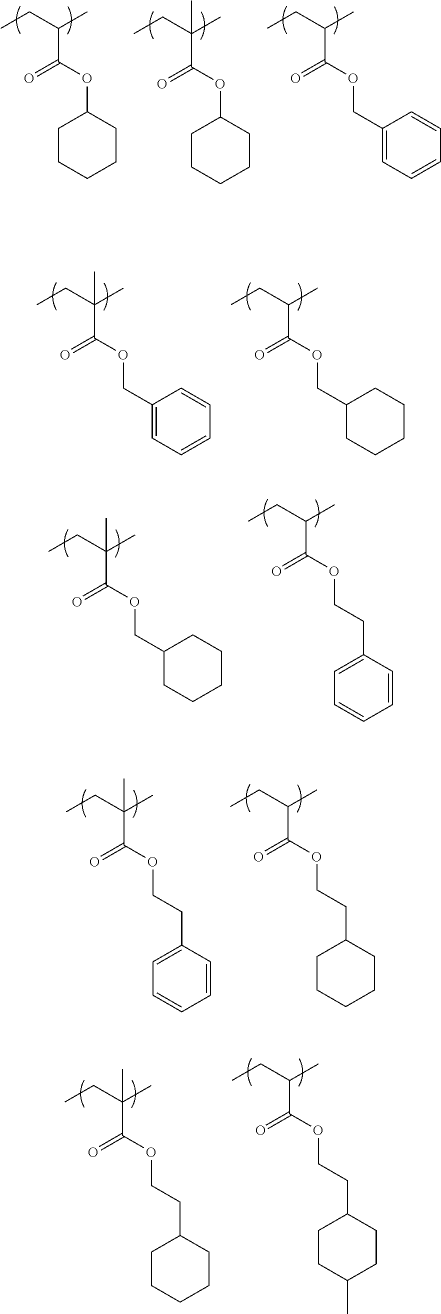

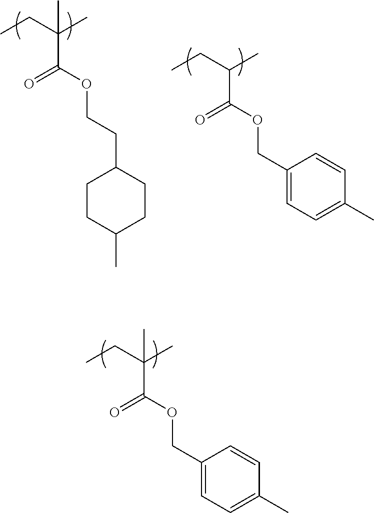

In the resin (A1), repeating units known in the resist field, other than the repeating units represented by formulae (1-I) to (1-III), may be contained as a copolymerization component.

The contents of the repeating unit represented by formula (1-I), the repeating unit represented by formula (1-II) and the repeating unit represented by formula (1-III) in the resin (A1) are preferably from 30 to 80 mol %, from 15 to 50 mol % and from 5 to 20 mol %, respectively, more preferably from 45 to 75 mol %, from 15 to 35 mol % and from 5 to 15 mol %, respectively, based on all repeating units in the resin (A1). At the same time, the total content of the repeating units represented by formulae (1-I) to (1-III) in the resin (A1) is preferably 100 mol % based on all repeating units in the resin (A1). By having such a configuration, the composition can be an actinic ray-sensitive or radiation-sensitive resin composition with higher resolution and less defects.

The resin (A1) is a resin capable of increasing the solubility for an alkali developer by the action of an acid (acid-decomposable resin) and contains, in a repeating unit, a group capable of decomposing by the action of an acid to produce an alkali-soluble group (acid-decomposable group).

In the resin (A1), the acid-decomposable group is a group formed by substituting a group capable of leaving by the action of an acid for a hydrogen atom of an alkali-soluble group, more specifically, a group formed by substituting a tert-butyl group for a hydrogen atom of —COON in the repeating unit represented by formula (1-II). That is, a tert-butoxycarbonyl group is the acid-decomposable group.

Incidentally, (meth)acrylic acid ester monomers corresponding to, for example, the repeating units represented by formulae (1-II) and (1-III) can be synthesized by esterifying a (meth)acrylic acid chloride and an alcohol compound in a solvent such as THF, acetone and methylene chloride in the presence of a basic catalyst such as triethylamine, pyridine and DBU. A commercially available product may be also used.

The resin (A1) can be synthesized using a conventional polymerization method.

The weight average molecular weight (Mw) of the resin (A1) is preferably from 3,000 to 100,000, more preferably from 5,000 to 50,000, still more preferably from 10,000 to 30,000. This range is preferred because when the molecular weight is 100,000 or less, the dissolution rate for an alkali developer is not excessively reduced and good resolution can be achieved, and when the molecular weight is 3,000 or more, the dissolution rate is not excessively increased and the film loss can be successfully suppressed.

The polydispersity (Mw/Mn) of the resin (A1) is preferably from 1.0 to 3.0, more preferably from 1.0 to 2.0.

Here, the weight average molecular weight (Mw) and the polydispersity (Mw/Mn) are determined by gel permeation chromatography (GPC) (solvent: THF) with a polystyrene standard.

The actinic ray-sensitive or radiation-sensitive resin composition of the first invention of the present invention may contain two or more kinds of resins. In this case, the composition may contain two or more kinds of resins (A1) or may contain, in addition to one or more kinds of resins (A1), one or more kinds of resins other than the resin (A1) within the range not impairing the effects of the present invention. The resin other than the resin (A1) is not particularly limited, and known resins may be used, but examples thereof include a PHS (poly-para-hydroxystyrene)-based resin protected by an acid-decomposable group, and a tertiary (meth)acrylate copolymer. Examples of the acid-decomposable group include an acetal group, a tert-butoxycarbonyl group, a tert-butoxycarbonylethyl group and a tert-butoxy group. Examples of the tertiary (meth)acrylate include tert-butoxy (meth)acrylate, ethylcyclohexyl (meth)acrylate and ethylcyclopentyl (meth)acrylate.

The content of the resin (A1) is not particularly limited but is, when containing two or more kinds of the resins, as a total amount, preferably from 20 to 99 mass %, more preferably from 30 to 98 mass %, based on the entire solid content of the actinic ray-sensitive or radiation-sensitive resin composition of the first invention of the present invention. (In this specification, mass ratio is equal to weight ratio.)

Specific examples of the resin (A1) containing repeating units represented by formulae (1-I) to (1-III) are illustrated below, but the present invention is not limited thereto.

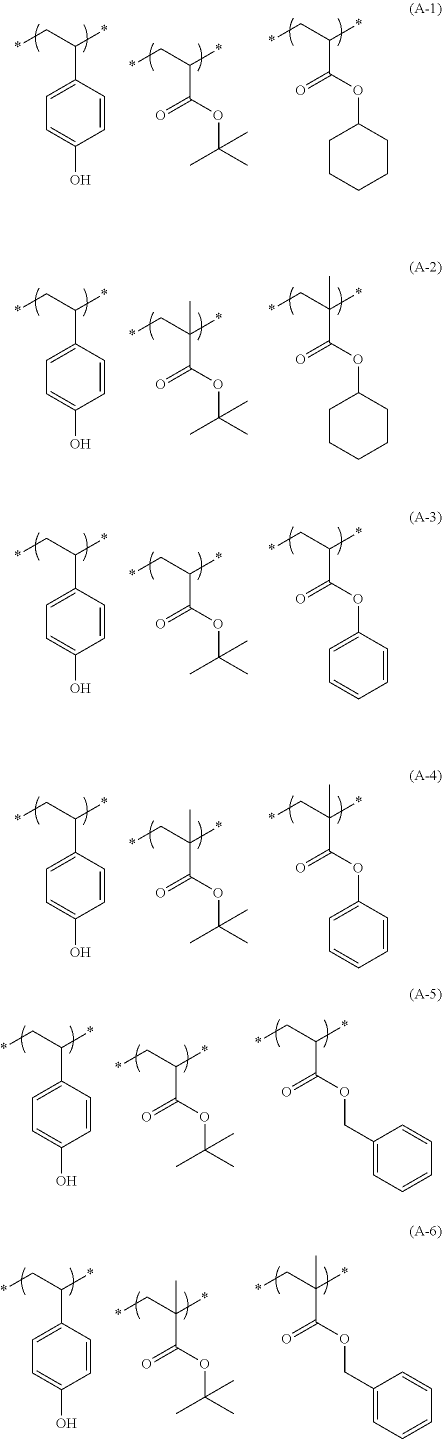

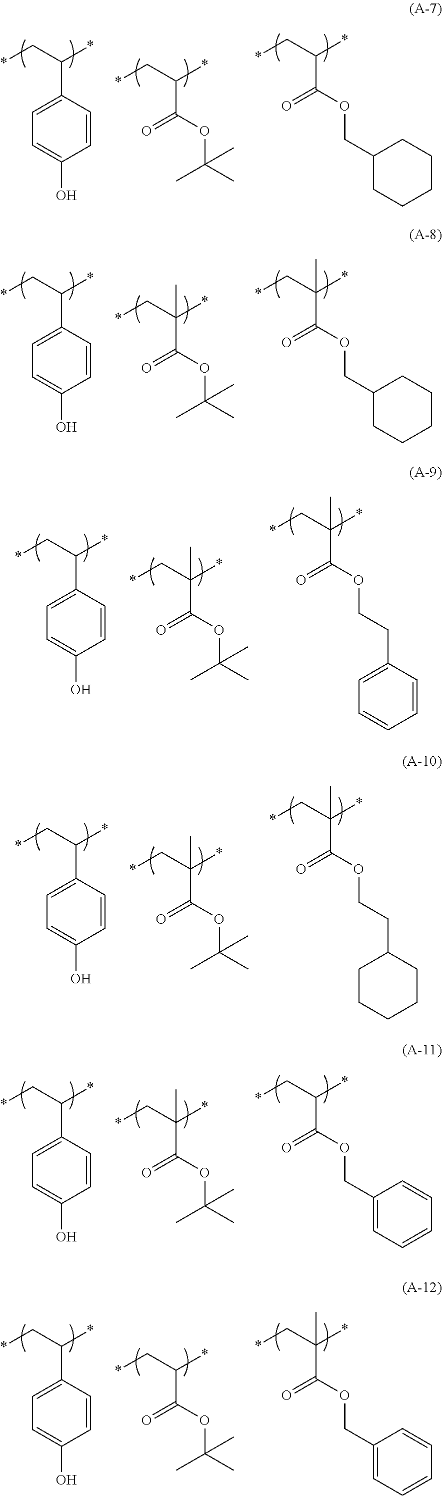

### [1-2] Resin (A2) Capable of Increasing the Solubility for an Alkali Developer by the Action of an Acid

The actinic ray-sensitive or radiation-sensitive resin composition of the second invention of the present invention contains (A2) a resin capable of increasing the solubility for an alkali developer by the action of an acid (hereinafter, sometimes simply referred to as a “resin (A2)”).

The actinic ray-sensitive or radiation-sensitive resin composition of the second invention of the present invention is suitable for irradiation with KrF excimer laser light, electron beam, X-ray or high-energy ray at a wavelength of 50 nm or less (e.g., EUV), and the resin (A2) preferably contains a hydroxystyrene repeating unit represented by the following formula (2-I):

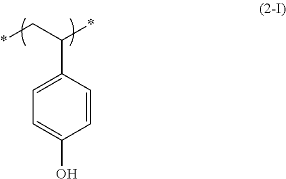

In the present invention, the content of the hydroxystyrene repeating unit above is preferably from 5 to 95 mol %, more preferably from 5 to 90 mol %, still more preferably from 10 to 85 mol %, based on all repeating units in the resin (A2).

In the present invention, the resin (A2) is preferably a copolymer containing the hydroxystyrene repeating unit above and a hydroxystyrene repeating unit protected by a group capable of leaving by the action of an acid, or a copolymer containing the hydroxystyrene repeating unit and a tertiary alkyl (meth)acrylate repeating unit.

In the present invention, when the resin (A2) contains a hydroxystyrene repeating unit protected by a group capable of leaving by the action of an acid, the repeating unit is preferably a repeating unit represented by the following formula (A-1):

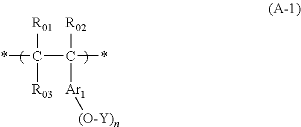

In the formula, each of R₀₁, R₀₂ and R₀₃ independently represents a hydrogen atom, an alkyl group, a cycloalkyl group, a halogen atom, a cyano group or an alkoxycarbonyl group. Ar₁ represents an (n+1)-valent aromatic ring group.

R₀₃ may also represent an alkylene group and combine with Ar₁ to form a 5- or 6-membered ring together with the —C—C— chain. In this case, Ar₁ represents an (n+2)-valent aromatic ring group.

Each Y independently represents a hydrogen atom or a group capable of leaving by the action of an acid. When n is an integer of 2 or more, each Y may be the same as or different from every other Y. However, at least one Y represents a group capable of leaving by the action of an acid.

n represents an integer of 1 to 4 and is preferably 1 or 2, more preferably 1.

The alkyl group as R₀₁ to R₀₃ is, for example, an alkyl group having a carbon number of 20 or less and is preferably a methyl group, an ethyl group, a propyl group, an isopropyl group, an n-butyl group, a sec-butyl group, a hexyl group, a 2-ethylhexyl group, an octyl group or a dodecyl group. The alkyl group is more preferably an alkyl group having a carbon number of 8 or less. These alkyl groups may have a substituent.

As the alkyl group contained in the alkoxycarbonyl group of R₀₁ to R₀₃, preferred alkyl groups are the same as those of the alkyl group in R₀₁ to R₀₃.

The cycloalkyl group as R₀₁ to R₀₃ may be either a monocyclic cycloalkyl group or a polycyclic cycloalkyl group. The cycloalkyl group is preferably a monocyclic cycloalkyl group having a carbon number of 3 to 8, such as cyclopropyl group, cyclopentyl group and cyclohexyl group. These cycloalkyl groups may have a substituent.

The halogen atom as R₀₁ to R₀₃ includes a fluorine atom, a chlorine atom, a bromine atom and an iodine atom, with a fluorine atom being preferred.

In the case where R₀₃ represents an alkylene group, the alkylene group is preferably an alkylene group having a carbon number of 1 to 8, such as methylene group, ethylene group, propylene group, butylene group, hexylene group and octylene group.

Each of R₀₁ to R₀₃ is preferably a hydrogen atom.

The aromatic ring group as Ar₁ is preferably an aromatic ring group having a carbon number of 6 to 14, and examples thereof include a benzene ring group, a toluene ring and a naphthalene ring group. These aromatic rings may have a substituent.

Examples of the group Y capable of leaving by the action of an acid include groups represented by —C(R³⁶)(R³⁷)(R³⁸), —C(═O)—O—C(R³⁶)(R³⁷)(R³⁸), —C(R⁰¹)(R⁰²)(OR³⁹),

In the formulae, each of R³⁶ to R³⁹ independently represents an alkyl group, a cycloalkyl group, an aryl group, an aralkyl group or an alkenyl group. R³⁶ and R³⁷ may combine with each other to form a ring structure.

Each of R⁰¹ and R⁰² independently represents a hydrogen atom, an alkyl group, a cycloalkyl group, an aryl group, an aralkyl group or an alkenyl group.

Ar represents an aryl group.

The alkyl group as R³⁶ to R³⁹, R⁰¹ and R⁰² is preferably an alkyl group having a carbon number of 1 to 8, and examples thereof include a methyl group, an ethyl group, a propyl group, an n-butyl group, a sec-butyl group, a hexyl group and an octyl group.

The cycloalkyl group as R³⁶ to R³⁹, R⁰¹ and R⁰² may be a monocyclic cycloalkyl group or a polycyclic cycloalkyl group. The monocyclic cycloalkyl group is preferably a cycloalkyl group having a carbon number of 3 to 8, and examples thereof include a cyclopropyl group, a cyclobutyl group, a cyclopentyl group, a cyclohexyl group and a cyclooctyl group. The polycyclic cycloalkyl group is preferably a cycloalkyl group having a carbon number of 6 to 20, and examples thereof include an adamantyl group, a norbornyl group, an isoboronyl group, a camphanyl group, a dicyclopentyl group, an α-pinel group, a tricyclodecanyl group, a tetracyclododecyl group and an androstanyl group. Incidentally, a part of carbon atoms in the cycloalkyl group may be substituted with a heteroatom such as oxygen atom.

The aryl group as R³⁶ to R³⁹, R⁰¹, R⁰² and Ar is preferably an aryl group having a carbon number of 6 to 10, and examples thereof include a phenyl group, a naphthyl group and an anthryl group.

The aralkyl group as R³⁶ to R³⁹, R⁰¹ and R⁰² is preferably an aralkyl group having a carbon number of 7 to 12, and preferred examples thereof include a benzyl group, a phenethyl group and a naphthylmethyl group.

The alkenyl group as R³⁶ to R³⁹, R⁰¹ and R⁰² is preferably an alkenyl group having a carbon number of 2 to 8, and examples thereof include a vinyl group, an allyl group, a butenyl group and a cyclohexenyl group.

The ring formed by combining R³⁶ and R³⁷ with each other may be either monocyclic or polycyclic. The monocyclic ring is preferably a cycloalkane structure having a carbon number of 3 to 8, and examples thereof include a cyclopropane structure, a cyclobutane structure, a cyclopentane structure, a cyclohexane structure, a cycloheptane structure and a cyclooctane structure. The polycyclic ring is preferably a cycloalkane structure having a carbon number of 6 to 20, and examples thereof include an adamantane structure, a norbornane structure, a dicyclopentane structure, a tricyclodecane structure and a tetracyclododecane structure. Incidentally, a part of carbon atoms in the ring structure may be substituted with a heteroatom such as oxygen atom.

Each of the groups above may have a substituent, and examples of the substituent include an alkyl group, a cycloalkyl group, an aryl group, an amino group, an amido group, a ureido group, a urethane group, a hydroxy group, a carboxy group, a halogen atom, an alkoxy group, a thioether group, an acyl group, an acyloxy group, an alkoxycarbonyl group, a cyano group and a nitro group. The carbon number of the substituent is preferably 8 or less.

In the resin (A2), the repeating units represented by formula (A-1) may combine with each other through a group as Y capable of leaving by the action of an acid.

The group Y capable of leaving by the action of an acid is more preferably a structure represented by the following formula (A-2):

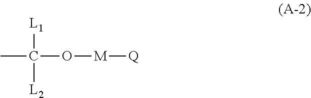

In the formula, each of L₁ and L₂ independently represents a hydrogen atom, an alkyl group, a cycloalkyl group, an aryl group or an aralkyl group.

M represents a single bond or a divalent linking group.

Q represents an alkyl group, an alicyclic group, an aromatic ring group, an amino group, an ammonium group, a mercapto group, a cyano group or an aldehyde group. The alicyclic group and the aromatic ring group may contain a heteroatom.

At least two members of Q, M and L₁ may combine with each other to form a 5- or 6-membered ring.

The alkyl group as L₁ and L₂ is, for example, an alkyl group having a carbon number of 1 to 8, and specific examples thereof include a methyl group, an ethyl group, a propyl group, an n-butyl group, a sec-butyl group, a hexyl group and an octyl group.

The cycloalkyl group as L₁ and L₂ is, for example, a cycloalkyl group having a carbon number of 3 to 15, and specific examples thereof include a cyclopentyl group, a cyclohexyl group, a norbornyl group and an adamantyl group.

The aryl group as L₁ and L₂ is, for example, an aryl group having a carbon number of 6 to 15, and specific examples thereof include a phenyl group, a tolyl group, a naphthyl group and an anthryl group.

The aralkyl group as L₁ and L₂ is, for example, an aralkyl group having a carbon number of 7 to 20, and specific examples thereof include a benzyl group and a phenethyl group.

Examples of the divalent linking group as M include an alkylene group (e.g., methylene, ethylene, propylene, butylene, hexylene, octylene), a cycloalkylene group (e.g., cyclopentylene, cyclohexylene), an alkenylene group (e.g., vinylene, propenylene, butenylene), an arylene group (e.g., phenylene, tolylene, naphthylene), —S—, —O—, —CO—, —SO₂—, —N(Rₒ)—, and a combination of two or more thereof. Here, Rₒ is a hydrogen atom or an alkyl group. The alkyl group as R₀ is, for example, an alkyl group having a carbon number of 1 to 8, and specific examples thereof include a methyl group, an ethyl group, a propyl group, an n-butyl group, a sec-butyl group, a hexyl group and an octyl group.

Examples of the alkyl group as Q is the same as those of the alkyl group as L₁ and L₂.

Examples of the alicyclic group and aromatic ring group as Q include the above-described cycloalkyl group and aryl group as L₁ and L₂. The cycloalkyl group and aryl group are preferably a group having a carbon number of 3 to 15.

Examples of the heteroatom-containing alicyclic or aromatic ring group as Q include a group having a heterocyclic structure such as thiirane, cyclothiolane, thiophene, furan, pyrrole, benzothiophene, benzofuran, benzopyrrole, triazine, imidazole, benzimidazole, triazole, thiadiazole, thiazole and pyrrolidone, but the ring is not limited thereto as long as it is a ring composed of a carbon atom and a heteroatom or a ring composed of only a heteroatom.

Examples of the ring structure which may be formed by combining at least two members out of Q, M and L₁ with each other include a 5- or 6-membered ring structure where a propylene group or a butylene group is formed by the members above. The 5- or 6-membered ring structure contains an oxygen atom.

In formula (A-2), the groups represented by L₁, L₂, M and Q and the ring structure which may be formed by combining at least two members out of Q, M and L₁ with each other may have a substituent, and examples of the substituent include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group and a nitro group. The carbon number of the substituent is preferably 8 or less.

The group represented by -(M-Q) is preferably a group having a carbon number of 1 to 30, more preferably a group having a carbon number of 5 to 20. Particularly, from the standpoint of suppressing the outgas problem (the problem that when a high-energy ray such as EUV light is irradiated, a compound in the resist film is degraded by fragmentation and volatizes as a low molecular compound during exposure to contaminate the environment in the exposure machine), a group having a carbon number of 6 or more is preferred.

In the present invention, the content of the repeating unit represented by formula (A-1) is preferably from 3 to 90 mol %, more preferably from 5 to 80 mol %, still more preferably from 7 to 70 mol %, based on all repeating units in the resin (A2).

Specific examples of the repeating unit represented by formula (A-1) are illustrated below, but the present invention is not limited thereto.

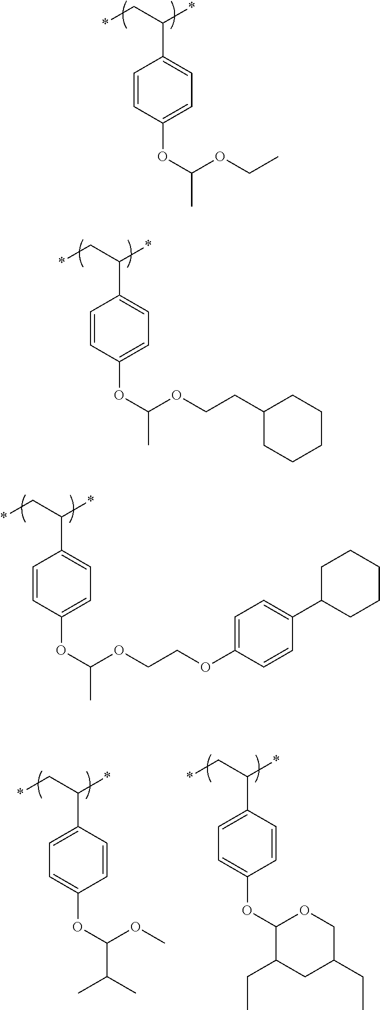

In the present invention, when the resin (A2) contains a tertiary alkyl (meth)acrylate repeating unit, the repeating unit is preferably a repeating unit represented by the following formula (X):

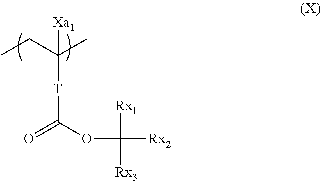

In formula (X), Xa₁ represents a hydrogen atom or an alkyl group.

T represents a single bond or a divalent linking group.

Each of Rx₁ to Rx₃ independently represents an alkyl group or a cycloalkyl group. Two members out of Rx₁ to Rx₃ may combine with each other to form a cycloalkyl group.

The alkyl group of Xa₁ may have a substituent, and examples of the substituent include a halogen atom and a hydroxyl group. Specific examples of Xa₁ include a hydrogen atom, a methyl group, a trifluoromethyl group and a hydroxymethyl group. Among these, a hydrogen atom and a methyl group are preferred, and a methyl group is more preferred.

Examples of the divalent linking group as T include an alkylene group, a —(COO-Rt)— group and a —(O—Rt)— group. In the formulae, Rt represents an alkylene group or a cycloalkylene group.

T is preferably a single bond or a —(COO-Rt)— group. Rt is preferably an alkylene group having a carbon number of 1 to 5, more preferably a —CH₂— group, —(CH₂)₂— group or a —(CH₂)₃— group.

The alkyl group as Rx₁ to Rx₃ is a linear or branched alkyl group and preferably an alkyl group having a carbon number of 1 to 4, such as methyl group, ethyl group, n-propyl group, isopropyl group, n-butyl group, isobutyl group and tert-butyl group.

The cycloalkyl group as Rx₁ to Rx₃ is a monocyclic or polycyclic cycloalkyl group and preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The cycloalkyl group which may be formed by combining two members of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group, more preferably a monocyclic cycloalkyl group having a carbon number of 5 or 6.

An embodiment where Rx₁ is a methyl group or an ethyl group and Rx₂ and Rx₃ are combined to form the above-described cycloalkyl group is preferred.

Specific preferred examples of the repeating unit represented by formula (X) are illustrated below, but the present invention is not limited thereto.

(In the formulae, Rx represents H, CH₃, CF₃ or CH₂OH, and each of Rxa and Rxb represents an alkyl group having a carbon number of 1 to 4.)

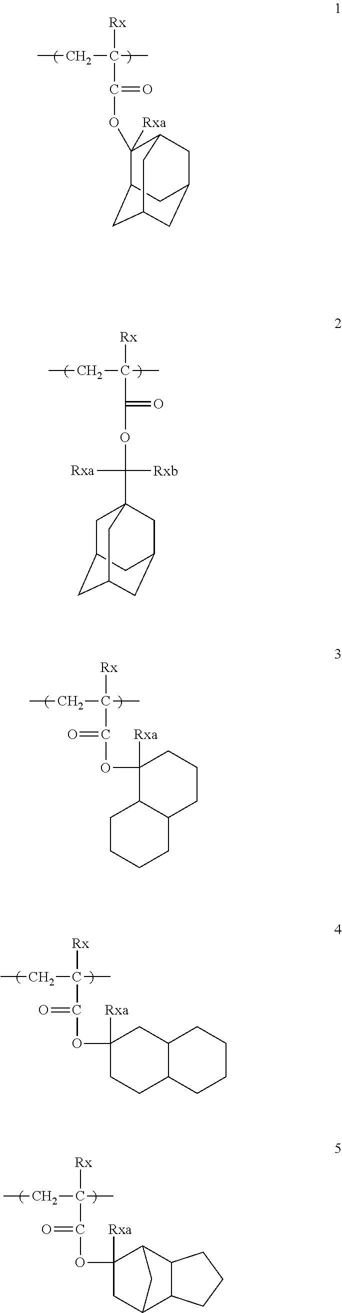

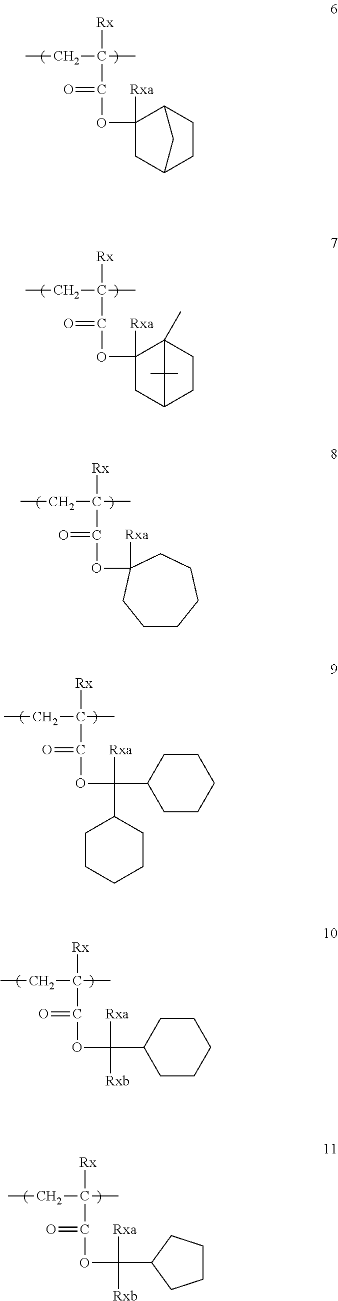

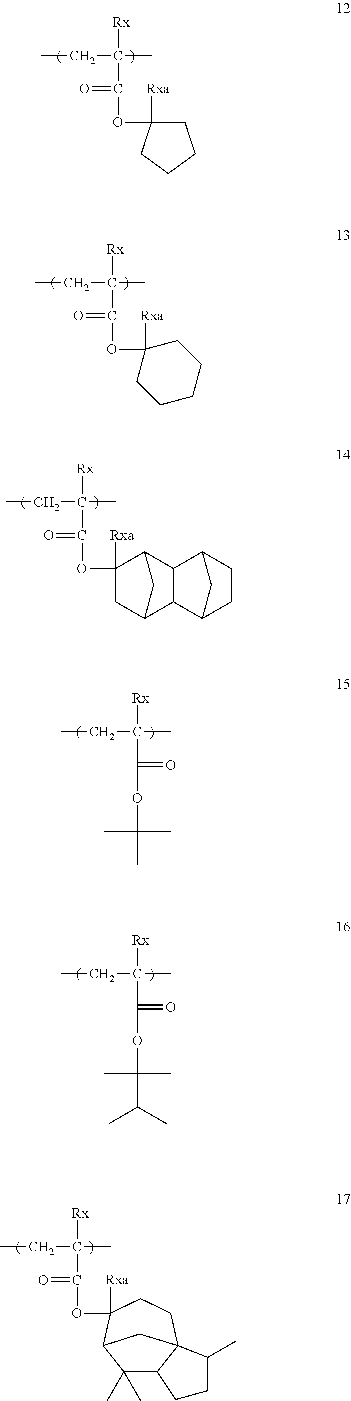

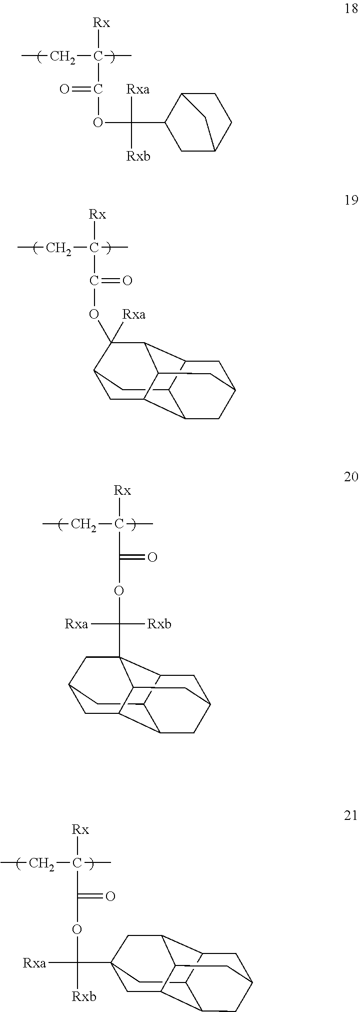

In the present invention, the repeating unit represented by formula (X) is preferably represented by the following formula (2-II):

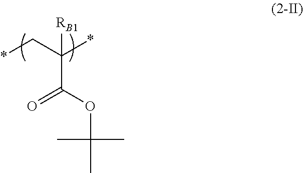

In the formula, R_{B1} represents a hydrogen atom or a methyl group which may have a substituent.

Examples of the substituent in the methyl group which may have a substituent, represented by R_{B1}, include a halogen atom and a hydroxyl group. Specific examples of R_{B1} include a hydrogen atom, a methyl group, a trifluoromethyl group and a hydroxymethyl group. Among these, a hydrogen atom and a methyl group are preferred, and a methyl group is more preferred.

The content of the repeating unit represented by formula (X) is preferably from 3 to 90 mol %, more preferably from 5 to 80 mol %, still more preferably from 7 to 70 mol %, based on all repeating units in the resin (A2).

In the present invention, the resin (A2) that is suitable for exposure to KrF excimer laser light, electron beam, X-ray or high-energy ray at a wavelength of 50 nm or less (e.g., EUV) may contain a repeating unit other than the repeating units described above. Examples of such a repeating unit include a repeating unit stable to an acid, and a repeating unit having a lactone structure, which are described below.

More specifically, the repeating unit stable to an acid includes a repeating unit represented by the following formula (V) having a non-acid-decomposable aryl structure or cycloalkyl structure in the side chain of an acrylic structure. By having such a structure, adjustment of contrast, enhancement of etching resistance, and the like can be expected to be achieved.

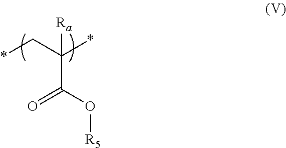

In formula (V), R₅ represents a non-acid-decomposable hydrocarbon group.

Ra represents a hydrogen atom, an alkyl group or a —CH₂—O—Ra₂ group, wherein Ra₂ represents a hydrogen atom or an alkyl group. The alkyl group as Ra and Ra₂ is preferably an alkyl group having a carbon number of 1 to 8, more preferably from 1 to 4. The alkyl group as Ra and Ra₂ may further have a substituent. Examples of the substituent include a halogen atom such as fluorine atom and chlorine atom. Examples of the alkyl group of Ra include a methyl group, a chloromethyl group and a trifluoromethyl group.

Ra is preferably a hydrogen atom, a methyl group, a hydroxymethyl group or a trifluoromethyl group, more preferably a hydrogen atom or a methyl group.

The non-acid-decomposable hydrocarbon of R₅ preferably contains a cyclic structure therein. Specific examples of the cyclic structure include a monocyclic or polycyclic cycloalkyl group (preferably having a carbon number of 3 to 14, more preferably from 3 to 7), a monocyclic or polycyclic cycloalkenyl group (preferably having a carbon number of 3 to 12), an aryl group (preferably having a carbon number of 6 to 20, more preferably from 6 to 12), and an aralkyl group (preferably having a carbon number of 7 to 20, more preferably from 7 to 12).

R₅ may further have a substituent, and examples of the substituent include an alkyl group having a carbon number of 1 to 4, a cycloalkyl group having a carbon number of 3 to 10, an aryl group having a carbon number of 6 to 10, a halogen atom such as fluorine atom and chlorine atom, an alkoxyl group, an alkoxycarbonyl group, a carbamoyl group, a cyano group and a nitro group. Among these substituent, an alkyl group having a carbon number of 1 to 4 is preferred.

In the present invention, the repeating unit represented by formula (V) is preferably represented by the following formula (2-III):

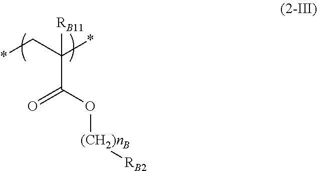

In the formula, R_{B11} represents a hydrogen atom or a methyl group which may have a substituent, R_{B2} represents a phenyl group which may have a substituent, or a cyclohexyl group which may have a substituent, and n_{B} represents an integer of 0 to 2.

Examples of the substituent in the methyl group which may have a substituent, represented by R_{B11}, are the same as those of the substituent in the methyl group which may have a substituent, represented by R_{B1}, and specific examples and preferred groups of R_{B11} are the same as specific examples and preferred groups of R_{B1}.

Examples of the substituent which the phenyl group or cyclohexyl group may further have are the same as those described above as the substituent which R₅ in formula (V) may further have. Particularly preferred substituents include an alkyl group having a carbon number of 1 to 4, a cycloalkyl group having a carbon number of 3 to 10, an aryl group having a carbon number of 6 to 10, and a halogen atom such as fluorine atom and chlorine atom.

In the case where the phenyl group or cyclohexyl group represented by R_{B2} has a substituent, the substituent is preferably substituted on the 4-position of the phenyl group or cyclohexyl group.

In view of etching resistance, R_{B2} is preferably a phenyl group which may have a substituent.

In view of the preferred glass transition temperature (Tg) of the resin in pattern formation, n_{B} is preferably 1.

In general, when the resin contains a repeating unit represented by formula (2-III), the sidelobe resistance is improved and the surface profile at the pattern formation becomes uniformly flat. However, it is known that a basic compound combined greatly effects the sidelobe resistance. The sidelobe resistance is more improved by combining the basic compound of the present invention.

When a contact hole pattern is formed using a resist composition employing the resin containing a repeating unit represented by formula (2-III), there arises a problem that the cross-sectional profile of the pattern is liable to have a tapered shape. In particular, when the depth of focus is changed from the optimal depth of focus to the minus side (defocused), since the pattern is resolved faithfully following an optical image, a tapered shape is readily formed in the region having a low optical contrast. To solve this problem, a basic compound represented by formula (2-IV) shown later is used, whereby even in the formation of a contact hole pattern, not only the above-described effect thanks to the repeating unit represented by formula (2-III) can be obtained but also a pattern having a good cross-sectional profile can be formed. Once a good cross-sectional profile is formed, the profile at DOF is improved and in turn, DOF is broadened, as a result, EDW is increased.

The content of the repeating unit represented by formula (V) is preferably from 1 to 40 mol %, more preferably from 2 to 20 mol %, based on all repeating units in the resin (A2).

Specific examples of the repeating unit represented by formula (V) are illustrated below, but the present invention is not limited thereto. In the formulae, Ra represents H, CH₃, CH₂OH or CF₃.

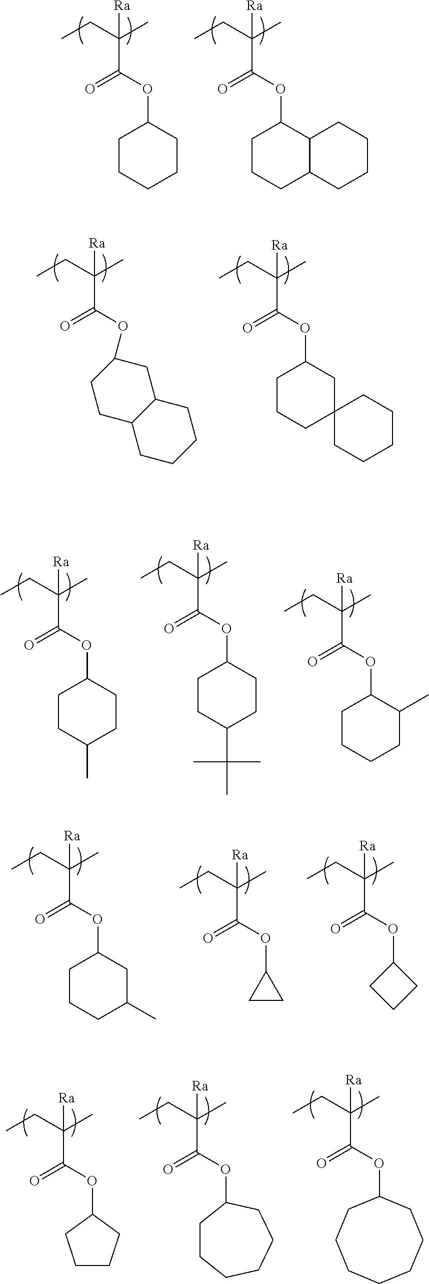

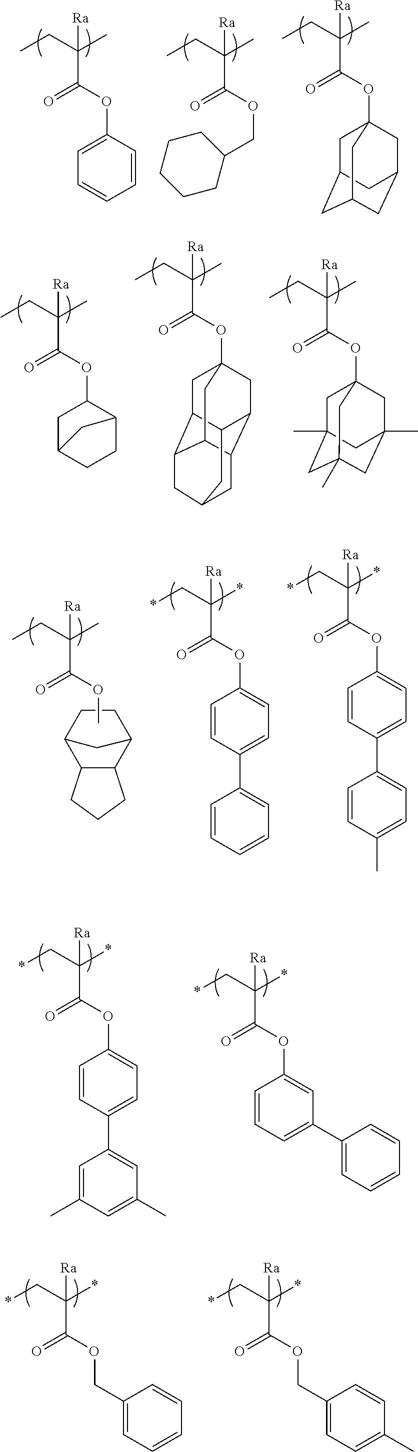

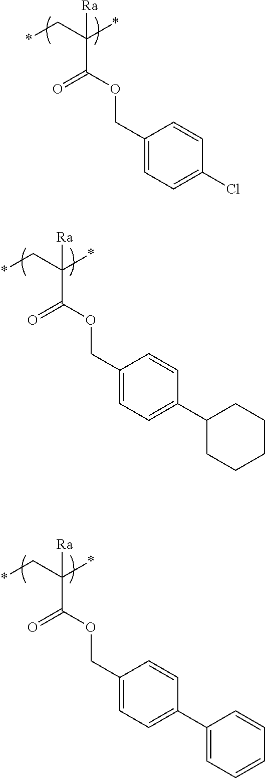

In the present invention, the resin (A2) preferably contains a repeating unit represented by formula (2-I), a repeating unit represented by formula (A-1) or (X) and a repeating unit represented by formula (V).

In the present invention, the contents of the repeating unit represented by formula (2-I), the repeating unit represented by formula (A-1) or (X) and the repeating unit represented by formula (V) are preferably from 45 to 80 mol %, from 15 to 50 mol % and from 5 to 20 mol %, respectively, based on all repeating units in the resin (A2).

The resin (A2) is preferably a resin composed of only a repeating unit represented by formula (2-I), a repeating unit represented by formula (A-1) or (X) and a repeating unit represented by formula (V), in other words, a resin where the total content of these repeating units in the resin (A2) is 100 mol % based on all repeating units in the resin (A2).

In the present invention, the resin (A2) preferably contains a repeating unit represented by the following formula (2-I), a repeating unit represented by the following formula (2-II) and a repeating unit represented by the following formula (2-III):

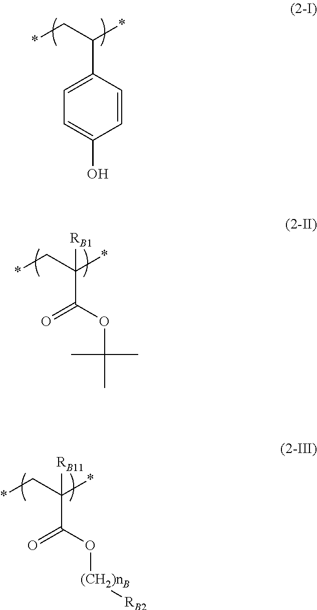

In formulae (2-II) and (2-III), the definitions and preferred ranges of R_{B1}, R_{B11}, R_{B2} and n_{B} are the same as those of R_{BI}, R_{B11}, R_{B2} and n_{B} described above for formulae (2-II) and (2-III).

In the present invention, the contents of the repeating unit represented by formula (2-I), the repeating unit represented by formula (2-II) and the repeating unit represented by formula (2-III) are preferably from 45 to 80 mol %, from 15 to 50 mol % and from 5 to 20 mol %, respectively, more preferably from 50 to 70 mol %, from 20 to 35 mol % and from 5 to 15 mol %, respectively, based on all repeating units in the resin (A2).

Specific preferred examples of the resin (A2) are illustrated below, but the present invention is not limited thereto.

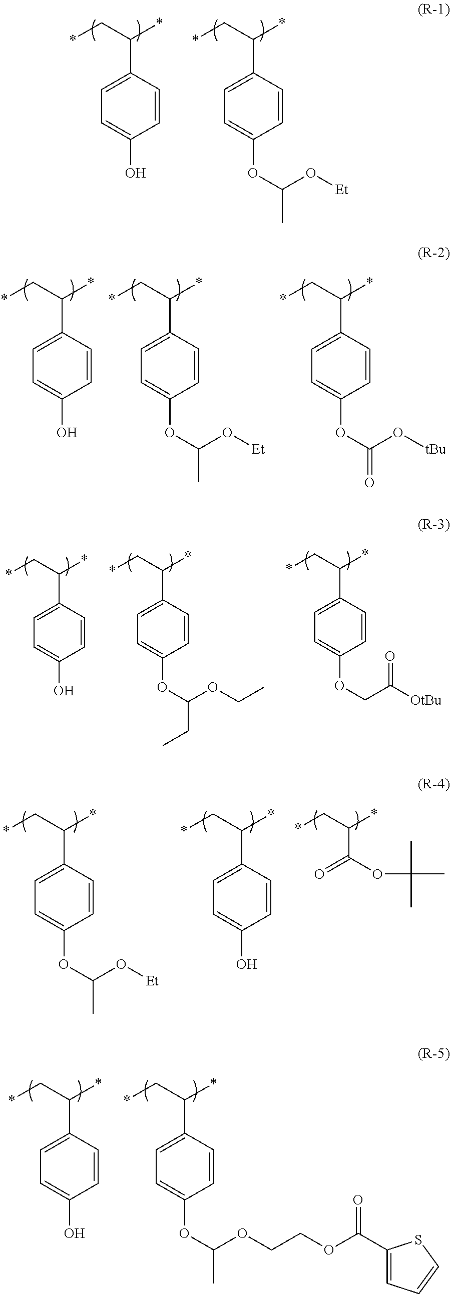

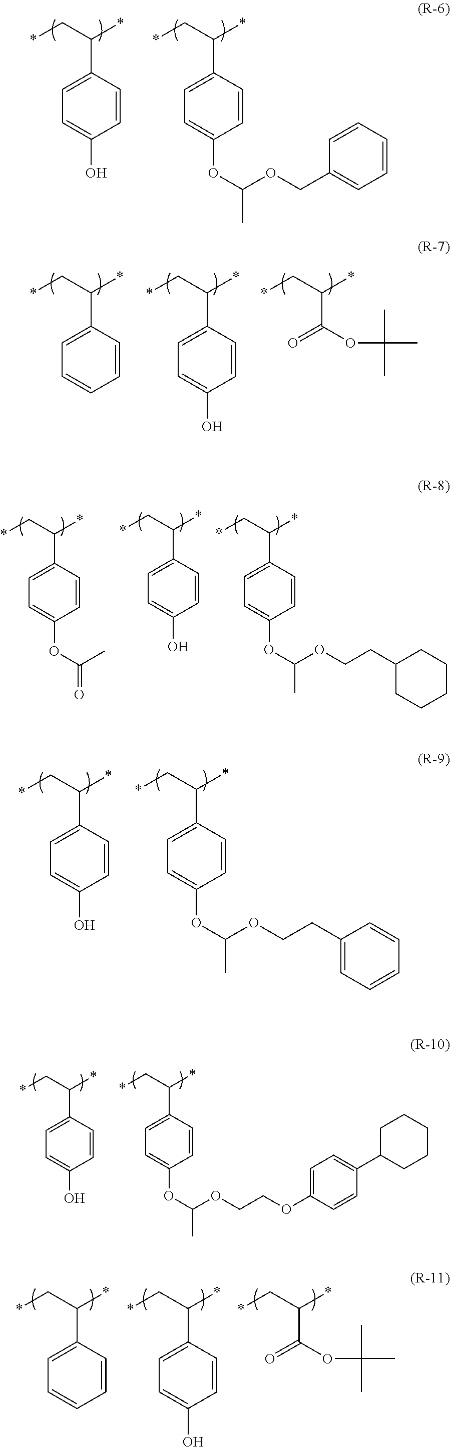

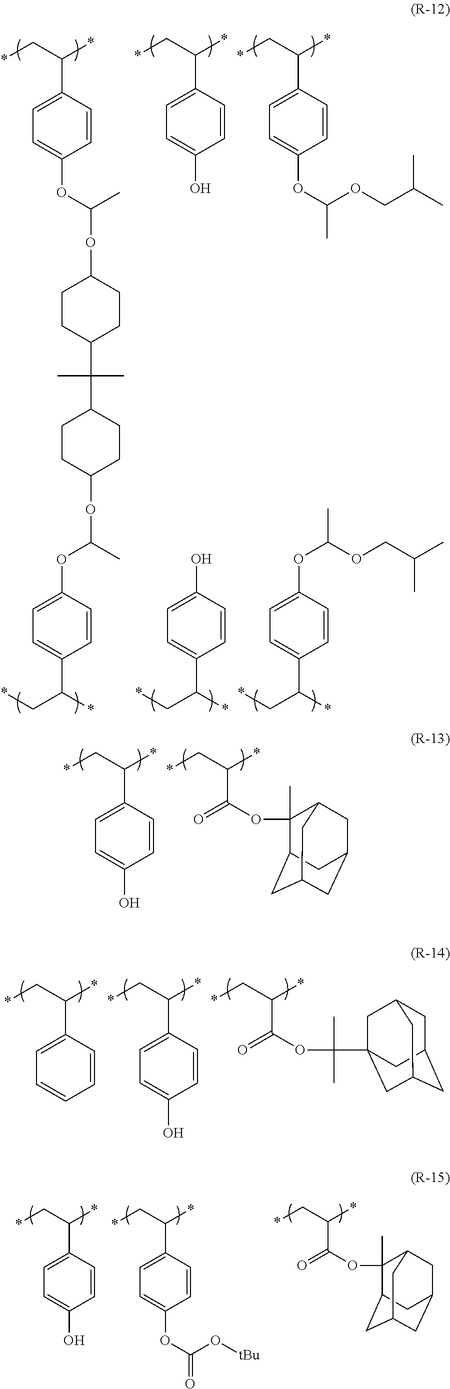

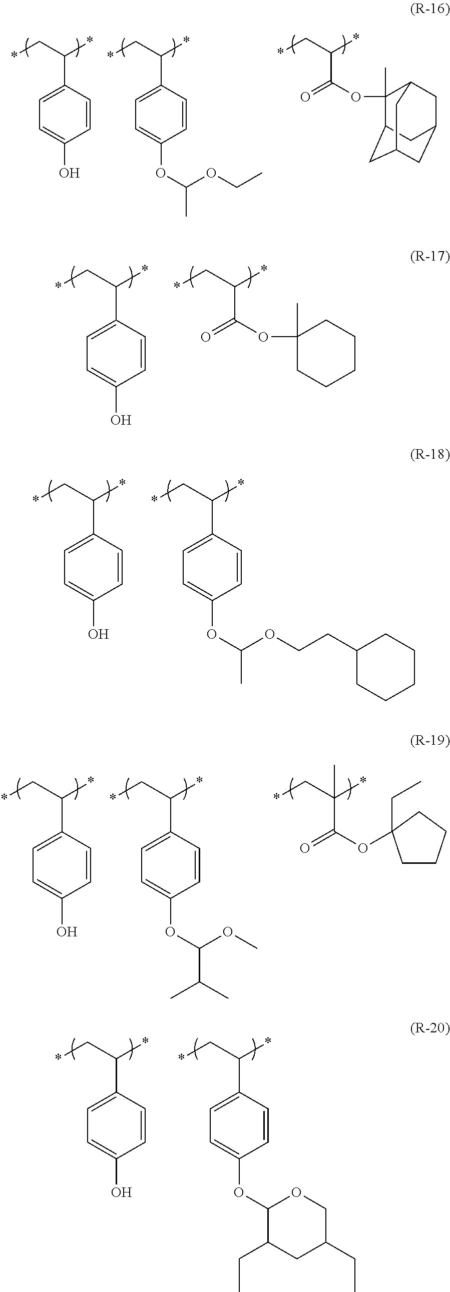

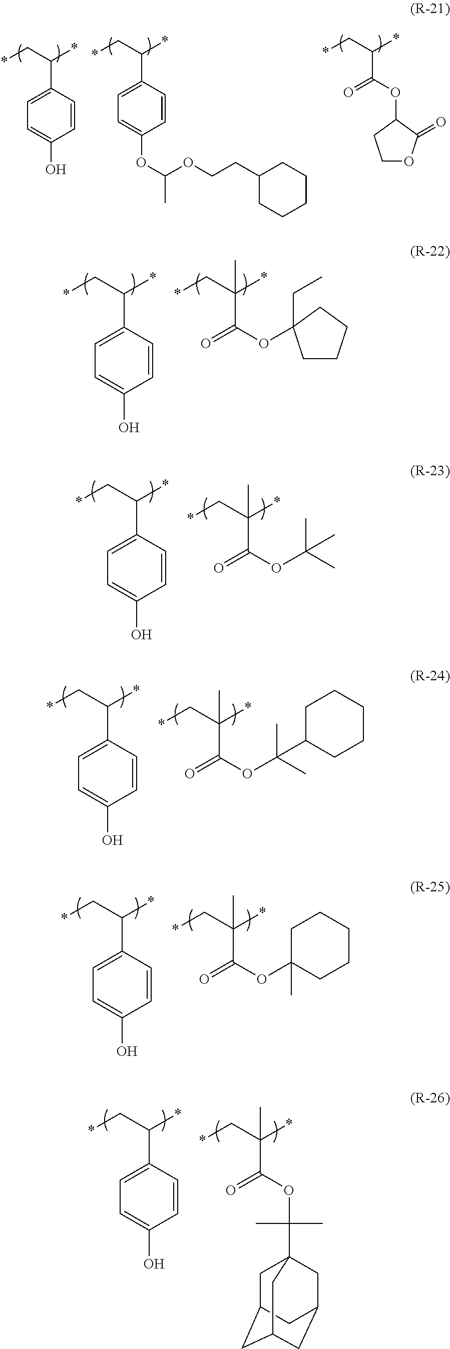

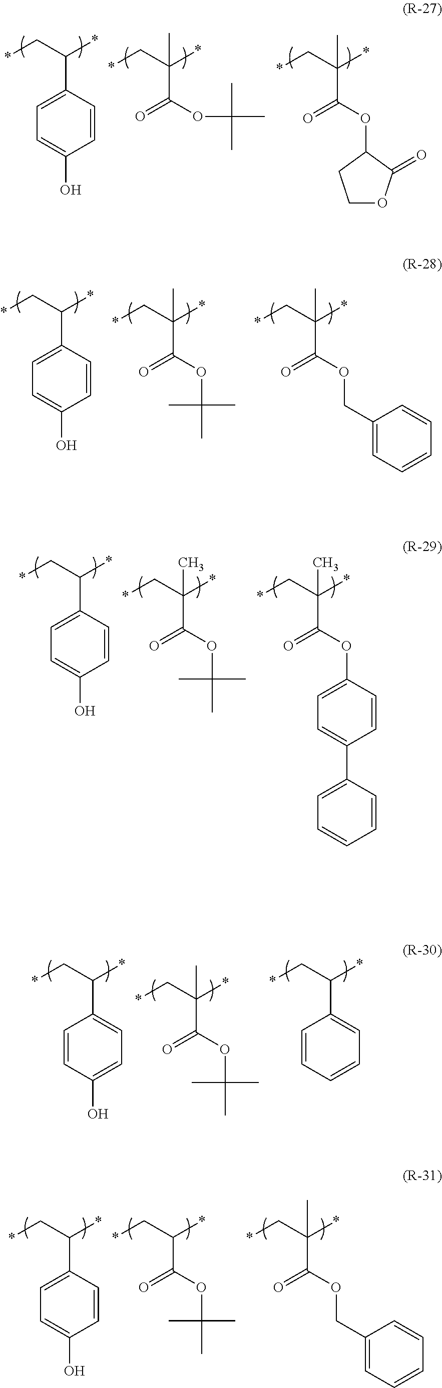

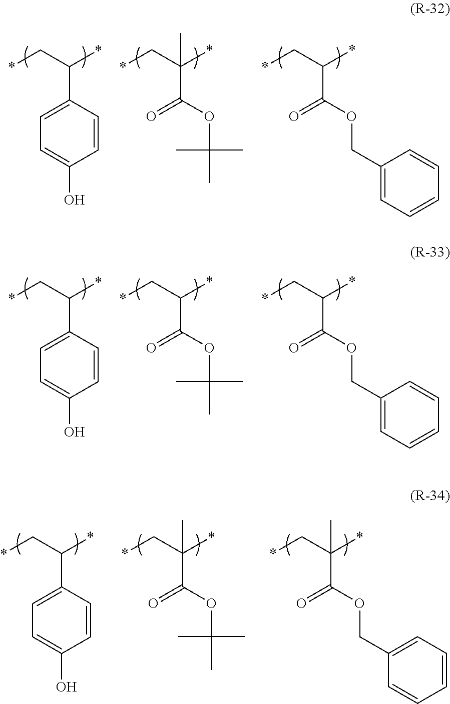

In specific examples above, Et indicates an ethyl group and tBu indicates a tert-butyl group.

The content of the group capable of decomposing by the action of an acid is calculated according to the formula B/(B+S) using the number (B) of groups capable of decomposing by the action of an acid and the number (S) of alkali-soluble groups not protected by a group capable of leaving by the action of an acid, in the resin. The content is preferably from 0.01 to 0.7, more preferably from 0.05 to 0.50, still more preferably from 0.05 to 0.40.

The actinic ray-sensitive or radiation-sensitive resin composition of the second invention of the present invention may contain two or more kinds of resins. In this case, the composition may contain two or more kinds of resins (A2) or may contain, in addition to one or more kinds of resins (A2), one or more kinds of resins other than the resin (A2) within the range not impairing the effects of the present invention.

The content of the resin (A2) added is not particularly limited but is, when containing two or more kinds of the resins, as a total amount, preferably from 20 to 99 mass %, more preferably from 30 to 98 mass %, based on the entire solid content of the actinic ray-sensitive or radiation-sensitive resin composition of the second invention of the present invention.

The molecular weight of the resin (A2) for use in the present invention is not particularly limited, but the weight average molecular weight is preferably from 1,000 to 100,000, more preferably from 1,500 to 30,000, still more preferably from 2,000 to 25,000. Here, the weight average molecular weight of the resin indicates a molecular weight in terms of polystyrene measured by GPC (carrier: THF or N-methyl-2-pyrrolidone (NMP)).

The polydispersity (Mw/Mn) is preferably from 1.00 to 5.00, more preferably from 1.03 to 3.50, still more preferably from 1.05 to 2.50.

Examples of the polymerization method for producing the resin (A2) in the present invention include a batch polymerization method of dissolving unsaturated monomers corresponding to precursors of respective repeating units and an initiator in a solvent and heating the solution, thereby effecting the polymerization, and a dropping polymerization method of adding dropwise a solution containing the monomers above and an initiator to a heated solvent over 1 to 10 hours. A dropping polymerization method is preferred.

Examples of the reaction solvent include ethers such as tetrahydrofuran, 1,4-dioxane, diisopropyl ether, ketones such as methyl ethyl ketone and methyl isobutyl ketone, an ester solvent such as ethyl acetate, an amide solvent such as dimethylformamide and dimethylacetamide, and the later-described solvent (e.g., propylene glycol monomethyl ether acetate, propylene glycol monomethyl ether, cyclohexanone) contained in the resin composition of the present invention. The polymerization is more preferably performed using the same solvent as the later-described solvent contained in the resist composition of the present invention. By the use of the same solvent, production of particles during storage can be suppressed.

With respect to details of the polymerization method, purification method and the like, the methods described, for example, in “Kobunshi Gosei (Polymer Synthesis)” of Dai 5-Han Jikken Kagaku Koza 26, Kobunshi Kagaku (Experimental Chemistry Lecture 26, Polymer Chemistry, 5th Edition), Chapter 2, Maruzen can be used.

### [1-3] Resin (A3) Capable of Increasing the Solubility for an Alkali Developer by the Action of an Acid

The chemical amplification resist composition of the third invention of the present invention contains (A3) a resin capable of increasing the solubility for an alkali developer by the action of an acid (hereinafter, sometimes simply referred to as a “resin (A3)”).

The chemical amplification resist composition of the third invention of the present invention is suitable for exposure to KrF excimer laser light, electron beam, X-ray or high-energy ray at a wavelength of 50 nm or less (e.g., EUV), and the resin (A3) preferably contains a hydroxystyrene repeating unit represented by the following formula (3-I):

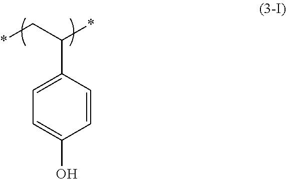

In the present invention, the content of the hydroxystyrene repeating unit above is preferably from 5 to 95 mol %, more preferably from 10 to 90 mol %, still more preferably from 20 to 80 mol %, based on all repeating units in the resin (A3).

In the present invention, the resin (A3) is preferably a copolymer containing the hydroxystyrene repeating unit above and a hydroxystyrene repeating unit protected by a group capable of leaving by the action of an acid, a copolymer containing the hydroxystyrene repeating unit and a tertiary alkyl (meth)acrylate repeating unit, or a copolymer containing the hydroxystyrene repeating unit, a hydroxystyrene repeating unit protected by a group capable of leaving by the action of an acid, and a tertiary alkyl (meth)acrylate repeating unit.

In the present invention, when the resin (A3) contains a hydroxystyrene repeating unit protected by a group capable of leaving by the action of an acid, the repeating unit is preferably a repeating unit represented by the following formula (A-1):

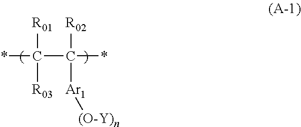

In formula (A-1), each of R₀₁, R₀₂ and R₀₃ independently represents a hydrogen atom, an alkyl group, a cycloalkyl group, a halogen atom, a cyano group or an alkoxycarbonyl group.

Ar₁ represents an (n+1)-valent aromatic ring group.

R₀₃ may also represent an alkylene group and combine with Ar₁ to form a 5- or 6-membered ring together with the —C≡C— chain. In this case, Ar₁ represents an (n+2)-valent aromatic ring group.

Each Y independently represents a hydrogen atom or a group capable of leaving by the action of an acid. When n is an integer of 2 or more, each Y may be the same as or different from every other Y. However, at least one Y represents a group capable of leaving by the action of an acid.

n represents an integer of 1 to 4 and is preferably 1 or 2, more preferably 1.

R₀₁, R₀₂, R₀₃, Ar₁, Y and n of formula (A-1) in the resin (A3) have the same meanings as R₀₁, R₀₂, R₀₃, Ar₁, Y and n of formula (A-1) in the resin (A2), and preferred ranges are also the same.

In the present invention, the content of the repeating unit represented by formula (A-1) is preferably from 3 to 90 mol %, more preferably from 5 to 80 mol %, still more preferably from 7 to 70 mol %, based on all repeating units in the resin (A3).

Specific examples of the repeating unit represented by formula (A-1) in resin (A3) are the same as specific examples of the repeating unit represented by formula (A-1) in resin (A2).

In the present invention, when the resin (A3) contains a tertiary alkyl (meth)acrylate repeating unit, the repeating unit is preferably a repeating unit represented by the following formula (X):

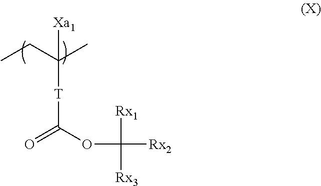

In formula (X), Xa₁ represents a hydrogen atom or an alkyl group.

T represents a single bond or a divalent linking group.

Each of Rx₁ to Rx₃ independently represents an alkyl group or a cycloalkyl group. Two members out of Rx₁ to Rx₃ may combine with each other to form a cycloalkyl group.

Xa₁, T and Rx₁ to Rx₃ of formula (X) in the resin (A3) have the same meanings as Xa₁, T and Rx₁ to Rx₃ of formula (X) in the resin (A2), and preferred ranges are also the same.

Specific examples of the repeating unit represented by formula (X) in the resin (A3) are the same as specific examples of the repeating unit represented by formula (X) in the resin (A2).

In the present invention, the repeating unit represented by formula (X) is preferably represented by the following formula (3-II):

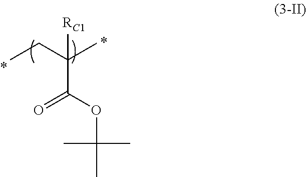

In formula (3-II), R_{C1} represents a hydrogen atom or a methyl group which may have a substituent.

Examples of the substituent in the methyl group which may have a substituent, represented by R_{C1}, include a halogen atom and a hydroxyl group. Specific examples of R_{C1} include a hydrogen atom, a methyl group, a trifluoromethyl group and a hydroxymethyl group. Among these, a hydrogen atom and a methyl group are preferred, and a methyl group is more preferred.

In the resin (A3), the content of the repeating unit represented by formula (X) is preferably from 3 to 90 mol %, more preferably from 5 to 80 mol %, still more preferably from 7 to 70 mol %, based on all repeating units in the resin (A3).

In the present invention, the resin (A3) that is suitable for exposure to KrF excimer laser light, electron beam, X-ray or high-energy ray at a wavelength of 50 nm or less (e.g., EUV) may contain a repeating unit other than the repeating units described above. Examples of such a repeating unit include a repeating unit stable to an acid, and a repeating unit having a lactone structure, which are described below.

More specifically, the repeating unit stable to an acid includes a repeating unit having a non-acid-decomposable aryl structure or cycloalkyl structure in the side chain of an acrylic structure, as exemplified below by formula (V). By having such a structure, adjustment of contrast, enhancement of etching resistance, and the like can be expected to be achieved.

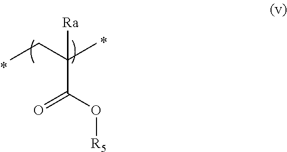

In formula (V), R₅ represents a non-acid-decomposable hydrocarbon group.

Ra represents a hydrogen atom, an alkyl group or a —CH₂—O—Ra₂ group, wherein Ra₂ represents a hydrogen atom or an alkyl group.

R₅, Ra and Ra₂ of formula (V) in the resin (A3) have the same meanings as R₅, Ra and Ra₂ of formula (V) in the resin (A2), and preferred ranges are also the same.

In the present invention, the repeating unit represented by formula (V) is preferably represented by the following formula (3-III):

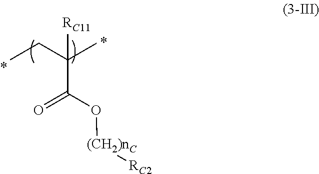

In formula (3-III), R_{C11} represents a hydrogen atom or a methyl group which may have a substituent.

R_{C2} represents a phenyl group which may have a substituent, or a cyclohexyl group which may have a substituent.

n_{C} represents an integer of 0 to 2.

Examples of the substituent in the methyl group which may have a substituent, represented by R_{C11}, are the same as those of the substituent in the methyl group which may have a substituent, represented by R_{C1}, and specific examples and preferred groups of R_{C11} are the same as specific examples and preferred groups of R_{C1}.

Examples of the substituent in the phenyl group or cyclohexyl group which may have a substituent, represented by R_{C2}, are the same as those described above as the substituent which R₅ in formula (V) may further have. Particularly preferred substituents include an alkyl group having a carbon number of 1 to 4, a cycloalkyl group having a carbon number of 3 to 10, an aryl group having a carbon number of 6 to 10, and a halogen atom such as fluorine atom and chlorine atom.

In the case where the phenyl group or cyclohexyl group represented by R_{C2} has a substituent, the substituent is preferably substituted on the 4-position of the phenyl group or cyclohexyl group.

In view of etching resistance, R_{C2} is preferably a phenyl group which may have a substituent.

In view of the preferred glass transition temperature (Tg) of the resin in pattern formation, n_{C} is preferably 1.

In general, when the resin contains a repeating unit represented by formula (3-III), the sidelobe resistance is improved and the surface profile at the pattern formation becomes uniformly flat. However, it is known that a basic compound combined greatly effects the sidelobe resistance. The sidelobe resistance is more improved by combining the basic compound of the present invention.

When a contact hole pattern is formed using a resist composition employing the resin containing a repeating unit represented by formula (3-III), there arises a problem that the cross-sectional profile of the pattern is liable to have a tapered shape. In particular, when the depth of focus is changed from the optimal depth of focus to the minus side (defocused), since the pattern is resolved faithfully following an optical image, a tapered shape is readily formed in the region having a low optical contrast. To solve this problem, a basic compound represented by formula (3-IV) shown later is used, whereby even in the formation of a contact hole pattern, not only the above-described effect thanks to the repeating unit represented by formula (3-III) can be obtained but also a pattern having a good cross-sectional profile can be formed. Once a good cross-sectional profile is formed, the profile at DOF is improved and in turn, DOF is broadened, as a result, EDW is increased.

The content of the repeating unit represented by formula (V) is preferably from 1 to 40 mol %, more preferably from 2 to 20 mol %, based on all repeating units in the resin (A3).

Specific examples of the repeating unit represented by formula (V) in the resin (A3) are the same as specific examples of the repeating unit represented by formula (V) in the resin (A2).

The resin (A3) may contain repeating units derived from other polymerizable monomers, in addition to the above-described repeating units. Examples of other polymerizable monomers include a compound having at least one addition-polymerizable unsaturated bond selected from (meth)acrylic acid esters, (meth)acrylamides, allyl compounds, vinyl ethers, vinyl esters, styrenes and crotonic acid esters. Other polymerizable monomers also include maleic anhydride, maleimide, acrylonitrile, methacrylonitrile and maleylonitrile.

Specific preferred examples of the repeating units derived from those other polymerizable monomers are illustrated below, but the present invention is not limited thereto.

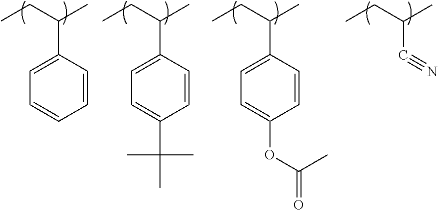

The content of the repeating unit derived from other polymerizable monomers is generally 50 mol % or less, preferably 30 mol % or less, based on all repeating units in the resin (A3).

In the present invention, the resin (A3) preferably contains a repeating unit represented by formula (3-I), a repeating unit represented by formula (A-1) or (X) and a repeating unit represented by formula (V).

In the present invention, the contents of the repeating unit represented by formula (3-I), the repeating unit represented by formula (A-1) or (X) and the repeating unit represented by formula (V) in the resin (A3) are preferably from 45 to 80 mol %, from 15 to 50 mol % and from 5 to 20 mol %, respectively, more preferably from 50 to 70 mol %, from 20 to 35 mol % and from 5 to 15 mol %, respectively, based on all repeating units in the resin (A3). Within these ranges, the composition can be a chemical amplification resist composition with higher sidelobe resistance.

The resin (A3) is preferably a resin composed of only a repeating unit represented by formula (3-I), a repeating unit represented by formula (A-1) or (X) and a repeating unit represented by formula (V), in other words, a resin where the total content of these repeating units in the resin (A3) is 100 mol % based on all repeating units in the resin (A3).

In the present invention, the resin (A3) more preferably contains a repeating unit represented by formula (3-I), a repeating unit represented by formula (3-II) and a repeating unit represented by (3-III):

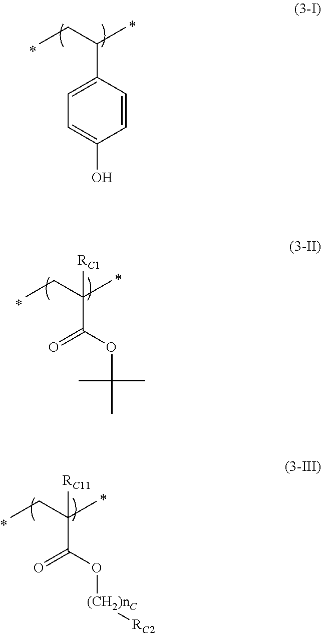

In formulae (3-II) and (3-III), the definitions and preferred ranges of R_{C1}, R_{C11}, R_{C2} and n_{C} are the same as those of R_{C1}, R_{C11}, R_{C2} and n_{C} described above for formulae (3-II) and (3-III).

In the present invention, the contents of the repeating unit represented by formula (3-I), the repeating unit represented by formula (3-II) and the repeating unit represented by formula (3-III) in the resin (A3) are preferably from 45 to 80 mol %, from 15 to 50 mol % and from 5 to 20 mol %, respectively, more preferably from 50 to 70 mol %, from 20 to 35 mol % and from 5 to 15 mol %, respectively, based on all repeating units in the resin (A3). In these ranges, the composition can be a chemical amplification resist composition with more enlarged EDW.

The resin (A3) is preferably a resin composed of only the repeating units represented by formulae (3-I) to (3-III), in other words, a resin where the total content of the repeating units represented by formulae (3-I) to (3-III) in the resin (A3) is 100 mol % based on all repeating units in the resin (A3).

Specific examples of the resin (A3) are the same as specific examples of the resin (A2).

The content of the group capable of decomposing by the action of an acid is calculated according to the formula B/(B+S) using the number (B) of groups capable of decomposing by the action of an acid and the number (S) of alkali-soluble groups not protected by a group capable of leaving by the action of an acid, in the resin. The content is preferably from 0.01 to 0.7, more preferably from 0.05 to 0.50, still more preferably from 0.05 to 0.40.

The chemical amplification resist composition of the third invention of the present invention may contain two or more kinds of resins. In this case, the composition may contain two or more kinds of resins (A3) or may contain, in addition to one or more kinds of resins (A3), one or more kinds of resins other than the resin (A3) within the range not impairing the effects of the present invention. The resin other than the resin (A3) is not particularly limited, and known resins may be used, but examples thereof include a PHS (poly-para-hydroxystyrene)-based resin protected by an acid-decomposable group, and a tertiary (meth)acrylate copolymer. Examples of the acid-decomposable group include an acetal group, a tert-butoxycarbonyl group, a tert-butoxycarbonylethyl group and a tert-butoxy group. Examples of the tertiary (meth)acrylate include tert-butoxy (meth)acrylate, ethylcyclohexyl (meth)acrylate and ethylcyclopentyl (meth)acrylate.

The content of the resin (A3) is not particularly limited but is, when containing two or more kinds of the resins, as a total amount, preferably from 20 to 99 mass %, more preferably from 30 to 98 mass %, based on the entire solid content of the chemical amplification resist composition of the third invention of the present invention.

The weight average molecular weight (Mw) of the resin (A3) for use in the present invention is preferably from 3,000 to 100,000, more preferably from 5,000 to 50,000, still more preferably from 10,000 to 30,000. This range is preferred because when the molecular weight is 100,000 or less, the dissolution rate for an alkali developer is not excessively reduced and good resolution can be achieved, and when the molecular weight is 3,000 or more, the dissolution rate is not excessively increased and the film loss can be successfully suppressed.

The polydispersity (Mw/Mn) of the resin (A3) is preferably from 1.0 to 3.0, more preferably from 1.0 to 2.0.

Here, the weight average molecular weight (Mw) and polydispersity (Mw/Mn) of the resin are determined by GPC (gel permeation chromatography) (solvent: THF) with a polystyrene standard.

Examples of the polymerization method for producing the resin (A3) are the same as those of the polymerization method for producing the resin (A2).

[2] (B) Compound Capable of Generating an Acid Upon Irradiation with an Actinic Ray or Radiation

The composition of the present invention contains (B) a compound capable of generating an acid upon irradiation with an actinic ray or radiation (hereinafter, sometimes referred to as an “acid generator (B)”). The acid generator (B) is preferably a compound capable of generating a fluorine atom-containing acid. When the acid generated has a fluorine atom, the acid is a strong acid and therefore, the deprotection reaction of the resins (A1) to (A3) more proceeds, as a result, resolution or pattern removability at -DOF are enhanced.

The acid generator (B) is preferably an onium salt, and the cation of the onium salt is preferably a sulfonium cation or an iodonium cation, more preferably a sulfonium cation.

The counter anion of the onium cation is preferably an alkyl sulfonate anion, an arylsulfonate anion, or a fluorine atom-containing sulfonate anion, more preferably an alkylsulfonate anion substituted with a fluorine atom or an arylsulfonate anion substituted with a fluorine atom or an alkyl fluoride group.

The alkylsulfonate anion substituted with a fluorine atom is preferably a perfluoroalkylsulfonate anion having a carbon number of 1 to 8, more preferably a perfluoroalkylsulfonate anion having a carbon number of 2 to 6.

The aryl group of the arylsulfonate anion substituted with a fluorine atom or an alkyl fluoride group is preferably an aryl group having a carbon number of 6 to 14, more preferably a phenyl group.

The alkyl fluoride group substituted on the aryl group is preferably a perfluoroalkyl group having a carbon number of 1 to 8, more preferably a perfluoroalkyl group having a carbon number of 1 to 4.

The counter anion may have a substituent other than a fluorine atom or an alkyl fluoride group. Specific examples of the substituent include an alkyl group (preferably having a carbon number of 1 to 8), a cycloalkyl group (preferably having a carbon number of 3 to 8), an alkoxy group (preferably having a carbon number of 1 to 8) and an alkylthio group (preferably having a carbon number of 1 to 8), but the substituent is not particularly limited.

The component (B) more specifically includes a compound represented by the following formula (Z1) or (ZII):

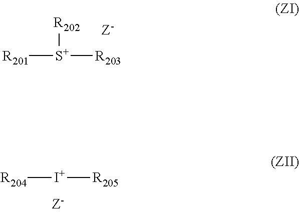

In formula (ZI), each of R₂₀₁, R₂₀₂ and R₂₀₃ independently represents an organic group.

Z⁻ represents a non-nucleophilic anion, and preferred examples thereof include a sulfonate anion, a bis(alkylsulfonyl)imide anion and a tris(alkylsulfonyl)methide anion. These anions are preferably substituted with a fluorine atom, and the above-described fluorine atom-containing organic anion (that is, an alkylsulfonate anion substituted with a fluorine atom, an arylsulfonate anion substituted with a fluorine atom or an alkyl fluoride group, or the like) is more preferred.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group.

Examples of the group formed by combining two members out of R₂₀₁ to R₂₀₃ include an alkylene group (e.g., butylene, pentylene).

The compound may be a compound having a plurality of structures represented by formula (ZI), for example, may be a compound having a structure where at least one of R₂₀₁ to R₂₀₃ in a compound represented by formula (ZI) is bonded to at least one of R₂₀₁ to R₂₀₃ in another compound represented by formula (ZI).

Examples of the organic group of R₂₀₁, R₂₀₂ and R₂₀₃ include an aryl group (preferably having a carbon number of 6 to 15), a linear or branched alkyl group (preferably having a carbon number of 1 to 10), and a cycloalkyl group (preferably having a carbon number of 3 to 15).

At least one of three members R₂₀₁, R₂₀₂ and R₂₀₃ is preferably an aryl group, and it is more preferred that these members all are an aryl group. The aryl group may be also a heteroaryl group such as indole residue and pyrrole residue, other than a phenyl group, a naphthyl group and the like.

Each of the aryl group, alkyl group and cycloalkyl group as R₂₀₁, R₂₀₂ and R₂₀₃ may further have a substituent, and examples of the substituent include, but are not limited to, a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7).

Also, two members selected from R₂₀₁, R₂₀₂ and R₂₀₃ may combine through a single bond or a linking group. Examples of the linking group include, but are not limited to, an alkylene group (preferably having a carbon number of 1 to 3), —O—, —S—, —CO— and —SO₂—.

Preferred structures when at least one of R₂₀₁, R₂₀₂ and R₂₀₃ is not an aryl group include cation structures such as compounds described in paragraphs 0046 and 0047 of JP-A-2004-233661 and paragraphs 0040 to 0046 of JP-A-2003-35948, Compounds (1-1) to (I-70) illustrated in U.S. Patent Application Publication No. 2003/0224288A1, and Compounds (IA-1) to (IA-54) and (IB-1) to (IB-24) illustrated in U.S. Patent Application Publication No. 200310077540A1. In particular, when at least one of R₂₀₁, R₂₀₂ and R₂₀₃ is not an aryl group, the following embodiment (1) or (2) is preferred.

(1) Embodiment where at Least One of R₂₀₁, R₂₀₂ and R₂₀₃ is a Structure Represented by Ar—CO—X— and Remaining Two Members are a Linear or Branched Alkyl Group or a Cycloalkyl Group

In this case, the remaining two linear or branched alkyl groups or cycloalkyl groups may combine with each other to form a ring structure. Here, Ar represents an aryl group which may have a substituent, and is specifically the same as the aryl group of R₂₀₁, R₂₀₂ and R₂₀₃. A phenyl group which may have a substituent is preferred.

X represents an alkylene group which may have a substituent, and is specifically an alkylene group having a carbon number of 1 to 6. An alkylene group having a linear or branched structure with a carbon number of 1 to 3 is preferred.

The remaining two linear or branched alkyl groups or cycloalkyl groups preferably have a carbon number of 1 to 6. Such an atomic group may further have a substituent. Also, it is preferred that these groups are combined with each other to form a ring structure (preferably a 5- to 7-membered ring).

Examples of the substituent which each of the groups above may have are the same as those of the substituent which the aryl group, alkyl group and cycloalkyl group of R₂₀₁, R₂₀₂ and R₂₀₃ may have.

(2) Embodiment where at Least One of R₂₀₁, R₂₀₂ and R₂₀₃ is an Aryl Group which May Have a Substituent and Remaining Two Members are a Linear or Branched Alkyl Group or a Cycloalkyl Group

In this case, the aryl group is specifically the same as the aryl group of R₂₀₁, R₂₀₂ and R₂₀₃ and is preferably a phenyl group or a naphthyl group. Also, the aryl group preferably has any of a hydroxyl group, an alkoxy group and an alkyl group, as a substituent. The substituent is more preferably an alkoxy group having a carbon number of 1 to 12, still more preferably an alkoxy group having a carbon number of 1 to 6.

The remaining two linear or branched alkyl groups or cycloalkyl groups preferably have a carbon number of 1 to 6. Such a group may further have a substituent. Also, these groups may combine with each other to form a ring structure.

Examples of the substituent which the alkyl group or cycloalkyl group above may have are the same as those of the substituent which the aryl group, alkyl group and cycloalkyl group of R₂₀₁, R₂₀₂ and R₂₀₃ may have.

In formula (ZII), each of R₂₀₄ and R₂₀₅ independently represents an aryl group, an alkyl group or a cycloalkyl group.

The aryl group, alkyl group and cycloalkyl group of R₂₀₄ and R₂₀₅ are the same as those described as the aryl group, alkyl group and cycloalkyl group of R₂₀₁ to R₂₀₃ in compound (ZI).

The aryl group, alkyl group and cycloalkyl group of R₂₀₄ and R₂₀₅ may have a substituent. Examples of the substituent include those which the aryl group, alkyl group and cycloalkyl group of R₂₀₁ to R₂₀₃ in formula (ZI) may have.

Z⁻ has the same meaning as Z⁻ in formula (ZI).

Preferred examples of the component (B) are illustrated below but are not limited thereto.

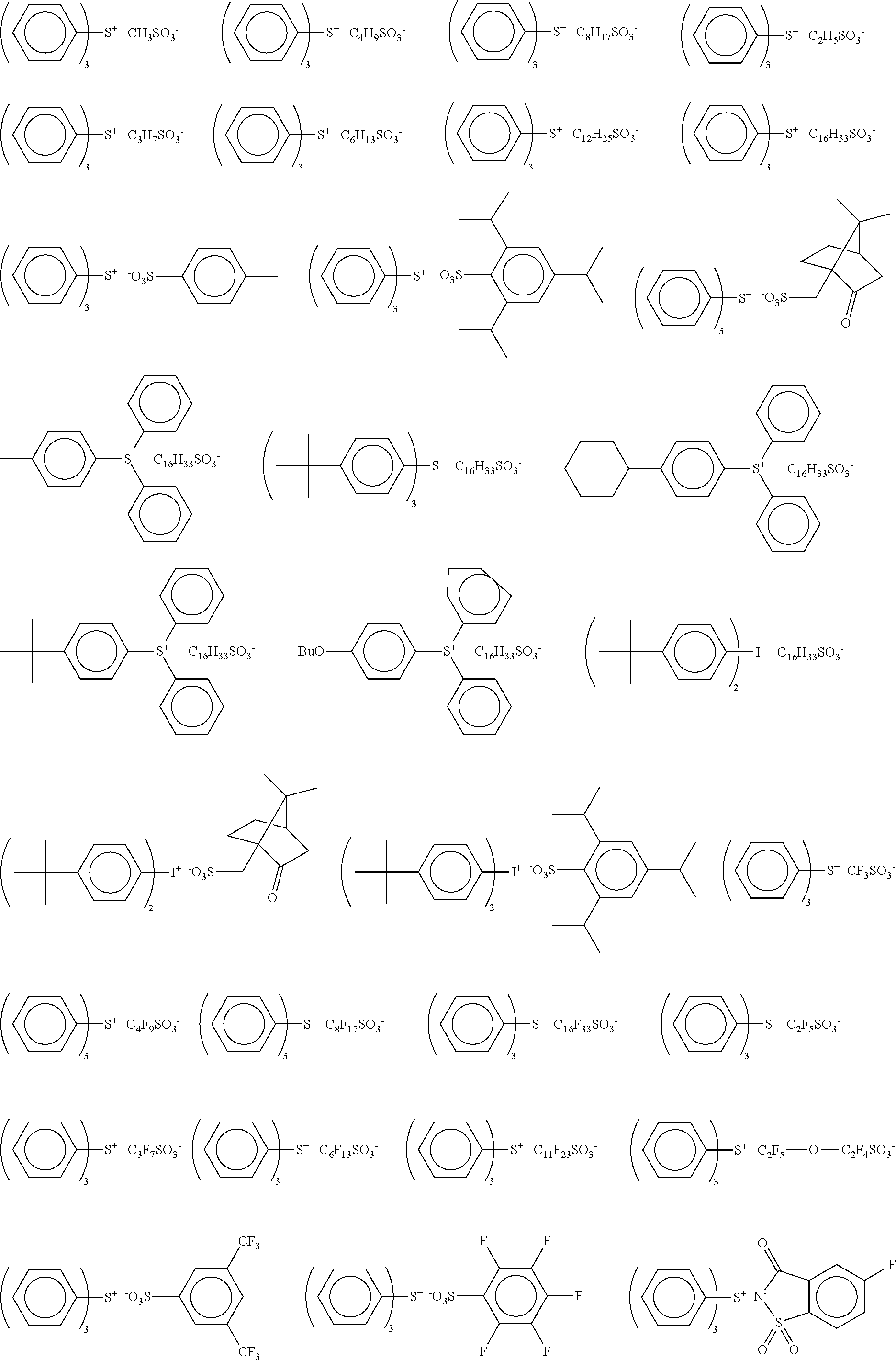

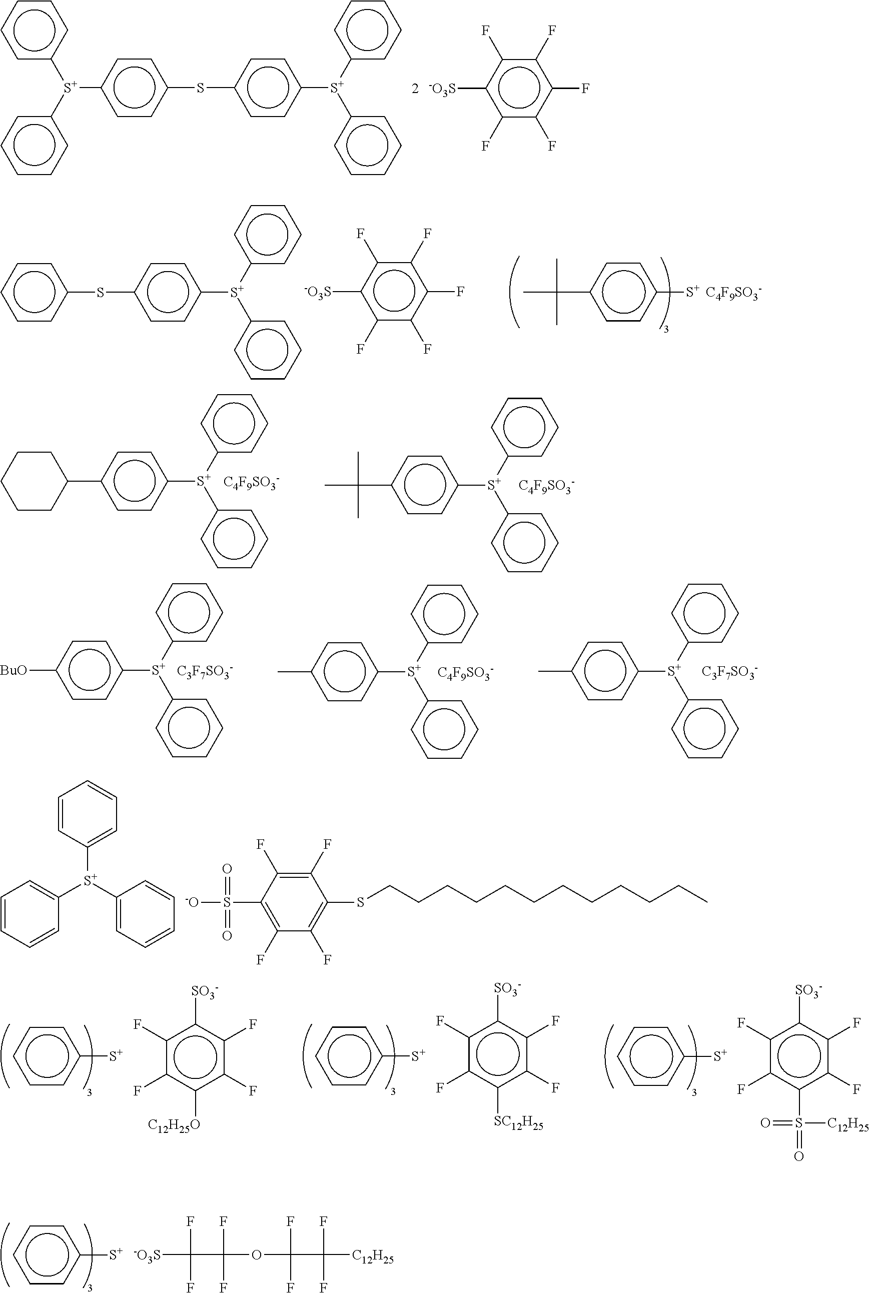

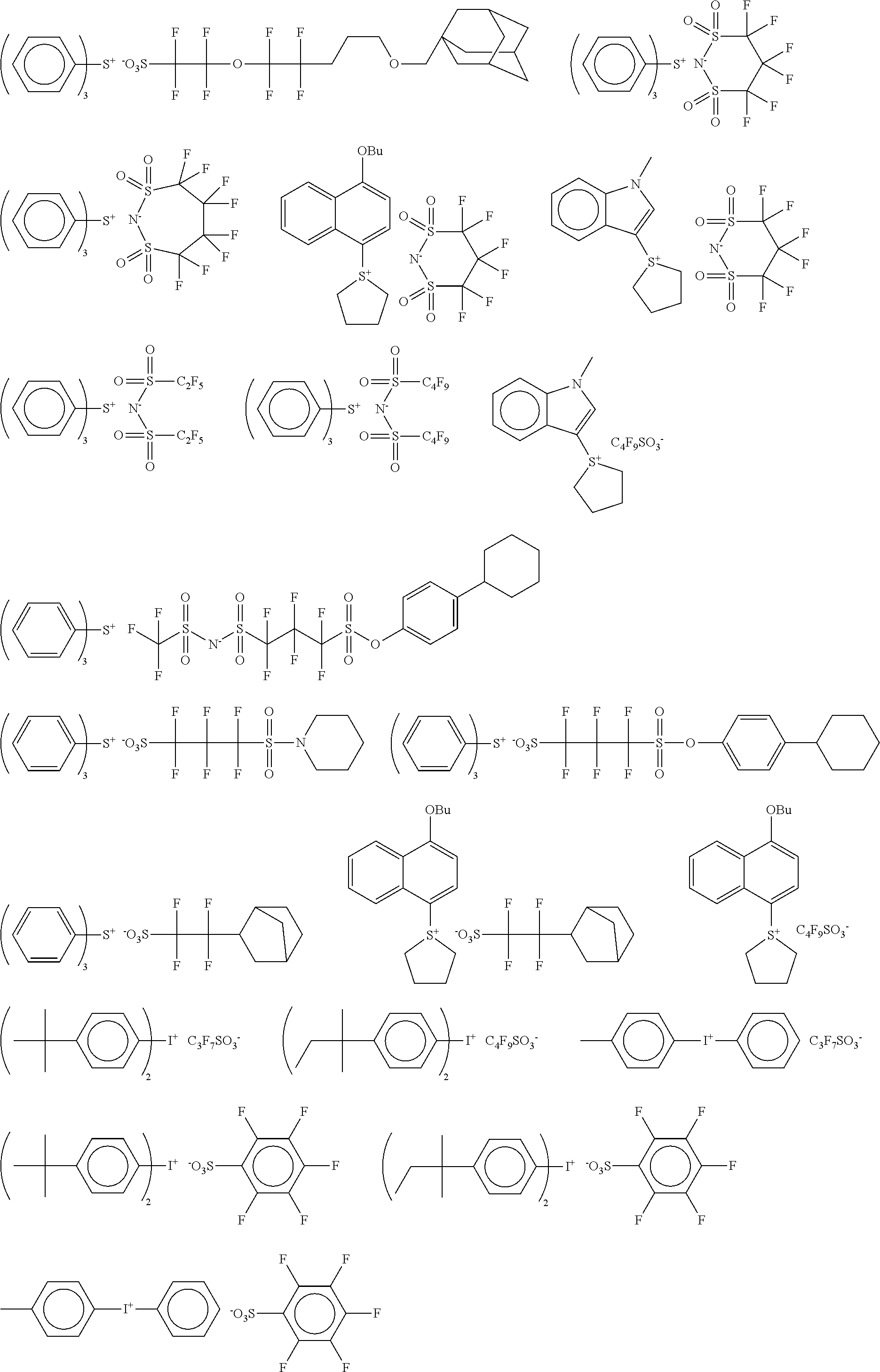

The content of the component (B) is preferably from 0.5 to 25 mass %, more preferably from 0.5 to 15 mass %, still more preferably from 1.0 to 15 mass %, yet still more preferably from 1.0 to 10 mass %, based on the entire solid content of the composition.

[(B′) Compound Capable of Generating an Acid Other than an Onium Salt Upon Irradiation with an Actinic Ray or Radiation]

The composition of the present invention may further contain (B′) a compound capable of generating an acid other than an onium salt upon irradiation with an actinic ray or radiation (hereinafter, sometimes referred to as an “acid generator (B′)”).

The acid generator (B′) is preferably a diazodisulfone compound or an oxime ester compound.

The acid generator (B′) more specifically includes a diazodisulfone compound represented by the following formula (ZIII′):

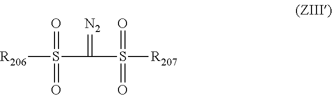

In formula (ZIII′), each of R₂₀₆ and R₂₀₇ independently represents an alkyl group, a cycloalkyl group or an aryl group and may have a substituent.

The alkyl group includes a linear or branched alkyl group having a carbon number of 1 to 16 (preferably from 1 to 10).

The cycloalkyl group includes a monocyclic or polycyclic cycloalkyl group having a carbon number of 6 to 20 (preferably from 6 to 10).

The aryl group includes an aryl group having a carbon number of 6 to 20 (preferably from 6 to 10).

Examples of the substituent which R₂₀₆ and R₂₀₇ may further have include those described above as the substituent which the aryl group, alkyl group and cycloalkyl group as R₂₀₁, R₂₀₂ and R₂₀₃ may have.

Preferred examples of the diazodisulfone compound represented by formula (ZIII′) are illustrated below but are not limited thereto.

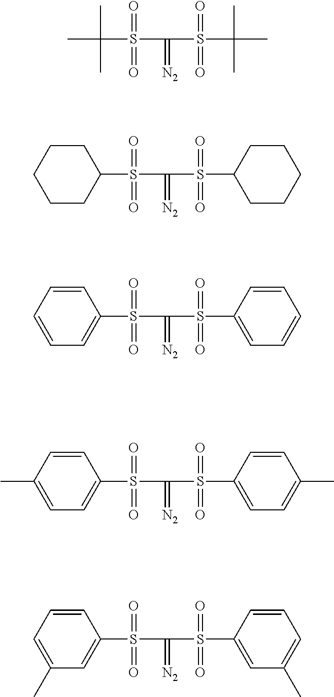

Oxime ester compounds illustrated below may be also used as the acid generator (B′).

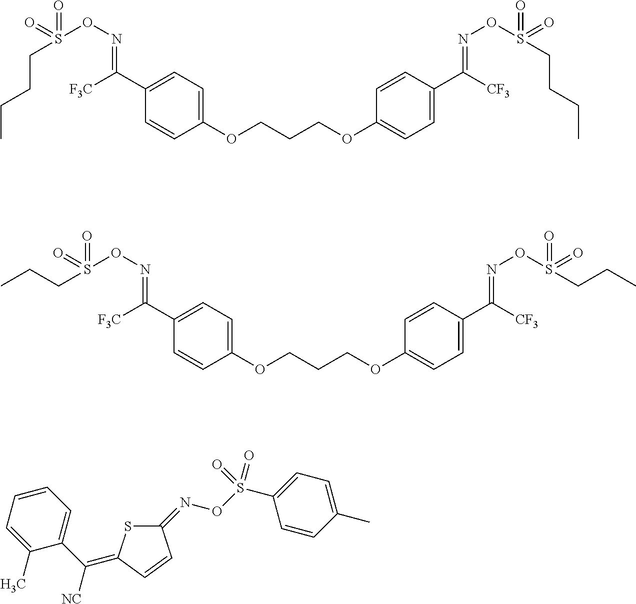

The composition of the present invention may or may not contain the acid generator (B′), but in the case of containing the acid generator (B′), the content thereof in the composition is preferably from 0.1 to 5.0 mass %, more preferably from 0.5 to 3 mass %, based on the entire solid content concentration.

In the case where containing two kinds of acid generators (B), the composition of the present invention may contain, for example, one kind of an acid generator (B) and one kind of an acid generator (B′).

The ratio between the acid generator (B) and the acid generator (B′) used in combination is preferably from 95:5 to 50:50, more preferably from 85:15 to 60:40. Also, in the case of containing two kinds of acid generators (B), one acid generator (B) is preferably contained in an amount of 5 mass % or more, more preferably 15 mass % or more, based on those two kinds of acid generators (B).

### [3] Basic Compounds (C1) to (C3)

The basic compound (C1) contained in the actinic ray-sensitive or radiation-sensitive resin composition of the first invention of the present invention, the basic compound (C2) contained in the actinic ray-sensitive or radiation-sensitive resin composition of the second invention of the present invention, and the basic compound (C3) contained in the chemical amplification resist composition of the third invention of the present invention are described below.

### [3-1] (C1) Basic Compound

The actinic ray-sensitive or radiation-sensitive resin composition of the first invention of the present invention contains (C1) a basic compound represented by the following formula (1-IV):

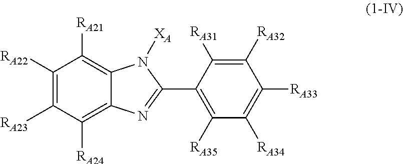

In formula (1-IV), each of R_{A21}, R_{A22}, R_{A23}, R_{A24}, R_{A31}, R_{A32}, R_{A33}, R_{A34} and R_{A35} independently represents a hydrogen atom, an alkyl group, an alkoxy group or an aralkyl group, preferably a hydrogen atom or an alkyl group.

X_{A} represents a hydrogen atom, an alkyl group, an aryl group or an aralkyl group.

The carbon number of the alkyl group as R_{A21}, R_{A22}, R_{A23}, R_{A24}, R_{A31}, R_{A32}, R_{A33}, R_{A34} and R_{A35} is not particularly limited but is preferably from 1 to 20, more preferably from 1 to 12, still more preferably from 1 to 4.

The carbon number of the alkoxy group as R_{A21}, R_{A22}, R_{A23}, R_{A24}, R_{A31}, R_{A32}, R_{A33}, R_{A34} and R_{A35} is not particularly limited but is preferably from 1 to 20, more preferably from 1 to 12, still more preferably from 1 to 4.

The carbon number of the aralkyl group as R_{A21}, R_{A22}, R_{A23}, R_{A24}, R_{A31}, R_{A32}, R_{A33}, R_{A34} and R_{A35} is not particularly limited but is preferably from 7 to 20, more preferably from 7 to 11, and specific examples of the aralkyl group include a benzyl group.

Each of R_{A21}, R_{A22}, R_{A23} and R_{A24} independently represents preferably a hydrogen atom or an alkyl group, more preferably a hydrogen atom. In another embodiment, it is also preferred that R_{A21} and R_{A24} represent a hydrogen atom and at the same time, each of R_{A22} and R_{A23} independently represents a hydrogen atom, an alkyl group or an aralkyl group. However, in this case, at least one of R_{A22} and R_{A23} represents an alkyl group or an aralkyl group. In view of balance of hydrophilicity and hydrophobicity, the above-described combination of substituents is preferred for R_{A21}, R_{A22}, R_{A23} and R_{A24}. Thanks to such a combination, particularly, the solubility in a developer is enhanced and in turn, the pattern profile is more improved.

Each of R_{A31}, R_{A32}, R_{A33}, R_{A34} and R_{A35} independently represents preferably a hydrogen atom or an alkyl group, more preferably a hydrogen atom. In another embodiment, it is also preferred that R_{A32} and R_{A34} represent a hydrogen atom and at the same time, each of R_{A31}, R_{A33} and R_{A35} independently represents a hydrogen atom, an alkyl group or an alkoxy group. However, in this case, at least one of R_{A31}, R_{A33} and R_{A35} represents an alkyl group or an alkoxy group. In view of balance of hydrophilicity and hydrophobicity, the above-described combination of substituents is preferred for R_{A31}, R_{A32}, R_{A33}, R_{A34} and R_{A35}. Thanks to such a combination, particularly, the solubility in a developer is enhanced and in turn, the pattern profile is more improved.

The alkyl group and aralkyl group represented by X_{A} are the same as the alkyl group and aralkyl group represented by R_{A21}, R_{A22}, R_{A23}, R_{A24}, R_{A31}, R_{A32}, R_{A33}, R_{A34} and R_{A35} above.

The carbon number of the aryl group as X_{A} is not particularly limited but is preferably from 6 to 20, more preferably from 6 to 10, and specific examples of the aryl group include a phenyl group and a naphthyl group.

X_{A} preferably represents a hydrogen atom, an alkyl group or an aryl group, more preferably a hydrogen atom or an alkyl group, still more preferably a hydrogen atom.

Specific examples of the basic compound (C1) for use in the present invention are illustrated below, but the present invention is not limited thereto.

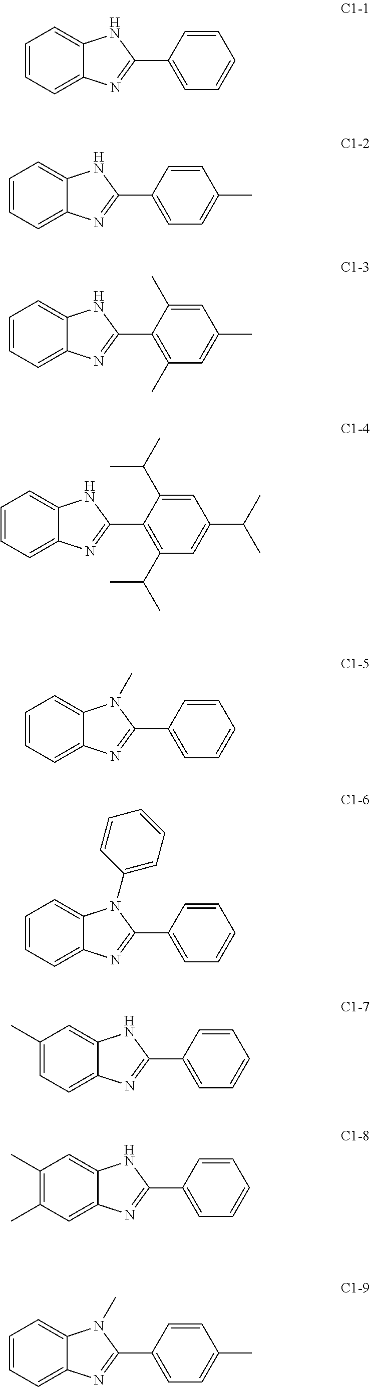

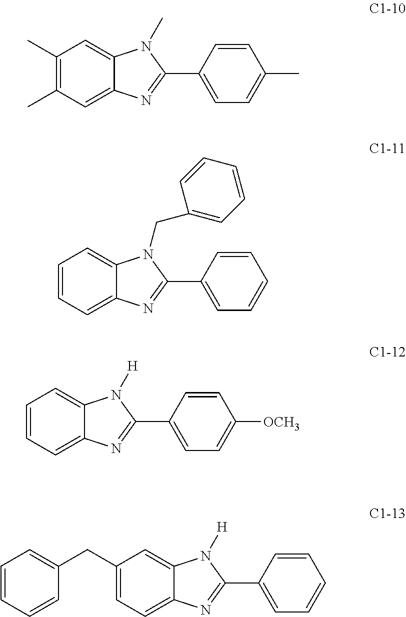

The basic compound represented by formula (1-IV) can be obtained by reacting benzimidazole and halobenzene or reacting 2-cyanobenzimidazole or 2-halobenzimidazole with an aryllithium or an aryl Grignard reagent. Also, some of these basic compounds are available from Tokyo Chemical Industry Co., Ltd., Wako Pure Chemical Industries, Ltd., and the like.

The molecular weight of the basic compound (C1) is generally from 100 to 1,000, preferably from 150 to 800.

The reason why at the contact hole pattern formation using a resin (A1) containing a repeating unit represented by formula (1-III), a pattern having a good cross-sectional profile can be formed by using the basic compound (C1) is not clearly known, but this is presumed as follows.

The acid generated upon exposure has a fixed collision probability of reacting with a basic compound as a quencher. In the case of conventional strongly basic compounds, the range of attracting acid by polarity is wide due to their strong polarity and this allows for a high collision probability with acid and readily leads to deactivation of acid. Accordingly, a tapered shape is liable to be formed in the region having a low optical contrast, such as minus defocus region, because the pattern is resolved faithfully following an optical image.

On the other hand, when a weakly basic compound like the basic compound (C1) of the present invention is applied as a quencher, the range of attracting acid by polarity is narrow due to its low polarity and the collision probability with acid decreases. Accordingly, it is considered that even in a film (typically a resist film) having a low optical contrast with minus defocus, the generated acid is not rapidly deactivated (quenched) but the acid remains and diffuses also into the lower part of the film, whereby the deprotection reaction of the acid-decomposable resin can be accelerated and a rectangular profile can be ensured.

As for the basic compound (C1), one kind of a compound may be used, or two or more kinds of compounds may be used in combination. The content of the basic compound (C1) is preferably from 0.001 to 10 mass %, more preferably from 0.01 to 5 mass %, based on the entire solid content of the actinic ray-sensitive or radiation-sensitive resin composition of the first invention of the present invention.

### [3-2] (C2) Basic Compound Represented by Formula (2-IV)

The actinic ray-sensitive or radiation-sensitive resin composition of the second invention of the present invention contains (C2) a basic compound represented by the following formula (2-IV):

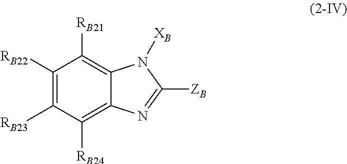

In the formula, each of R_{B21}, R_{B22}, R_{B23} and R_{B24} independently represents a hydrogen atom, an alkyl group, an alkoxy group or an aralkyl group.

X_{B} represents a hydrogen atom, an alkyl group or an aryl group, and Z_{B} represents a heterocyclic group.

The carbon number of the alkyl group as R_{B21}, R_{B22}, R_{B23} and R_{B24} is not particularly limited but is preferably from 1 to 20, more preferably from 1 to 12.

The carbon number of the alkoxy group as R_{B21}, R_{B22}, R_{B23} and R_{B24} is not particularly limited but is preferably from 1 to 20, more preferably from 1 to 12.

The carbon number of the aralkyl group as R_{B21}, R_{B22}, R_{B23} and R_{B24} is not particularly limited but is preferably from 7 to 20, more preferably from 7 to 11, and specific examples of the aralkyl group include a benzyl group.

The alkyl group as X_{B} includes those described for R_{B21}, R_{B22}, R_{B23} and R_{B24}.

The carbon number of the aryl group as X_{B} is not particularly limited but is preferably from 6 to 20, more preferably from 6 to 10, and specific examples of the aryl group include a phenyl group and a naphthyl group.

The heterocyclic group as Z_{B} is preferably a heterocyclic group having a carbon number of 2 to 20 and may be either a heteroatom-containing aromatic group or a heteroatom-containing alicyclic group but is preferably a heteroatom-containing aromatic group. A 5- or 6-membered ring is preferred. The heterocyclic group as Z_{B} is preferably a nitrogen-containing heterocyclic ring. Examples of the heterocyclic group as Z_{B} include a heterocyclic structure-containing group such as pyridine ring group, thiazole ring group, thiadiazole ring group, imidazole ring group, thiophene ring group, furan ring group, pyrrole ring group, thiirane ring group, cyclothiolane ring group, benzothiophene ring group, benzofuran ring group, benzopyrrole ring group, triazine ring group, benzimidazole ring group, triazole ring group and pyrrolidone ring group, but the ring structure is not limited thereto and may be sufficient if it is a structure generally called a heterocyclic ring (a ring composed of carbon and a heteroatom, or a ring composed of a heteroatom). The heterocyclic ring is preferably a pyridine ring group, a thiazole ring group, a thiadiazole ring group, an imidazole ring group, a thiophene ring group, a furan ring group or a pyrrole ring group.

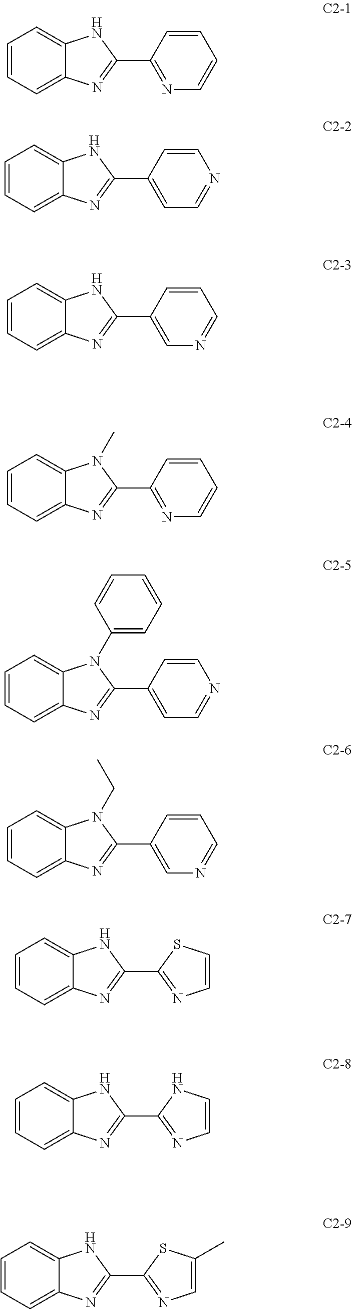

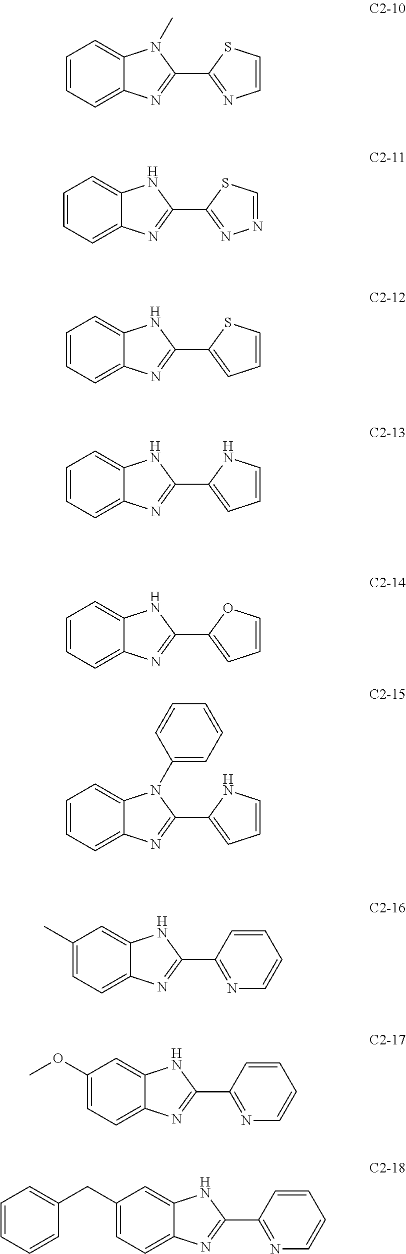

The basic compound represented by formula (2-IV) can be produced, for example, by reacting 2-bromobenzimidazole and a halogenated heterocyclic compound at a low temperature (for example, from −78° C. to 40° C.) in the presence of butyllithium.

The molecular weight of the basic compound represented by formula (2-IV) is preferably from 100 to 5,000, more preferably from 200 to 3,000.

In the present invention, content of the basic compound represented by formula (2-IV) is preferably from 0.001 to 10 mass %, more preferably from 0.01 to 5 mass %, based on the solid content of the actinic ray-sensitive or radiation-sensitive resin composition of the second invention of the present invention.

### [3-3] (C3) Basic Compound

The chemical amplification resist composition of the third invention of the present invention contains a basic compound represented by the following formula (3-IV):

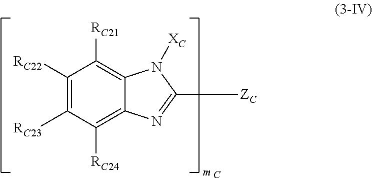

In formula (3-IV), each of R_{C21}, R_{C22}, R_{C23} and R_{C24} independently represents a hydrogen atom, an alkyl group, a cycloalkyl group, an alkoxy group or an aralkyl group, and when a plurality of R_{C21}'s, R_{C22}'s, R_{C23}'s or R_{C24}'s are present, each R_{C21}, R_{C22}, R_{C23} or R_{C24} may be the same as or different from every other R_{C21}, R_{C22}, R_{C23} or R_{C24}.

X_{C} represents a hydrogen atom, an alkyl group, an aryl group or an aralkyl group, and when a plurality of X_{c}'s are present, each X_{C} may be the same as or different from every other X_{C}.

m_{C} represents 1 or 2.

Z_{C} represents a mercapto group (—SH) when m_{C} is 1, and represents a sulfide group (—S—) or a disulfide group (—S—S—) when m_{C} is 2.

The carbon number of the alkyl group as R_{C21}, R_{C22}, R_{C23} and R_{C24} is not particularly limited but is preferably from 1 to 20, more preferably from 1 to 12, still more preferably from 1 to 4.

The carbon number of the cycloalkyl group as R_{C21}, R_{C22}, R_{C23} and R_{C24} is not particularly limited but is preferably from 3 to 20, more preferably from 5 to 15, still more preferably from 5 to 10.

The carbon number of the alkoxy group as R_{C21}, R_{C22}, R_{C23} and R_{C24} is not particularly limited but is preferably from 1 to 20, more preferably from 1 to 12, still more preferably from 1 to 4.

The carbon number of the aralkyl group as R_{C21}, R_{C22}, R_{C23} and R_{C24} is not particularly limited but is preferably from 7 to 20, more preferably from 7 to 11, and specific examples of the aralkyl group include a benzyl group.

Each of R_{C21}, R_{C22}, R_{C23} and R_{C24} independently represents preferably a hydrogen atom, an alkyl group or a cycloalkyl group, more preferably a hydrogen atom or an alkyl group, still more preferably a hydrogen atom. In another embodiment, it is also preferred that R_{C21} and R_{C24} represent a hydrogen atom and at the same time, each of R_{C22} and R_{C23} independently represents a hydrogen atom, an alkyl group, a cycloalkyl group, an alkoxy group or an aralkyl group, preferably a hydrogen atom, an alkyl group or a cycloalkyl group.

The alkyl group and aralkyl group represented by X_{C} are the same as the alkyl group and aralkyl group represented by R_{C21}, R_{C22}, R_{C23} and R_{C24} above.

The carbon number of the aryl group as X_{C} is not particularly limited but is preferably from 6 to 20, more preferably from 6 to 10, and specific examples of the aryl group include a phenyl group and a naphthyl group.

X_{C} preferably represents a hydrogen atom, an alkyl group or an aryl group, more preferably a hydrogen atom or an aryl group, still more preferably an aryl group.

m_{C} is the number of benzimidazole ring structures substituted on Z_{C} in formula (3-IV) and represents 1 or 2. That is, when m_{C} is 1, the basic compound represented by formula (3-IV) is a compound having one benzimidazole ring structure, and when m_{C} is 2, the basic compound represented by formula (3-IV) is a compound where two benzimidazole ring structures are connected by Z_{C}. Incidentally, when m_{C} is 2, two benzimidazole ring structures may be the same or different.

Z_{C} is, when m_{C} is 1, a mercapto group (—SH), which is a monovalent group, and when m_{C} is 2, a sulfide group (—S—) or a disulfide group (—S—S—), which are a divalent linking group, and connects two benzimidazole ring structures.

Specific examples of the basic compound (C3) for use in the present invention are illustrated below, but the present invention is not limited thereto.

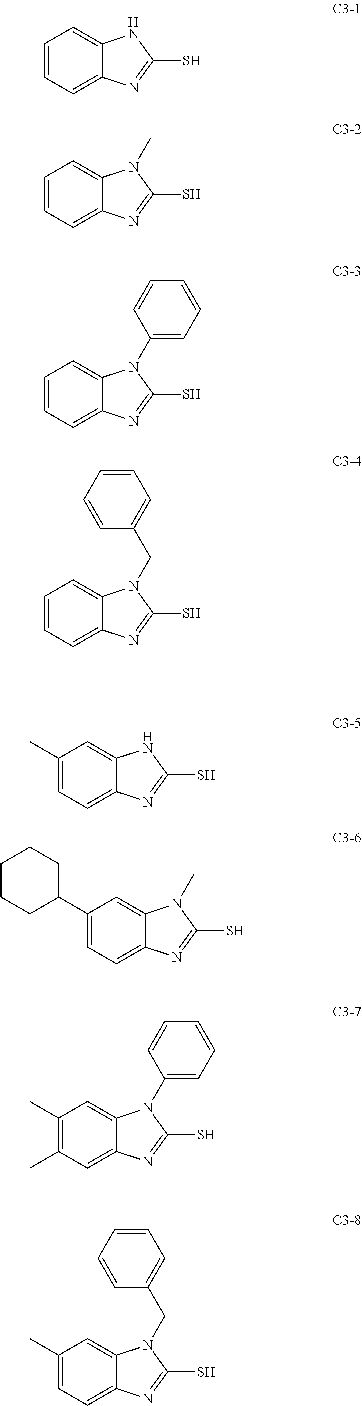

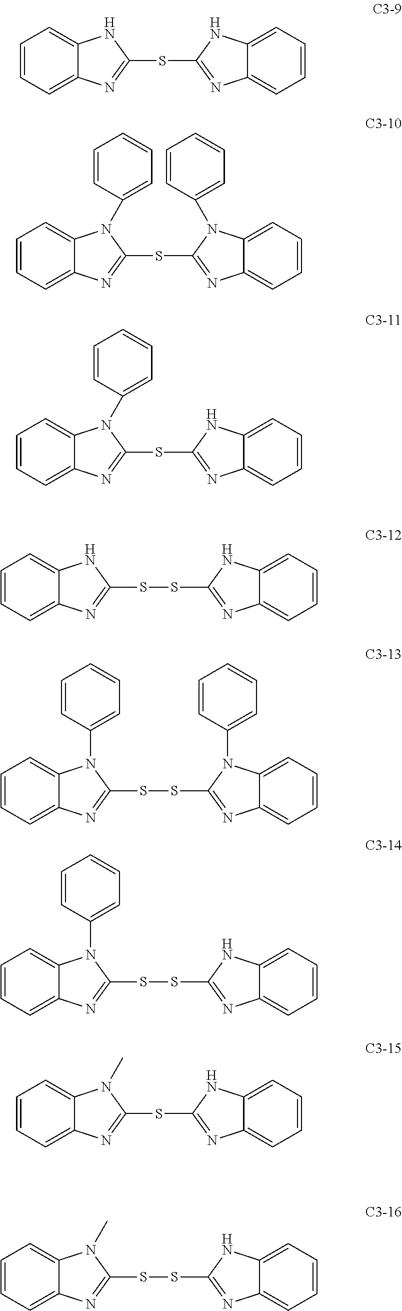

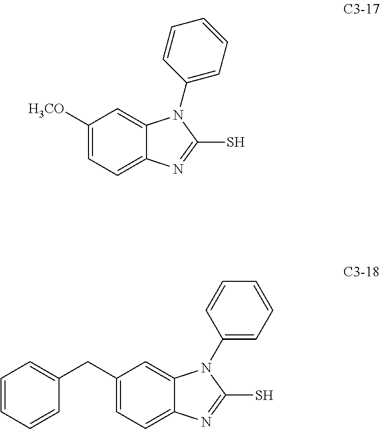

The basic compound represented by formula (3-IV) can be obtained by reacting a corresponding mercaptoimidazole and a halide compound. For example, Compound (C3-2) can be synthesized by reacting methyl bromide with Compound (C3-1) that is a commercial product, under alkali conditions. Compounds (C3-3) to (C3-18) can be also synthesized by the same synthesis method. As another method, the compound can be also synthesized by a cyclization condensation reaction of 1,2-dibromobenzene and mercaptomethyl-diamine. Furthermore, the disulfide compound such as (C3-12) to (C3-14) and (C3-16) can be synthesized by reductive coupling (for example, a reaction in the presence of NaBH₄) of a corresponding mercapto compound. Incidentally, as Basic Compound (C3-1), a commercial product available from, for example, Ouchi Shinko Chemical Industrial Co., Ltd. may be also used.

The molecular weight of the basic compound (C3) is generally from 100 to 1,000, preferably from 150 to 800.

As for the basic compound (C3), one kind of a compound may be used, or two or more kinds of compounds may be used in combination. The content of the basic compound (C3) is preferably from 0.001 to 10 mass %, more preferably from 0.01 to 5 mass %, based on the entire solid content of the chemical amplification resist composition of the third invention of the present invention.

### [4] (D) Another Basic Compound

The composition of the present invention may further use a basic compound (hereinafter, sometimes referred to as a “basic compound (D)”) other than the basic compounds (C1) to (C3), in combination.

The basic compound (D) used in combination is preferably a nitrogen-containing organic basic compound. The compound which can be used in combination is not particularly limited but, for example, compounds classified into the following (1) to (4) are preferably used.

### (1) Compound Represented by the Following Formula (BS-1):

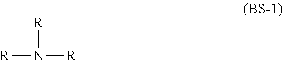

In formula (BS-1), each R independently represents any of a hydrogen torn, an alkyl group (linear or branched), a cycloalkyl group (monocyclic or polycyclic), an aryl group and an aralkyl group, but it is excluded that three R's all are a hydrogen atom.

The carbon number of the alkyl group as R is not particularly limited but is usually from 1 to 20, preferably from 1 to 12.

The carbon number of the cycloalkyl group as R is not particularly limited but is usually from 3 to 20, preferably from 5 to 15.

The carbon number of the aryl group as R is not particularly limited but is usually from 6 to 20, preferably from 6 to 10. Specific examples of the aryl group include a phenyl group and a naphthyl group.

The carbon number of the aralkyl group as R is not particularly limited but is usually from 7 to 20, preferably from 7 to 11. Specific examples of the aralkyl group include a benzyl group.

In the alkyl group, cycloalkyl group, aryl group and aralkyl group as R, a hydrogen atom may be replaced by a substituent. Examples of the substituent include an alkyl group, a cycloalkyl group, an aryl group, an aralkyl group, a hydroxyl group, a carboxyl group, an alkoxy group, an aryloxy group, an alkylcarbonyloxy group and an alkyloxycarbonyl group.

In the compound represented by formula (BS-1), it is preferred that only one of three R's is a hydrogen atom or all R's are not a hydrogen atom.

Specific examples of the compound represented by formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecyl amine, dimethylundecylamine, N,N-dimethyldodecylamine, methyldioctadecylamine, N,N-dibutylaniline, N,N-dihexylaniline, 2,6-diisopropylaniline and 2,4,6-tri(tert-butyl)aniline.

Also, one preferred embodiment is a compound where in formula (BS-1), at least one R is an alkyl group substituted with a hydroxyl group. Specific examples of the compound include triethanolamine and N,N-dihydroxyethylaniline.

The alkyl group as R may contain an oxygen atom in the alkyl chain to form an oxyalkylene chain. The oxyalkylene group is preferably —CH₂CH₂O—. Specific examples thereof include tris(methoxyethoxyethyl)amine and compounds illustrated in U.S. Pat. No. 6,040,112, column 3, line 60 et seq.

### (2) Compound Having a Nitrogen-Containing Heterocyclic Structure

The heterocyclic structure may or may not have aromaticity, may contain a plurality of nitrogen atoms, and may further contain a heteroatom other than nitrogen. Specific examples thereof include a compound having an imidazole structure (e.g., 2,4,5-triphenylimidazole), a compound having a piperidine structure (e.g., N-hydroxyethylpiperidine, bis(1,2,2,6,6-pentamethyl-4-piperidyl)sebacate), a compound having a pyridine structure (e.g., 4-dimethylaminopyridine) and a compound having an antipyrine structure (e.g., antipyrine, hydroxyantipyrine), which are compounds other than the basic compound represented by formula (1-IV), (2-IV) or (3-IV).

A compound having two or more ring structures is also suitably used. Specific examples thereof include 1,5-diazabicyclo[4.3.0]non-5-ene and 1,8-diazabicyclo[5.4.0]undec-7-ene.

### (3) Phenoxy Group-Containing Amine Compound

The phenoxy group-containing amine compound is a compound where the alkyl group of an amine compound has a phenoxy group at the terminal opposite the nitrogen atom. The phenoxy group may have a substituent such as alkyl group, alkoxy group, halogen atom, cyano group, nitro group, carboxyl group, carboxylic acid ester group, sulfonic acid ester group, aryl group, aralkyl group, acyloxy group and aryloxy group.

The compound is preferably a compound having at least one oxyalkylene chain between the phenoxy group and the nitrogen atom. The number of oxyalkylene chains in one molecule is preferably from 3 to 9, more preferably from 4 to 6. Among oxyalkylene chains, —CH₂CH₂O— is preferred.

Specific examples thereof include 2-[2-{2-(2,2-dimethoxy-phenoxyethoxy)ethyl}-bis-(2-methoxyethyl)]-amine and Compounds (C1-1) to (C3-3) illustrated in paragraph [0066] of U.S. Patent Application Publication No. 2007/0224539A1.

### (4) Ammonium Salt

An ammonium salt may be also arbitrarily used. The ammonium salt is preferably a hydroxide or a carboxylate. More specifically, a tetraalkylammonium hydroxide typified by tetrabutylammonium hydroxide is preferred.

Other examples of the basic compound (D) which can be used include compounds synthesized in Examples of JP-A-2002-363146 and compounds described in paragraph 0108 of JP-A-2007-298569.

In the present invention, one kind of a basic compound (D) may be used alone, or two or more kinds of compounds may be used in combination.

The composition of the present invention may or may not contain a basic compound (D), but in the case of containing the basic compound, the content of the basic compound (D) is usually from 0.001 to 10 mass %, preferably from 0.01 to 5 mass %, based on the solid content of the composition.

The molar ratio of [acid generator (acid generator (B) and acid generator (B′)]/[basic compound (basic compounds (C1) to (C3) and (D))] is preferably from 2.5 to 300. That is, the molar ratio is preferably 2.5 or more in view of sensitivity and resolution and preferably 300 or less from the standpoint of suppressing a reduction in the resolution due to thickening of the pattern with aging after exposure until heat treatment. This molar ratio is more preferably from 5.0 to 200, still more preferably from 7.0 to 150.

### [5] (E) Surfactant

The composition of the present invention may further contain a surfactant. The surfactant is preferably a fluorine-containing and/or silicon-containing surfactant.

Examples of the surfactant above include Megaface F176 and Megaface R08 produced by Dainippon Ink & Chemicals, Inc.; PF636, PF656 and PF6320 produced by OMNOVA; Troysol S-366 produced by Troy Chemical; Florad FC430 produced by Sumitomo 3M Inc.; and polysiloxane polymer KP-341 produced by Shin-Etsu Chemical Co., Ltd.

A surfactant other than the fluorine-containing and/or silicon-containing surfactant may be also used. Specific examples thereof include polyoxyethylene alkyl ethers and polyoxyethylene alkylaryl ethers.

In addition, known surfactants may be arbitrarily used. Examples of the surfactant which can be used include surfactants described in paragraph [0273] et seq. of U.S. Patent Application Publication No. 2008/0248425A1.

In the present invention, one kind of a surfactant may be used alone, or two or more kinds of surfactants may be used in combination.

The composition of the present invention may or may not contain a surfactant, but in the case of containing a surfactant, the content of the surfactant is preferably from 0.0001 to 2 mass %, more preferably from 0.001 to 1 mass %, based on the entire solid content of the composition.

### [6] (F) Solvent

The composition of the present invention can be dissolved in a solvent capable of dissolving respective components described above and then applied on a support. The solid content concentration of all components of the composition is preferably from 2 to 30 mass %, more preferably from 3 to 25 mass %.

Preferred examples of the solvent which can be used here include an alkylene glycol monoalkyl ether carboxylate [e.g., propylene glycol monomethyl ether acetate (PGMEA, another name: 1-methoxy-2-acetoxypropane), ethylene glycol monoethyl ether acetate], an alkyl alkoxy carboxylate [e.g., ethyl 3-ethoxypropionate (EEP, another name; ethyl-3-ethoxypropionate), methyl methoxypropionate] an alkylene glycol monoalkyl ether [e.g., propylene glycol monomethyl ether (PGME, another name: 1-methoxy-2-propanol), ethylene glycol monomethyl ether, ethylene glycol monoethyl ether], an alkyl lactate [e.g., ethyl lactate (hereinafter, sometimes referred to as “EL”), methyl lactate], a chain or cyclic ketone (cyclohexanone, cyclopentanone, 2-heptanone, methyl ethyl ketone), other arbitrary esters (e.g., 2-methoxyethyl acetate, ethyl acetate, methyl pyruvate, ethyl pyruvate, propyl pyruvate), and other arbitrary solvents (e.g., toluene, N,N-dimethylformamide, dimethylsulfoxide, N-methylpyrrolidone, tetrahydrofuran). One of these solvents may be used alone, or some of them may be mixed and used.

In view of coatability, the composition of the present invention preferably uses a solvent containing an alkylene glycol monoalkyl ether carboxylate, more preferably a mixed solvent of an alkylene glycol monoalkyl ether carboxylate and an alkyl alkoxy carboxylate, an alkylene glycol monoalkyl ether or an alkyl lactate.

The alkylene glycol monoalkyl ether carboxylate is preferably a propylene glycol monoalkyl ether carboxylate, more preferably propylene glycol monomethyl ether acetate.

The alkyl alkoxy carboxylate is preferably an alkyl alkoxy propionate, more preferably ethyl 3-ethoxypropionate.

The alkylene glycol monoalkyl ether is preferably a propylene glycol monoalkyl ether, more preferably propylene glycol monomethyl ether.

The alkyl lactate is preferably ethyl lactate.

In view of the coatability, the solvent is more preferably a mixed solvent of an alkylene glycol monoalkyl ether carboxylate and an alkyl alkoxy carboxylate, still more preferably a mixed solvent of a propylene glycol monoalkyl ether carboxylate and an alkyl alkoxy propionate, yet still more preferably a mixed solvent of propylene glycol monomethyl ether acetate and ethyl 3-ethoxypropionate.

Above all, the solvent preferably contains an alkylene glycol monoalkyl ether carboxylate in an amount of 50 mass % or more, more preferably 60 mass % or more, based on all solvents.

The mixing ratio (by mass) of an alkylene glycol monoalkyl ether carboxylate and an alkyl alkoxy carboxylate is, in view of coatability, preferably from 50:50 to 90:10, more preferably from 60:40 to 80:20.

### [7] (G) Sugar Derivative Capable of Decomposing by the Action of an Acid to Generate an Alcoholic Hydroxyl Group

In view of the sensitivity and the developability of unexposed area, the composition of the present invention preferably further contains (G) a sugar derivative capable of decomposing by the action of an acid to generate an alcoholic hydroxyl group (hereinafter, sometimes simply referred to as a “sugar derivative (G)”).

The (G) sugar derivative capable of decomposing by the action of an acid to generate an alcoholic hydroxyl group include, for example, a compound having, in the molecule, three or more groups selected from the group consisting of a hydroxyl group and a group capable of decomposing by the action of an acid to generate an alcoholic hydroxyl group. Here, as a premise, the sugar derivative (G) contains at least one group capable of decomposing by the action of an acid to generate an alcoholic hydroxyl group.

The sugar derivative (G) is preferably a chain or cyclic sugar derivative. Examples of the sugar derivative include pentoses, hexoses, pseudo-sugars except for monosaccharides, and their peripheral sugars. The sugar derivative may be substituted with, for example, a group capable of decomposing by the action of an acid to generate an alcoholic hydroxyl group.

The group capable of decomposing by the action of an acid to generate an alcoholic hydroxyl group includes a group where a hydrogen atom of an alcoholic hydroxyl group is replaced by a group capable of leaving by the action of an acid, and specifically indicates an acetal group, a ketal group, a tert-butoxycarbonyl group, a tert-butyl ester group or the like.

Also, as in the following structure,

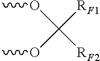

a group capable of decomposing by the action of an acid to generate an alcoholic hydroxyl group may be formed by bonding two hydroxyl groups. In the formula above, each of R_{F1} and R_{F2} independently represents an alkyl group, a cycloalkyl group, an aralkyl group or an aryl group, and R_{F1} and R_{F2} may combine to form a ring.

Two or more of these groups capable of decomposing by the action of an acid to generate an alcoholic group may be present at the same time in the same molecule, and it is preferred to have two or more groups capable of decomposing by the action of an acid to generate an alcoholic hydroxyl group, in the same molecule, and at least one of the groups preferably has the following structure:

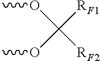

wherein R_{F1} and R_{F2} have the same meanings as above.

In the present invention, the sugar derivative (G) has three or more groups selected from a hydroxyl group and a group capable of decomposing by the action of an acid to generate an alcoholic hydroxyl group, and the number of the groups is preferably from 3 to 10, more preferably from 4 to 8.

The molecular weight of the sugar derivative (G) is preferably from 150 to 3,000, more preferably from 150 to 1,500.

In the present invention, the sugar derivative (G) may have any of the following structures as long as it is a compound satisfying the above-described requirements, but above all, a sugar derivative such as cyclic sugar derivative and chain sugar derivative, and its analogs are preferred.

In the present invention, the cyclic sugar derivative indicates a sugar derivative where a cyclic structure such as alicyclic group is the main framework or is present on the side chain. Preferred cyclic structures include a 5-membered ring, a 6-membered ring and the like, and examples thereof include a cyclohexane ring, a cyclopentane ring, and a tetrahydrofuran or tetrahydropyran ring containing an ether oxygen.

Specific examples of the framework of the cyclic sugar derivative include arabinose, xylose, fucose, rhamnose, galactose, glucose, fructose, fructopyranose, sorbose, mannose, allopyranose, altrose, talose, tagatose, arabinopyranoside, thiogalactopyranose, mannopyranoside, glucopyranose, glucopyranoside, sucrose, palatinose, lactitol, lactose, maltulose, maltose, maltoside, maltitol, cellobiose, turanose, trehalose, melibiose, maltotriose, melezitose, raffinose, stachyose, maltotetraose, maltohexaose and cyclodextrin.

Examples of the sugar derivative (G) such as cyclic sugar derivative are illustrated below, but the present invention is not limited thereto.

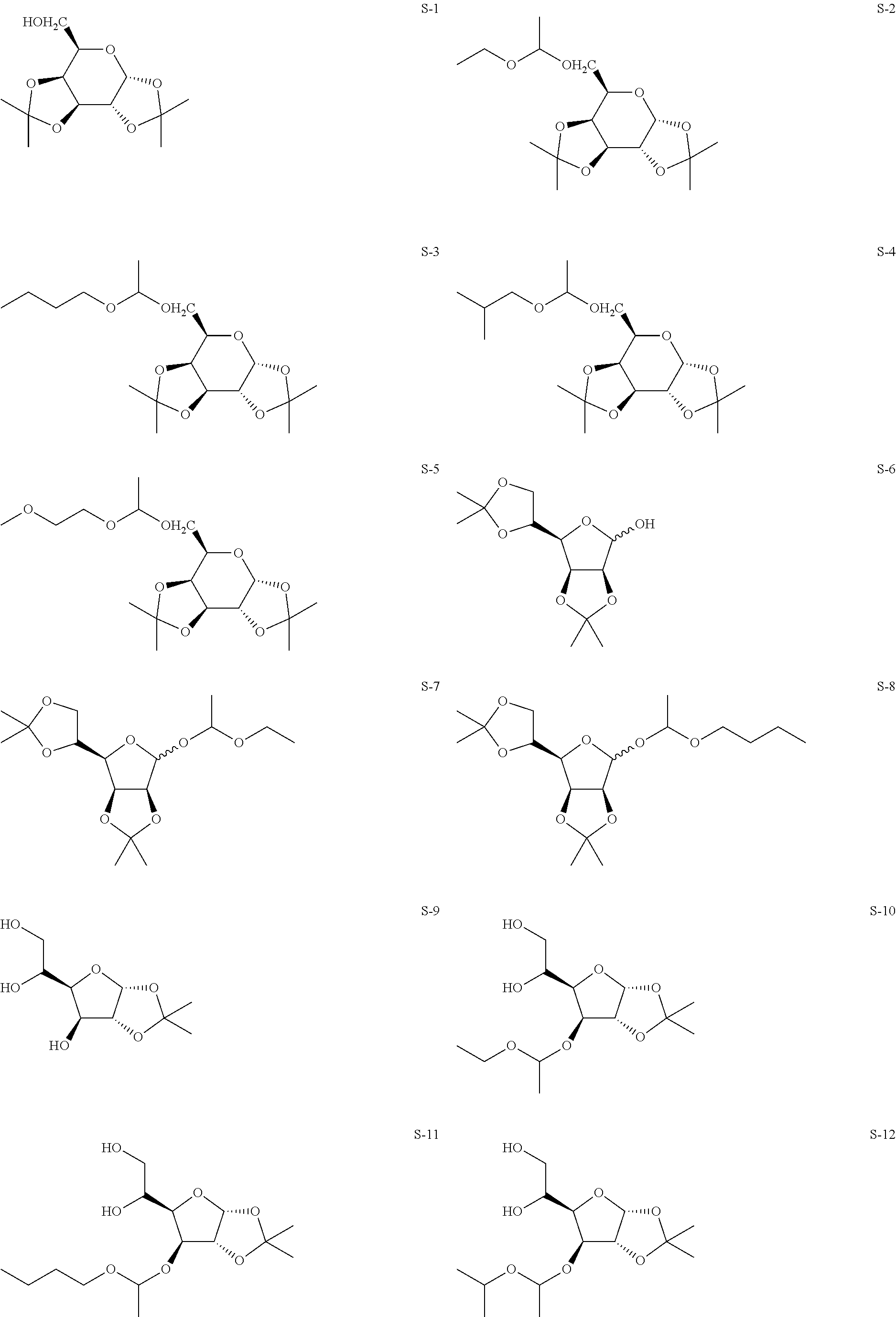

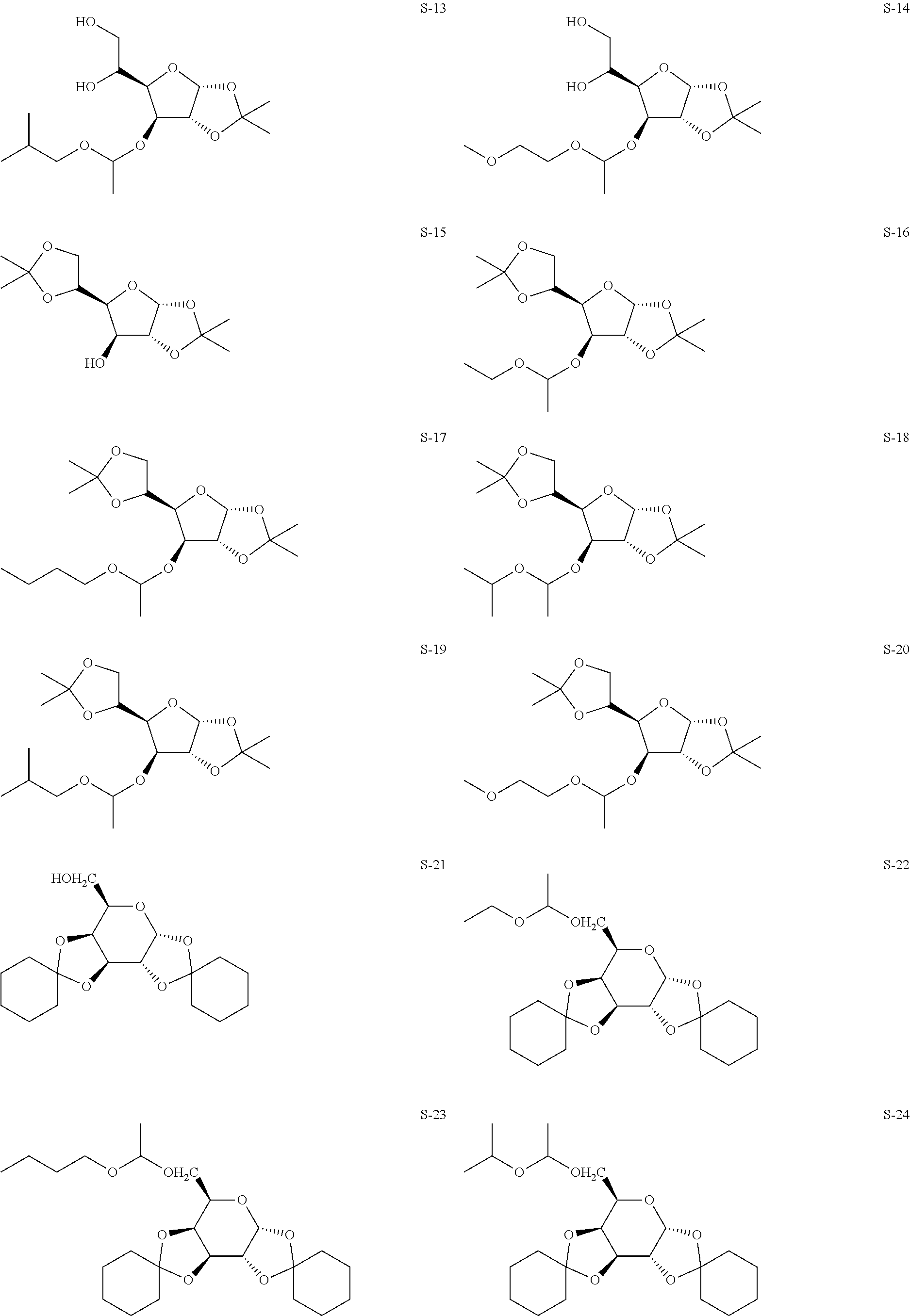

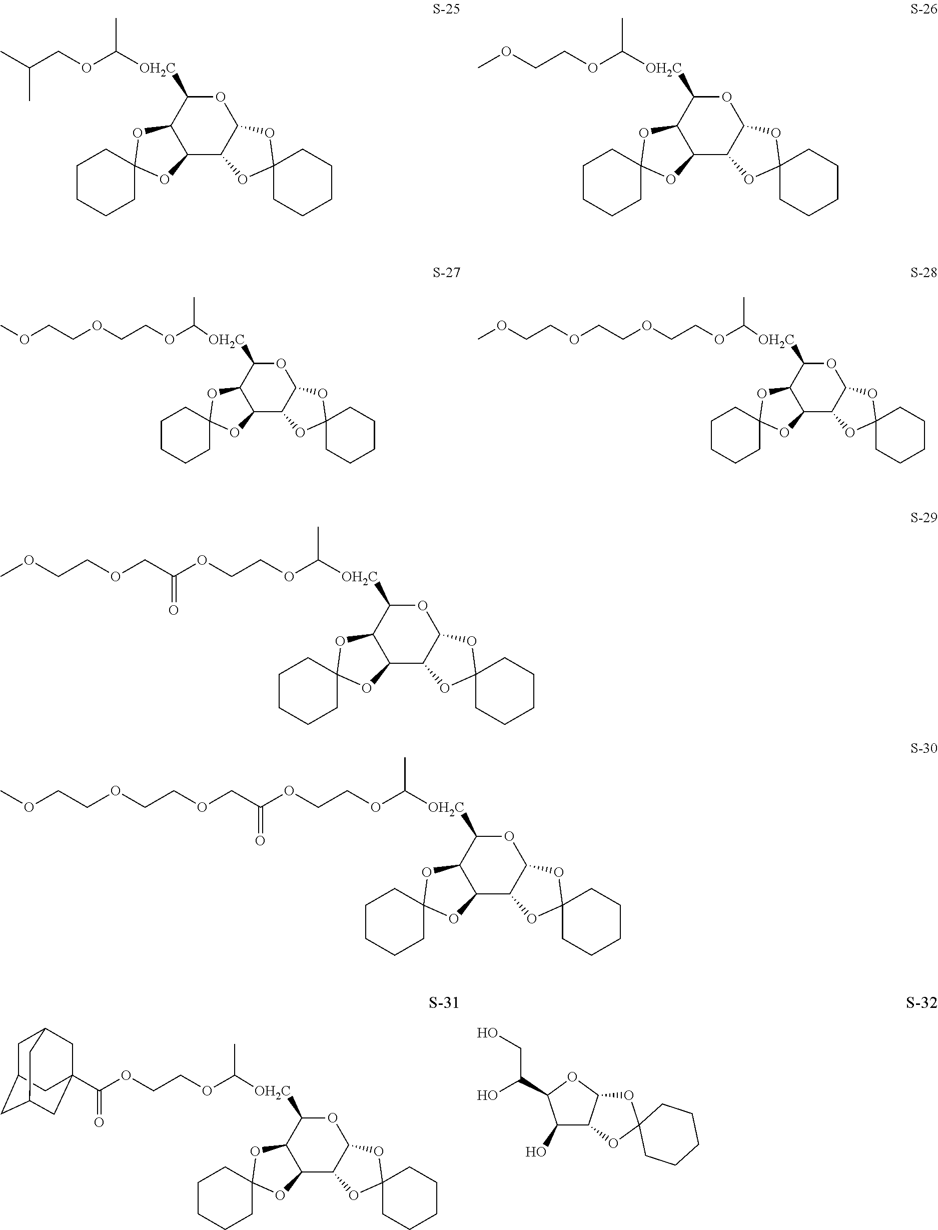

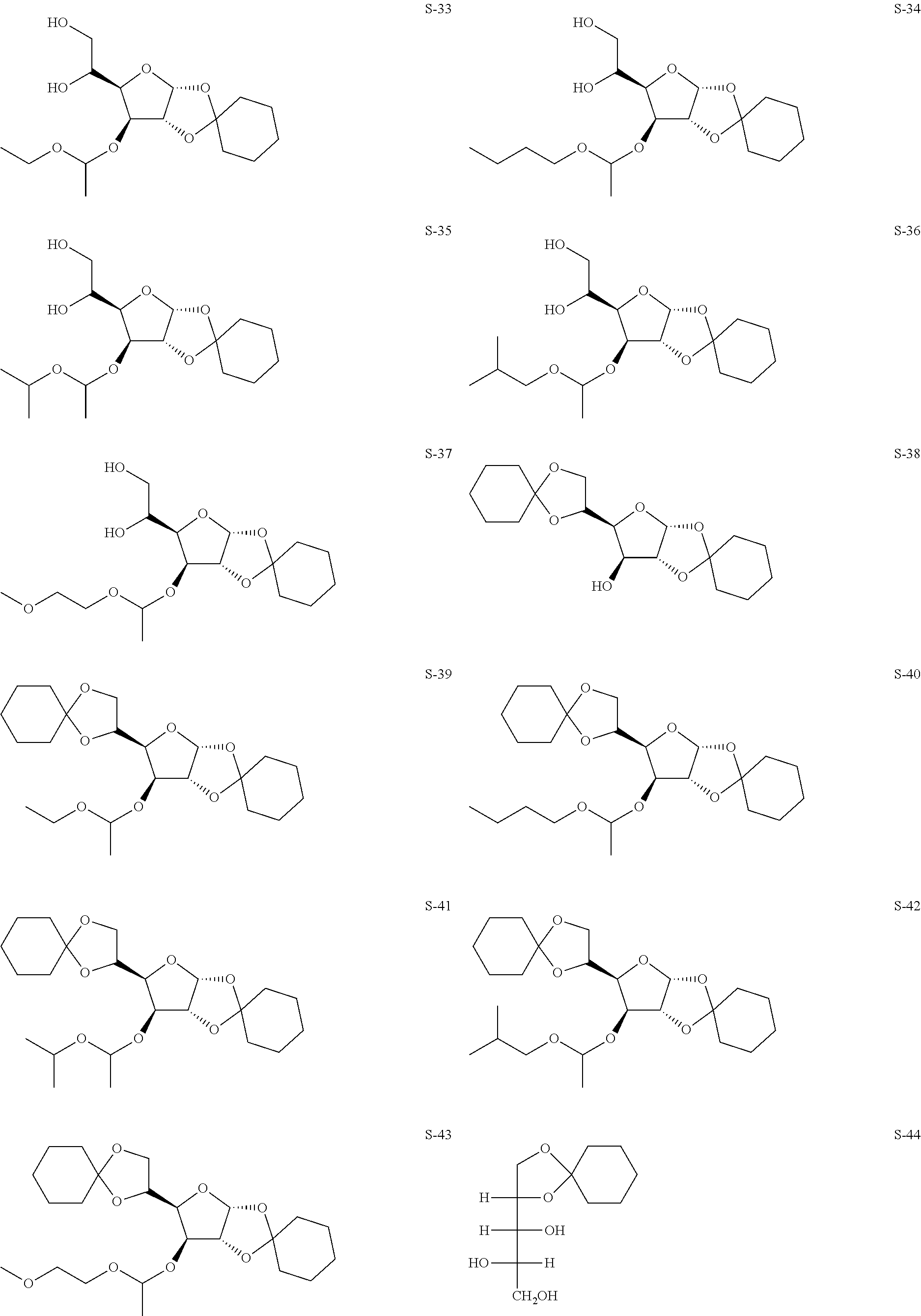

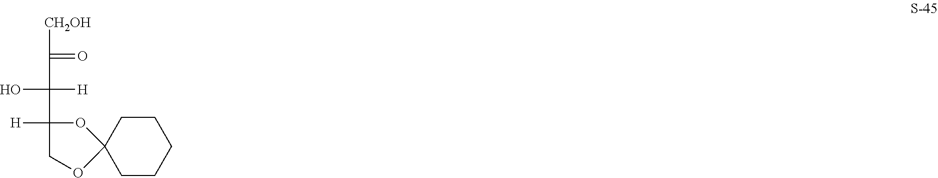

The “chain sugar derivative” as used in the present invention indicates a compound having a ring-opened structure of general sugar or a structure analogous thereto.

Specific examples thereof include threitol, erythritol, adonitol, arabitol, xylitol, sorbitol, mannitol, iditol, dulcitol, erythrose, xylulose, ribulose, deoxyribulose, glucero-gulo-heptose, and compounds shown below.

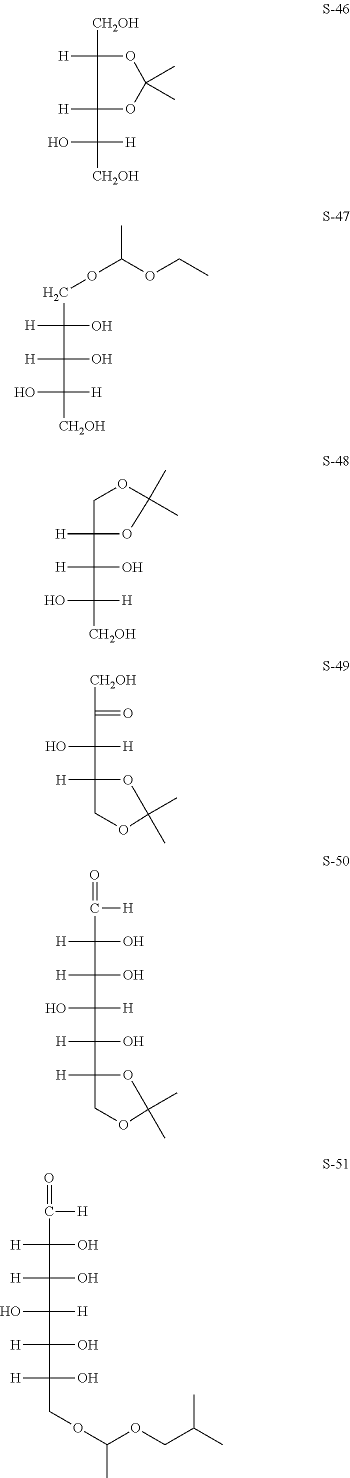

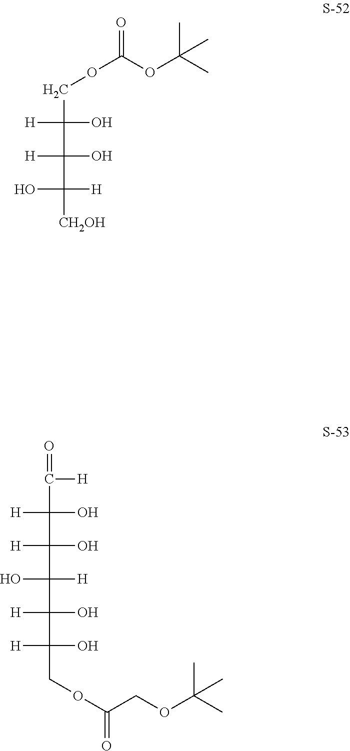

The compounds above have an optical isomer depending on the structure, but all optical isomers are included in the compounds. Depending on the case, the hydroxyl group of these compounds may be substituted with an acid-degradable group such as acetal group and isopropylidene group, or other substituents.

The present invention is, however, not limited to these compounds anyway.

One of these sugar derivatives (G) may be used alone, or two or more kinds thereof may be used.

In the case where the composition of the present invention contains (G) a sugar derivative, the content of the sugar derivative (G) is preferably from 0.001 to 10 mass %, more preferably from 0.01 to 5 mass %, based on the solid content of the composition. That is, the content is preferably 0.001 mass % or more for obtaining a sufficiently high addition effect and is preferably 10 mass % or less in view of the sensitivity and the developability of unexposed area.

### [8] Other Compounds

In addition, the composition of the present invention may arbitrarily contain, for example, a compound capable of generating a carboxylic acid upon irradiation with an actinic ray or radiation, a carboxylic acid such as benzoic acid, a dye, a photo-base generator, an antioxidant (for example, a phenol-based antioxidant disclosed in paragraphs 0130 to 0133 of JP-A-2006-276688), and a compound capable of producing an acid upon irradiation with radiation to decrease the basicity or become neutral described in JP-A-2006-330098 and Japanese Patent 3,577,743.

### [9] Resist Film and Pattern Forming Method

The resist film of the present invention is formed of the composition of the present invention. More specifically, the resist film is preferably formed by applying the composition on a substrate. The thickness of the resist film of the present invention is preferably from 0.05 to 4.0 μm. The substrate may be selected from various substrates used in the fabrication of a semiconductor.

An antireflection film may be provided as the underlayer of the resist. The antireflection film which can be used may be either an inorganic film type such as titanium, titanium dioxide, titanium nitride, chromium oxide, carbon and amorphous silicon, or an organic film type composed of a light absorber and a polymer material. The former requires equipment for the film formation, such as vacuum deposition apparatus, CVD apparatus and sputtering apparatus. Examples of the organic antireflection film include a film composed of a diphenylamine derivative/formaldehyde-modified melamine resin condensate, an alkali-soluble resin and a light absorber described in JP-B-7-69611 (the term “JP-B” as used herein means an “examined Japanese patent publication”); a reaction product of a maleic anhydride copolymer and a diamine-type light absorber described in U.S. Pat. No. 5,294,680; a film containing a resin binder and a methylolmelamine-based thermal crosslinking agent described in JP-A-6-118631; an acrylic resin-type antireflection film containing a carboxylic acid group, an epoxy group and a light absorbing group within the same molecule described in JP-A-6-118656; a film composed of a methylolmelamine and a benzophenone-based light absorber described in JP-A-8-87115; and a film obtained by adding a low molecular light absorber to a polyvinyl alcohol resin described in JP-A-8-179509.

Also, the organic antireflection film which can be used may be a commercially available organic antireflection film such as DUV30 Series and DUV-40 Series produced by Brewer Science, Inc., or AR-2, AR-3 and AR-5 produced by Shipley Co., Ltd.

If desired, an antireflection film may be used as the overlayer of the resist.

Examples of the antireflection film include AQUATAR-II, AQUATAR-III, AQUATAR-VII and AQUATAR-VIII produced by AZ Electronic Materials.

The pattern forming method of the present invention includes a step of exposing the resist film described above, and a step of developing the exposed film.

More specifically, in the step of forming a pattern on a resist film at the production or the like of a precision integrated circuit device, the composition of the present invention is applied on a substrate (for example, a silicon/silicon dioxide-coated substrate, a glass substrate, an ITO substrate or a quartz/chromium oxide-coated substrate) to form a resist film, and the resist film is irradiated with an actinic ray or radiation such as KrF excimer laser light, electron beam and EUV light, then preferably baked (heated), and subjected to development, rinsing and drying, whereby a good pattern can be obtained.

The pattern forming method preferably contains, after film formation, a pre-baking step (PB) before entering the exposure step.

Also, the pattern forming method preferably contains a post-exposure baking step (PEB) after the exposure step but before the development step.

As for the heating temperature, both PB and PEB are preferably performed at 70 to 150° C., more preferably at 80 to 140° C.

The heating time is preferably from 30 to 300 seconds, more preferably from 30 to 180 seconds, still more preferably from 30 to 90 seconds.

The heating can be performed using a device attached to an ordinary exposure/developing machine or may be performed using a hot plate or the like. Thanks to baking, the reaction in the exposed area is accelerated, and the sensitivity and pattern profile are improved.

The alkali developer which can be used in the development is an aqueous solution of alkalis (usually from 0.1 to 20 mass %) such as inorganic alkalis (e.g., sodium hydroxide, potassium hydroxide, sodium carbonate, sodium silicate, sodium metasilicate, aqueous ammonia), primary amines (e.g., ethylamine, n-propylamine), secondary amines (e.g., diethylamine, di-n-butylamine), tertiary amines (e.g., triethylamine, methyldiethylamine), alcohol amines (e.g., dimethylethanolamine, triethanolamine), quaternary ammonium salts (e.g., tetramethylammonium hydroxide (TMAH), tetraethylammonium hydroxide, choline) and cyclic amines (e.g., pyrrole, piperidine). This aqueous solution of alkalis may be used after adding thereto an appropriate amount of alcohols such as isopropyl alcohol or a surfactant such as nonionic surfactant.

Among these developers, a quaternary ammonium salt is preferred, and tetramethylammonium hydroxide (TMAH) and choline are more preferred.

The pH of the alkali developer is usually from 10 to 15.

As for the rinsing solution, pure water is used, and an appropriate amount of a surfactant may be added thereto before use.

After the development or rinsing, a treatment of removing the developer or rinsing solution attached to the pattern by a supercritical fluid may be performed.

Examples of the actinic ray or radiation serving as an exposure light source include infrared light, visible light, ultraviolet light, far ultraviolet light, extreme-ultraviolet ray (EUV light), X-ray and electron beam (EB). The radiation is preferably far ultraviolet light at a wavelength of 250 nm or less, more preferably 220 nm or less, still more preferably from 1 to 200 nm, and specific examples thereof include KrF excimer laser (248 nm), ArF excimer laser (193 nm), F₂ excimer laser (157 nm), X-ray, electron beam and extreme-ultraviolet ray. The exposure is preferably preformed by the irradiation of KrF excimer laser, electron beam, X-ray or extreme-ultraviolet ray. That is, the composition of the present invention is preferably used for exposure to KrF excimer laser, electron beam, X-ray or extreme-ultraviolet ray.

### EXAMPLES

The present invention is described in greater detail below by referring to Examples, but the present invention should not be construed as being limited thereto.

The first invention of the present invention is described in greater detail below by referring to Examples, but the present invention should not be construed as being limited thereto.

### Synthesis Example 1-1

### Synthesis of Resin (A-6)-1

A 2 L-volume flask was charged with 600 g of ethylene glycol monoethyl ether acetate and nitrogen-purged at a flow rate of 100 mL/min for 1 hour. Also, 105.4 g (0.65 mol) of 4-acetoxystyrene, 35.6 g (0.25 mol) of tert-butyl methacrylate, 17.6 g (0.10 mol) of benzyl methacrylate, and 1.73 g (0.0075 mol) of a polymerization initiator, V-601 (produced by Wako Pure Chemical Industries, Ltd.), were dissolved in 200 g of ethylene glycol monoethyl ether acetate, and the obtained solution was subjected to nitrogen purging in the same manner as above.

The 2 L-volume flask containing ethylene glycol monoethyl ether acetate was heated until the inner temperature reached 80° C., and 1.73 g (0.0075 mol) of a polymerization initiator, V-601, was further added thereto. The resulting mixture was stirred for 5 minutes, and the monomer mixture solution prepared above was added dropwise thereto with stirring over 6 hours. After the dropwise addition, the reaction solution was further heated with stirring for 2 hours, then cooled to room temperature and added dropwise to 3 L of hexane to precipitate a polymer, and the solid collected by filtration was dissolved in 500 ml of acetone. This solution was again added dropwise to 3 L of hexane, and the solid collected by filtration was dried under reduced pressure to obtain 151 g of a 4-acetoxystyrene/tert-butyl methacrylate/benzyl methacrylate copolymer.

Subsequently, 40.00 g of the polymer obtained above, 40 ml of methanol, 200 ml of 1-methoxy-2-propanol and 1.5 ml of concentrated hydrochloric acid were added to a reaction vessel, and the mixture was heated to 80° C. and stirred for 5 hours. The reaction solution was allowed to cool to room temperature and added dropwise to 3 L of distilled water, and the solid collected by filtration was dissolved in 200 ml of acetone. The resulting solution was again added dropwise to 3 L of distilled water, and the solid collected by filtration was dried under reduced pressure to obtain 35.5 g of Resin (A-6)-1.

The weight average molecular weight (Mw) in terms of polystyrene and the polydispersity (Mw/Mn) were determined by GPC (solvent: THF), as a result, the weight average molecular weight (Mw) was 25,000 and the polydispersity (Mw/Mn) was 1.50.

Resins shown in Table 1-1 having structures illustrated above were synthesized in the same manner as in Synthesis Example 1-1 except for changing the monomers used. The compositional ratio, weight average molecular weight and polydispersity of the resin can be appropriately adjusted by the charge ratio of monomers, the charge amount of initiator, the reaction temperature or the like based on the target values. The compositional ratio of the resin determined by ¹H-NMR and ¹³C-NMR, and the weight average molecular weight (Mw) and molecular weight polydispersity (Mw/Mn) determined by GPC similarly to the above, are shown in Table 1-1. The compositional ratio (by mol) is the compositional ratio of repeating units starting from the left in the resin illustrated above with the symbol shown in Table 1-1. All of Resins (A-2)-1 to (A-2)-3 have the structure of Resin (A-2), all of Resins (A-6)-1 to (A-6)-5 have the structure of Resin (A-6), and all of Resins (A-8)-1 to (A-8)-3 have the structure of Resin (A-8), where the compositional ratio, the molecular weight or the polydispersity differs from each other.

Also, Resin A-X having a structure illustrated below was synthesized as a resin for comparison in the same manner as in Synthesis Example 1-1. The compositional ratio, molecular weight and polydispersity of Resin A-X, determined by the same methods as above, are shown together in Table 1-1.

TABLE 1-1

| | Compositional Ratio | | | Weight Average | |
|---|---|---|---|---|---|
| | (mol %) | | | Molecular Weight | Polydispersity |
| Resin | (1-I) | (1-II) | (1-III) | (Mw) | (Mw/Mn) |
| (A-2)-1 | 60 | 30 | 10 | 20000 | 1.51 |
| (A-2)-2 | 60 | 30 | 10 | 15000 | 1.50 |
| (A-2)-3 | 65 | 25 | 10 | 25000 | 1.49 |
| (A-6)-1 | 60 | 30 | 10 | 25000 | 1.50 |
| (A-6)-2 | 65 | 25 | 10 | 24500 | 1.49 |
| (A-6)-3 | 70 | 20 | 10 | 25500 | 1.51 |
| (A-6)-4 | 65 | 25 | 10 | 20000 | 1.50 |
| (A-6)-5 | 65 | 25 | 10 | 15000 | 1.49 |
| (A-8)-1 | 70 | 20 | 10 | 20000 | 1.50 |
| (A-8)-2 | 70 | 25 | 5 | 25000 | 1.49 |
| (A-8)-3 | 65 | 20 | 15 | 20000 | 1.51 |
| (A-5) | 65 | 25 | 10 | 20000 | 1.52 |
| (A-11) | 65 | 25 | 10 | 20000 | 1.53 |
| (A-12) | 65 | 25 | 10 | 20000 | 1.51 |
| A-X | 60 | 30 | 10 | 15000 | 1.55 |

Comparative Resin A-X:

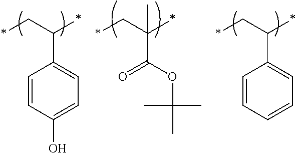

### [Preparation of Actinic Ray-Sensitive or Radiation-Sensitive Resin Composition]

The resin, the acid generator, the basic compound, the sugar derivative and the surfactant shown in Table 1-2 below were dissolved in a single solvent of propylene glycol monomethyl ether acetate (another name: 1-methoxy-2-acetoxypropane, hereinafter simply referred to as “PGMEA”) or a mixed solvent of PGMEA and propylene glycol monomethyl ether (another name: 1-methoxy-2-propanol, hereinafter simply referred to as “PGME”), ethyl lactate (hereinafter simply referred to as “EL”) or ethyl-3-ethoxypropionate (hereinafter simply referred to as “EEP”) to prepare a solution having a solid content concentration of 10.0 mass %, and the obtained solution was microfiltered through a membrane filter having a pore size of 0.1 μm to obtain a positive resist solution (an actinic ray-sensitive or radiation-sensitive resin composition).

The resist solutions used in the evaluation are shown in Table 1-2 below. Here, the amount added (mass %) of each component except for solvents means mass % based on the solid content excluding solvents. As for the solvent, a mixing ratio (mass %) of PGMEA, PGME, EL and EEP is shown.

TABLE 1-2

| | | Acid | Basic | Sugar | | | | | |
|---|---|---|---|---|---|---|---|---|---|
| | | Generators | Compound | Derivative | | Solvent (F) | | | |
| | Resin (A1) | (B), (B′) | (C1) | (G) | Surfactant (E) | PGMEA | PGME | EL | EEP |
| | (mass %) | (mass %) | (mass %) | (mass %) | (mass %) | (mass %) | (mass %) | (mass %) | (mass %) |
| Example 1-1 | (A-6)-2 (97.86) | B-5 (2.0) | C1-1 (0.1) | — | E-2 (0.04) | 80 | 0 | 0 | 20 |
| Example 1-2 | (A-6)-2 (94.86) | B-5 (2.0) | C1-1 (0.1) | S-38 (3.0) | E-2 (0.04) | 80 | 0 | 0 | 20 |
| Example 1-3 | (A-6)-2 (97.86) | B-1 (2.0) | C1-1 (0.1) | — | E-2 (0.04) | 80 | 0 | 0 | 20 |
| Example 1-4 | (A-6)-2 (94.86) | B-1 (2.0) | C1-1 (0.1) | S-38 (3.0) | E-2 (0.04) | 80 | 0 | 0 | 20 |
| Example 1-5 | (A-6)-1 (94.86) | B-1 (2.0) | C1-1 (0.1) | S-38 (3.0) | E-2 (0.04) | 80 | 0 | 0 | 20 |
| Example 1-6 | (A-6)-3 (94.86) | B-1 (2.0) | C1-1 (0.1) | S-38 (3.0) | E-2 (0.04) | 80 | 0 | 0 | 20 |
| Example 1-7 | (A-2)-2 (94.86) | B-1 (2.0) | C1-1 (0.1) | S-38 (3.0) | E-2 (0.04) | 80 | 0 | 0 | 20 |
| Example 1-8 | (A-8)-3 (97.86) | B-1 (2.0) | C1-1 (0.1) | — | E-2 (0.04) | 80 | 0 | 0 | 20 |
| Example 1-9 | (A-6)-2 (94.86) | B-2 (2.0) | C1-1 (0.1) | S-38 (3.0) | E-2 (0.04) | 80 | 0 | 0 | 20 |
| Example 1-10 | (A-6)-2 (94.86) | B-4 (2.0) | C1-1 (0.1) | S-38 (3.0) | E-3 (0.04) | 80 | 0 | 0 | 20 |
| Example 1-11 | (A-6)-2 (94.86) | B-6 (2.0) | C1-2 (0.1) | S-38 (3.0) | E-2 (0.04) | 80 | 0 | 0 | 20 |
| Example 1-12 | (A-6)-2 (94.86) | B-1 (2.0) | C1-1 (0.1) | S-38 (3.0) | E-2 (0.04) | 100 | 0 | 0 | 0 |
| Example 1-13 | (A-6)-2 (94.86) | B-3 (2.0) | C1-1 (0.1) | S-38 (3.0) | E-1 (0.04) | 80 | 20 | 0 | 0 |
| Example 1-14 | (A-6)-2 (94.86) | B-1 (2.0) | C1-1 (0.1) | S-38 (3.0) | E-4 (0.04) | 80 | 0 | 20 | 0 |
| Example 1-15 | (A-6)-2 (97.86) | B-5/B-1 | C1-1 (0.1) | — | E-2 (0.04) | 80 | 0 | 0 | 20 |
| | | (1.4/0.6) | | | | | | | |
| Example 1-16 | (A-6)-2 (97.86) | B-5 (2.0) | C1-1/BS-12 | — | E-2 (0.04) | 80 | 0 | 0 | 20 |
| | | | (0.08/0.02) | | | | | | |
| Example 1-17 | (A-2)-1 (97.86) | B-5 (2.0) | C1-1 (0.1) | — | E-2 (0.04) | 80 | 0 | 0 | 20 |
| Example 1-18 | (A-2)-3 (97.86) | B-5 (2.0) | C1-1 (0.1) | — | E-2 (0.04) | 80 | 0 | 0 | 20 |
| Example 1-19 | (A-6)-4 (97.86) | B-5 (2.0) | C1-1 (0.1) | — | E-2 (0.04) | 80 | 0 | 0 | 20 |
| Example 1-20 | (A-6)-5 (97.86) | B-5 (2.0) | C1-1 (0.1) | — | E-2 (0.04) | 80 | 0 | 0 | 20 |
| Example 1-21 | (A-8)-1 (97.86) | B-5 (2.0) | C1-1 (0.1) | — | E-2 (0.04) | 80 | 0 | 0 | 20 |
| Example 1-22 | (A-8)-2 (97.86) | B-5 (2.0) | C1-1 (0.1) | — | E-2 (0.04) | 80 | 0 | 0 | 20 |
| Example 1-23 | (A-6)-2 (97.86) | B-5 (2.0) | C1-9 (0.1) | — | E-2 (0.04) | 80 | 0 | 0 | 20 |
| Example 1-24 | (A-6)-2 (97.86) | B-5/B-A | C1-9 (0.1) | — | E-2 (0.04) | 80 | 0 | 0 | 20 |
| | | (1.2/0.8) | | | | | | | |
| Example 1-25 | (A-5) (97.86) | B-2 (2.0) | C1-9 (0.1) | — | E-2 (0.04) | 80 | 0 | 0 | 20 |
| Example 1-26 | (A-11) (97.86) | B-2 (2.0) | C1-5 (0.1) | — | E-2 (0.04) | 80 | 0 | 0 | 20 |
| Example 1-27 | (A-12) (97.86) | B-2 (2.0) | C1-9 (0.1) | — | E-2 (0.04) | 80 | 0 | 0 | 20 |
| Example 1-28 | (A-6)-2 (97.86) | B-7 (2.0) | C1-5 (0.1) | — | E-2 (0.04) | 80 | 0 | 0 | 20 |
| Example 1-29 | (A-6)-2 (97.86) | B-2 (2.0) | C1-12 (0.1) | — | E-2 (0.04) | 80 | 0 | 0 | 20 |
| Example 1-30 | (A-6)-2 (97.86) | B-2 (2.0) | C1-13 (0.1) | — | E-2 (0.04) | 80 | 0 | 0 | 20 |
| Comparative | (A-6)-2 (94.86) | B-1 (2.0) | BS-11 (0.1) | S-38 (3.0) | E-2 (0.04) | 80 | 0 | 20 | 0 |
| Example 1-1 | | | | | | | | | |
| Comparative | A-X (94.86) | B-1 (2.0) | C1-1 (0.1) | S-38 (3.0) | E-2 (0.04) | 80 | 0 | 20 | 0 |
| Example 1-2 | | | | | | | | | |
| Comparative | (A-6)-2 (97.86) | B-5/B-A | BS-12 (0.1) | — | E-2 (0.04) | 80 | 0 | 0 | 20 |
| Example 1-3 | | (1.2/0.8) | | | | | | | |

Abbreviations in Table 1-2 are as follows.
(Acid Generator)
B-1 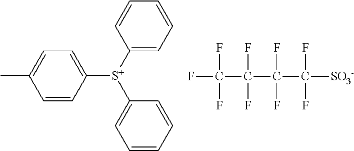
B-2 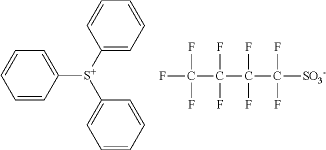
B-3 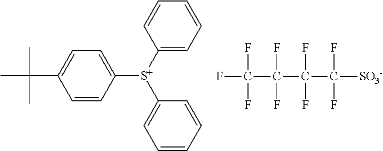
B-4 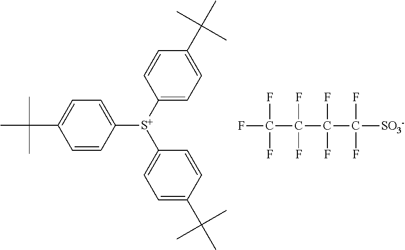
B-5 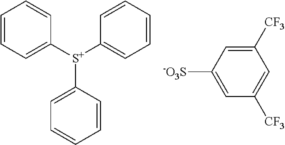
B-6 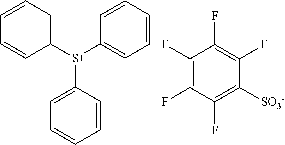
B-7: Triphenylsulfonium 2,4,6-triisopropylbenzenesulfonate
B-A: Bis(cyclohexylsulfonyl)diazomethane
(Basic Compound (C1))
A compound selected from Compounds (C1-1) to (C1-13) was used as the basic compound (C1) for use in the present invention. Also, for comparison, Comparative Compound (BS-11) or (BS-12) shown below was used.
BS-11: Dicyclohexylmethylamine
BS-12: Compound shown below. 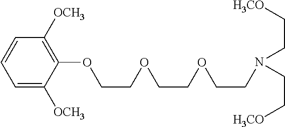
(Sugar Derivative)
A compound selected from Compounds (S-1) to (S-53) was used as the sugar derivative.
(Surfactant)
E-1: PF636 (produced by OMNOVA)
E-2: PF6320 (produced by OMNOVA)
E-3: Megaface F-176 (produced by Dainippon Ink & Chemicals, Inc.)
E-4: Florad FC430 (produced by Sumitomo 3M Inc.)

### [Production and Evaluation of Pattern]

The positive resist solution prepared above was uniformly applied on a silicon wafer having provided thereon a 60 nm-thick antireflection layer (DUV32, produced by Brewer Science, Inc.), by using a spin coater, Mark 8, manufactured by Tokyo Electron Ltd. and dried under heating at 130° C. over 60 seconds to form a positive resist film having a thickness of 0.40 μm.

This film stack was then exposed through a contact hole pattern mask (diameter: 150 nm wide, pitch: 300 nm (half pitch: 150 nm)) by using a KrF excimer laser scanner (PAS5500/850C, manufactured by ASML, wavelength: 248 nm) under the exposure conditions of NA=0.68 and σ=0.60. The resist film after exposure was baked at 140° C. over 60 seconds and the film after baking was dipped in an aqueous 2.38 mass % tetramethylammonium hydroxide (TMAH) solution over 60 seconds. After this development processing, the film was rinsed with pure water for 30 seconds and dried to obtain a contact hole pattern with a diameter of 150 nm wide and a pitch of 300 nm (half pitch: 150 nm). The obtained pattern was evaluated by the following methods. The results are shown in Table 1-3.

### (EDW)

The exposure dose for forming a contact hole pattern with a diameter of 150 nm wide and a pitch of 300 nm (half pitch: 150 nm) obtained in the same manner as above was taken as an optimal exposure dose. The exposure dose range allowing for a ±10% tolerance on the hole diameter when changing the exposure dose was determined using a scanning electron microscope (SEM) (S-8840, manufactured by Hitachi, Ltd.), and the value obtained by dividing the determined value by the optimal exposure dose was expressed in percentage and taken as the value of exposure latitude (EL). On the other hand, the focus for a contact hole pattern with a diameter of 150 nm wide and a pitch of 300 nm (half pitch: 150 nm) was taken as an optimal focus, and the focus range allowing for a ±10% tolerance on the hole diameter when changing the focus (defocusing) while keeping the exposure dose at the optimal exposure dose was taken as the defocus latitude (DOF). From the results of the exposure latitude (EL) and the defocus latitude (DOF), the numerical value of EDW was computed using Propata (produced by KLA Tencor Ltd.). As the numerical value is larger, the margin is greater and the performance is higher.

### (Side Wall Verticality)

The cross-sectional profile of a contact hole pattern with a diameter of 150 nm wide and a pitch of 300 nm (half pitch: 150 nm) obtained in the same manner as above was observed by cross-sectional SEM, and the verticality was rated A when the side surface was rising almost vertically, rated B when slightly tapered, rated C when significantly tapered, and rated D when reversely tapered.

### (Sidelobe Resistance)

With respect to the obtained contact hole pattern, the exposure dose for forming a contact hole pattern with a diameter of 150 nm wide and a pitch of 300 nm (half pitch: 150 nm) was taken as an optimal exposure dose, and the film surface state in the unexposed area around a contact hole at this exposure dose was observed by a scanning electron microscope (S-8840, manufactured by Hitachi, Ltd.). A pit-like surface roughness slightly observed between contact holes is a sidelobe exposed due to leakage light and was observed in the overexposed area.

A value obtained by dividing the exposure dose immediately before a sidelobe was observed when changing the exposure dose from the optimal exposure dose, by the optimal exposure dose was taken as an indicator of sidelobe resistance. A larger value indicates higher sidelobe resistance.

### (Coatability (Wafer In-Plane Uniformity))

The thickness at 30 points in the wafer plane of the obtained contact hole pattern was measured by an optical film thickness meter (VM-3110 (manufactured by Dainippon Screen Mfg. Co., Ltd.)). The absolute value of a value obtained by subtracting the average film thickness from a film thickness farthest from the average value was taken as the wafer in-plane uniformity. A smaller numerical value indicates higher uniformity.

### (Number of Blob Defects)

With respect to the obtained contact hole pattern, the film surface state in the unexposed area was measured using a defect inspection apparatus, KLA2360 (trade name), manufactured by KLA Tencor Ltd. in a random mode by setting the pixel size of the defect inspection apparatus to 0.16 μm and the threshold value to 20. Development defects extracted from differences generated by superimposition between a comparative image and the pixel unit were detected, and the number of development defects per unit area (1 cm²) was calculated. At the calculation, SEM observation of defects was performed by SEMVisionG3 (manufactured by Applied Materials Japan, Inc.), and the number of blob defects was determined by visually classifying the defects.

TABLE 1-3

| | | | | | Number of |
|---|---|---|---|---|---|
| | | | | | Blob |
| | | | | | Defects |
| | | Side Wall | Sidelobe | Coatability | (pieces/ |
| | EDW | Verticality | Resistance | (nm) | cm²) |
| Example 1-1 | 0.39 | A | 1.55 | 2 | 3 |
| Example 1-2 | 0.40 | A | 1.55 | 1 | 3 |
| Example 1-3 | 0.40 | A | 1.60 | 2 | 0 |
| Example 1-4 | 0.41 | A | 1.60 | 1 | 0 |
| Example 1-5 | 0.41 | A | 1.60 | 2 | 8 |
| Example 1-6 | 0.40 | A | 1.55 | 3 | 0 |
| Example 1-7 | 0.40 | A | 1.60 | 2 | 1 |
| Example 1-8 | 0.38 | A | 1.55 | 3 | 2 |
| Example 1-9 | 0.39 | A | 1.55 | 2 | 2 |
| Example 1-10 | 0.38 | A | 1.60 | 2 | 14 |
| Example 1-11 | 0.39 | A | 1.55 | 3 | 12 |
| Example 1-12 | 0.36 | B | 1.55 | 7 | 10 |
| Example 1-13 | 0.36 | B | 1.55 | 9 | 9 |
| Example 1-14 | 0.37 | B | 1.55 | 8 | 9 |
| Example 1-15 | 0.39 | A | 1.55 | 2 | 3 |
| Example 1-16 | 0.39 | A | 1.55 | 3 | 3 |
| Example 1-17 | 0.38 | A | 1.55 | 3 | 5 |
| Example 1-18 | 0.38 | A | 1.55 | 3 | 5 |
| Example 1-19 | 0.38 | A | 1.55 | 3 | 4 |
| Example 1-20 | 0.38 | A | 1.55 | 4 | 4 |
| Example 1-21 | 0.38 | A | 1.55 | 3 | 3 |
| Example 1-22 | 0.38 | A | 1.55 | 4 | 4 |
| Example 1-23 | 0.38 | A | 1.55 | 3 | 3 |
| Example 1-24 | 0.38 | B | 1.55 | 2 | 8 |
| Example 1-25 | 0.37 | A | 1.55 | 2 | 3 |
| Example 1-26 | 0.38 | A | 1.55 | 1 | 3 |
| Example 1-27 | 0.37 | A | 1.55 | 2 | 2 |
| Example 1-28 | 0.35 | A | 1.60 | 2 | 2 |
| Example 1-29 | 0.35 | A | 1.55 | 2 | 1 |
| Example 1-30 | 0.35 | A | 1.55 | 2 | 2 |
| Comparative | 0.22 | D | 1.20 | 9 | 240 |
| Example 1-1 | | | | | |
| Comparative | 0.20 | C | 1.15 | 8 | 220 |
| Example 1-2 | | | | | |
| Comparative | 0.25 | C | 1.30 | 8 | 120 |
| Example 1-3 | | | | | |

As apparent from the results shown in Table 1-3, compared with Comparative Examples 1-1 to 1-3 where only either the resin (A1) or the basic compound (C1) according to the present invention is used, in Examples where both are used, good results are obtained in all of EDW, side wall verticality, sidelobe resistance and number of blob defects. Furthermore, it is seen that in Examples 1-1 to 1-11 and 1-15 to 1-30 where a mixed solvent of PGMEA and EEP is used, the coatability is particularly excellent. In Examples using the basic compound (C1) according to the present invention, the sidelobe resistance is enhanced as compared with Comparative Examples 1-1 and 1-3, and this is considered to result because thanks to the basicity and volatility of the basic compound (C1) according to the present invention, the ability of trapping the generated acid in the vicinity of the film surface is successfully varied and the sidelobe resistance is enhanced. Also, in general, the number of blob defects is greatly attributed to the structure of the polymer as well as how the basic compound interacts with the acid generated in the system. Details of the mechanism are not clearly known, but the performance in terms of the number of blob defects is excellent in Examples using the resin (A1) and the basic compound (C1) according to the present invention, and this is revealed to be a good combination.

The second invention of the present invention is described in greater detail below by referring to Examples, but the present invention should not be construed as being limited thereto.

### Synthesis Example 2-1

### Synthesis of Resin 6

A 2 L-volume flask was charged with 600 g of ethylene glycol monoethyl ether acetate and nitrogen-purged at a flow rate of 100 mL/min for 1 hour. Also, 105.4 g (0.65 mol) of 4-acetoxystyrene, 35.6 g (0.25 mol) of tert-butyl methacrylate, 17.6 g (0.10 mol) of benzyl methacrylate, and 1.73 g (0.0075 mol) of a polymerization initiator, V-601 (produced by Wako Pure Chemical Industries, Ltd.), were dissolved in 200 g of ethylene glycol monoethyl ether acetate, and the obtained solution was subjected to nitrogen purging in the same manner as above.

The 2 L-volume flask containing ethylene glycol monoethyl ether acetate was heated until the inner temperature reached 80° C., and 1.73 g (0.0075 mol) of a polymerization initiator, V-601, was further added thereto. The resulting mixture was stirred for 5 minutes, and the monomer mixture solution prepared above was added dropwise thereto with stirring over 6 hours. After the dropwise addition, the reaction solution was further heated with stirring for 2 hours, then cooled to room temperature and added dropwise to 3 L of hexane to precipitate a polymer, and the solid collected by filtration was dissolved in 500 ml of acetone. This solution was again added dropwise to 3 L of hexane, and the solid collected by filtration was dried under reduced pressure to obtain 151 g of a 4-acetoxystyrene/tert-butyl methacrylate/benzyl methacrylate copolymer.

Subsequently, 40.00 g of the polymer obtained above, 40 ml of methanol, 200 ml of 1-methoxy-2-propanol and 1.5 ml of concentrated hydrochloric acid were added to a reaction vessel, and the mixture was heated to 80° C. and stirred for 5 hours. The reaction solution was allowed to cool to room temperature and added dropwise to 3 L of distilled water, and the solid collected by filtration was dissolved in 200 ml of acetone. The resulting solution was again added dropwise to 3 L of distilled water, and the solid collected by filtration was dried under reduced pressure to obtain 35.5 g of Resin 6.

The weight average molecular weight (Mw) in terms of polystyrene and the polydispersity (Mw/Mn) were determined by GPC (solvent: THF), as a result, the weight average molecular weight (Mw) was 24,500 and the polydispersity (Mw/Mn) was 1.49.

### Synthesis Example 2-2

### Synthesis of Resin 10

A 2 L-volume flask was charged with 600 g of ethylene glycol monoethyl ether acetate and nitrogen-purged at a flow rate of 100 mL/min for 1 hour. Also, 105.4 g (0.65 mol) of 4-acetoxystyrene, 35.6 g (0.25 mol) of tert-butyl methacrylate, 16.0 g (0.10 mol) of phenyl methacrylate, and 2.30 g (0.01 mol) of a polymerization initiator, V-601 (produced by Wako Pure Chemical Industries, Ltd.), were dissolved in 200 g of ethylene glycol monoethyl ether acetate, and the obtained solution was subjected to nitrogen purging in the same manner as above.

The 2 L-volume flask containing ethylene glycol monoethyl ether acetate was heated until the inner temperature reached 80° C., and 2.30 g (0.01 mol) of a polymerization initiator, V-601, was further added thereto. The resulting mixture was stirred for 5 minutes, and the monomer mixture solution prepared above was added dropwise thereto with stirring over 6 hours. After the dropwise addition, the reaction solution was further heated with stirring for 2 hours, then cooled to room temperature and added dropwise to 3 L of hexane to precipitate a polymer, and the solid collected by filtration was dissolved in 500 ml of acetone. This solution was again added dropwise to 3 L of hexane, and the solid collected by filtration was dried under reduced pressure to obtain 149 g of a 4-acetoxystyrene/tert-butyl methacrylate/phenyl methacrylate copolymer.

Subsequently, 40.00 g of the polymer obtained above was dissolved in 200 ml of tetrahydrofuran, and 5 ml of an aqueous 2.38 mass % tetramethylammonium hydroxide solution was added thereto. The mixed solution was stirred at room temperature for 1 hour, and distilled water was added thereto to precipitate a polymer. The precipitate was washed with distilled water and dried under reduced pressure. The polymer was dissolved in 100 ml of ethyl acetate and after adding hexane thereto, the precipitated polymer was dried under pressure to obtain 35.1 g of Resin 10 as a powder material. The weight average molecular weight by GPC was 23,500 and the polydispersity (Mw/Mn) was 1.50.

Resins shown in Table 2-1 having structures illustrated below were synthesized in the same manner as in Synthesis Examples 2-1 and 2-2 except for changing the monomers used. The compositional ratio, weight average molecular weight and polydispersity of the resin can be appropriately adjusted by the charge ratio of monomers, the charge amount of initiator, the reaction temperature or the like based on the target values.

The compositional ratio of the resin determined by ¹H-NMR and ¹³C-NMR, and the weight average molecular weight (Mw) and molecular weight polydispersity (Mw/Mn) determined by GPC similarly to the above, are shown in Table 2-1. The compositional ratio (by mol) is the compositional ratio of repeating units starting from the left in the resin denoted by the symbol in Table 2-1.

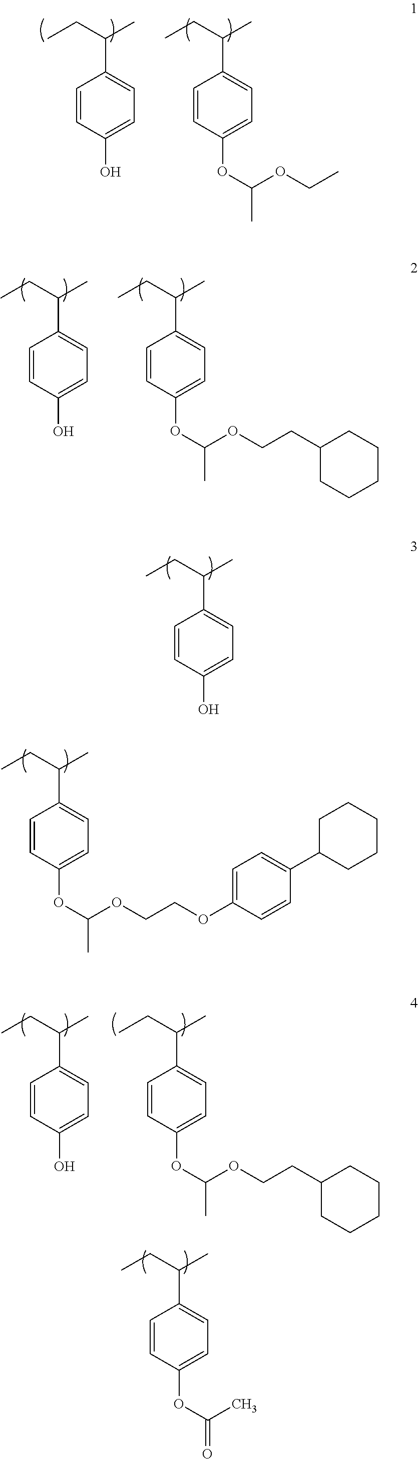

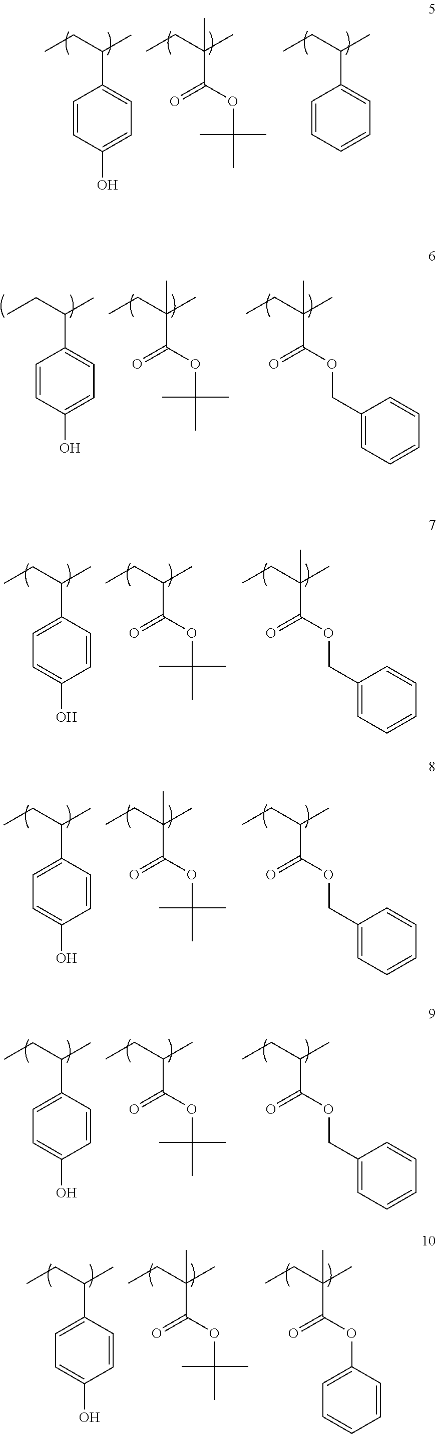

TABLE 2-1

| | | | | Weight Average | |
|---|---|---|---|---|---|
| | Compositional | | | Molecular | Polydispersity |
| Resin | Ratio (mol %) | | | Weight (Mw) | (Mw/Mn) |
| 1 | 60 | 40 | — | 12000 | 1.16 |
| 2 | 70 | 30 | — | 12000 | 1.16 |
| 3 | 80 | 20 | — | 18000 | 1.16 |
| 4 | 65 | 25 | 10 | 18000 | 1.15 |
| 5 | 60 | 30 | 10 | 23000 | 1.51 |
| 6 | 65 | 25 | 10 | 24500 | 1.49 |
| 7 | 65 | 25 | 10 | 23500 | 1.50 |
| 8 | 70 | 20 | 10 | 23000 | 1.51 |
| 9 | 70 | 20 | 10 | 24000 | 1.51 |
| 10 | 65 | 25 | 10 | 23500 | 1.50 |

### [Preparation of Actinic Ray-Sensitive or Radiation-Sensitive Resin Composition]

The resin, the acid generator, the basic compound, the surfactant and the sugar derivative added, if desired, shown in Table 2-2 below were dissolved in a single or mixed solvent of propylene glycol monomethyl ether acetate (hereinafter simply referred to as “PGMEA”), propylene glycol monomethyl ether (hereinafter simply referred to as “PGME”), ethyl lactate (hereinafter simply referred to as “EL”) and ethyl ethoxypropionate (hereinafter simply referred to as “EEP”) to prepare a solution having a solid content concentration of 10.0 mass %, and the obtained solution was microfiltered through a membrane filter having a pore size of 0.1 μm to obtain a positive resist solution (an actinic ray-sensitive or radiation-sensitive resin composition).

The resist solutions used in the evaluation are shown in Table 2-2 below. Here, the amount used (mass %) of each component except for solvents means mass % based on the solid content excluding solvents. As for the solvent, a mixing ratio (mass %) of PGMEA, PGME, EL and EEP is shown.

TABLE 2-2

| | | | | Sugar | | | | | |
|---|---|---|---|---|---|---|---|---|---|
| | | Acid Generator | Basic | Derivative | | Solvent (F) | | | |
| | Resin (A2) | (B) | Compound (C2) | (G) | Surfactant (E) | PGMEA | PGME | EL | EEP |
| | (mass %) | (mass %) | (mass %) | (mass %) | (mass %) | (mass %) | (mass %) | (mass %) | (mass %) |
| Example 2-1 | 1 (97.86) | B-5 (2.0) | C2-1 (0.1) | — | E-2 (0.04) | 80 | 0 | 0 | 20 |
| Example 2-2 | 2 (94.86) | B-2 (2.0) | C2-1 (0.1) | S-38 (3.0) | E-2 (0.04) | 80 | 0 | 0 | 20 |
| Example 2-3 | 6 (97.86) | B-1 (2.0) | C2-1 (0.1) | — | E-1 (0.04) | 80 | 0 | 0 | 20 |
| Example 2-4 | 6 (97.86) | B-3 (2.0) | C2-1 (0.1) | — | E-3 (0.04) | 80 | 0 | 0 | 20 |
| Example 2-5 | 3 (94.86) | B-6 (2.0) | C2-7 (0.1) | S-38 (3.0) | E-2 (0.04) | 80 | 0 | 0 | 20 |
| Example 2-6 | 4 (94.86) | B-4 (2.0) | C2-4 (0.1) | S-38 (3.0) | E-2 (0.04) | 80 | 0 | 0 | 20 |
| Example 2-7 | 6 (97.86) | B-1 (2.0) | C2-1 (0.1) | — | E-4 (0.04) | 80 | 20 | 0 | 0 |
| Example 2-8 | 6 (97.86) | B-1 (2.0) | C2-1 (0.1) | — | E-2 (0.04) | 80 | 0 | 20 | 0 |
| Example 2-9 | 1 (97.86) | B-5/B-1(1/1) | C2-1 (0.1) | — | E-2 (0.04) | 80 | 0 | 0 | 20 |
| | | (2.0) | | | | | | | |
| Example 2-10 | 1 (94.86) | B-5 (2.0) | C2-5 (0.1) | S-38 (3.0) | E-2 (0.04) | 80 | 0 | 0 | 20 |
| Example 2-11 | 1 (97.86) | B-5 (2.0) | C2-15 (0.1) | — | E-2 (0.04) | 80 | 0 | 0 | 20 |
| Example 2-12 | 7 (97.86) | B-1 (2.0) | C2-1 (0.1) | — | E-2 (0.04) | 80 | 0 | 20 | 0 |
| Example 2-13 | 8 (94.86) | B-3 (2.0) | C2-3 (0.1) | S-38 (3.0) | E-1 (0.04) | 80 | 0 | 0 | 20 |
| Example 2-14 | 9 (97.86) | B-5 (2.0) | C2-5 (0.1) | — | E-3 (0.04) | 100 | 0 | 0 | 0 |
| Example 2-15 | 10 (97.86) | B-1 (2.0) | C2-4 (0.1) | — | E-2 (0.04) | 80 | 0 | 0 | 20 |
| Example 2-16 | 1 (48.93) | B-5 (2.0) | C2-1 (0.1) | — | E-2 (0.04) | 80 | 0 | 0 | 20 |
| | 2 (48.93) | | | | | | | | |
| Comparative | 1 (97.86) | B-1 (2.0) | BS-11 (0.1) | — | E-2 (0.04) | 100 | 0 | 0 | 0 |
| Example 2-1 | | | | | | | | | |
| Comparative | 6 (94.86) | B-1 (2.0) | BS-11 (0.1) | S-38 (3.0) | E-2 (0.04) | 100 | 0 | 0 | 0 |
| Example 2-2 | | | | | | | | | |

(Acid Generator)
B-1 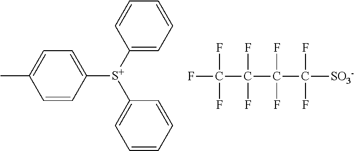
B-2 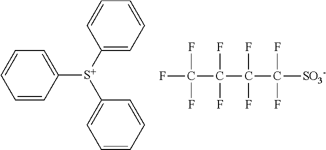
B-3 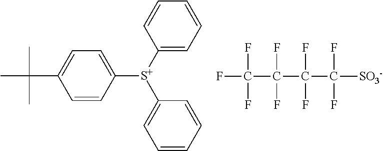
B-4 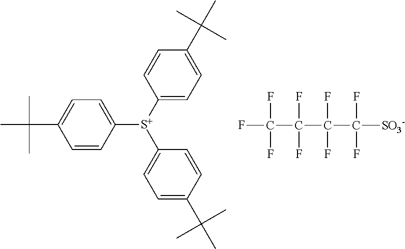
B-5 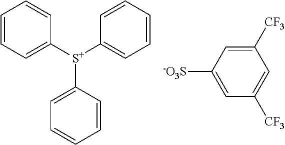
B-6 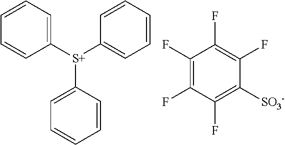
(Basic Compound (C2))
A compound selected from Compounds (C2-1) to (C2-18) was used as the basic compound (C2) for use in the present invention. Also, for comparison, Comparative Compound (BS-11) shown below was used.
(Organic Basic Compound)
BS-11: Dicyclohexylmethylamine
(Sugar Derivative)
A compound selected from Compounds (S-1) to (S-53) was used as the sugar derivative.
(Surfactant)
E-1: PF636 (produced by OMNOVA)
E-2: PF6320 (produced by OMNOVA)
E-3: Megaface F176 (produced by Dainippon Ink & Chemicals, Inc.)
E-4: Florad FC430 (produced by Sumitomo 3M Inc.)

### [Production and Evaluation of Pattern]

The positive resist solution prepared above was uniformly applied on a silicon wafer having provided thereon a 60 nm-thick antireflection layer (DUV32, produced by Brewer Science, Inc.), by using a spin coater, Mark 8, manufactured by Tokyo Electron Ltd. and dried under heating at 130° C. for 60 seconds to form a positive resist film having a thickness of 0.4 μm. This film stack was then exposed through a contact hole pattern mask by using a KrF excimer laser scanner (PAS5500/850C, manufactured by ASML, wavelength: 248 nm) under the exposure conditions of NA=0.68 and σ=0.60. The film after exposure was baked at 140° C. over 60 seconds, dipped in an aqueous 2.38 mass % tetramethylammonium hydroxide (TMAH) solution for 60 seconds, then rinsed with water for 30 seconds and dried to obtain a contact hole pattern with a diameter of 150 nm and a pitch of 300 nm (half pitch: 150 nm). The obtained pattern was evaluated by the following methods. The results are shown in Table 2-3.

### (EDW)

The exposure dose for forming a contact hole pattern with a diameter of 150 nm and a pitch of 300 nm (half pitch: 150 nm) obtained in the same manner as above was taken as an optimal exposure dose. The exposure dose range allowing for a ±10% tolerance on the hole diameter when changing the exposure dose was determined using a scanning electron microscope (SEM) (S-8840, manufactured by Hitachi, Ltd.), and the value obtained by dividing the determined value by the optimal exposure dose was expressed in percentage and taken as the value of exposure latitude (EL). On the other hand, the focus for a contact hole pattern with a diameter of 150 nm and a pitch of 300 nm (half pitch: 150 nm) was taken as an optimal focus, and the focus range allowing for a ±10% tolerance on the hole diameter when changing the focus (defocusing) while keeping the exposure dose at the optimal exposure dose was taken as the defocus latitude (DOF). From the results of the exposure latitude (EL) and the defocus latitude (DOF), the numerical value of EDW was computed using Propata (produced by KLA Tencor Ltd.). As the numerical value is larger, the margin is greater and the performance is higher.

### (Side Wall Verticality)

The cross-sectional profile of a contact hole pattern with a diameter of 150 nm and a pitch of 300 nm (half pitch: 150 nm) obtained in the same manner as above was observed by cross-sectional SEM, and the verticality was rated A when the side surface was rising almost vertically, rated B when slightly tapered, rated C when significantly tapered, and rated D when reversely tapered.

### (Sidelobe Resistance)

The exposure dose for forming a contact hole pattern with a diameter of 150 nm and a pitch of 300 nm (half pitch: 150 nm) was taken as an optimal exposure dose, and the film surface state in the unexposed area around a contact hole at this exposure dose was observed by a scanning electron microscope (S-8840, manufactured by Hitachi, Ltd.).

A value obtained by dividing the exposure dose immediately before a sidelobe was observed when changing the exposure dose from the optimal exposure dose, by the optimal exposure dose was taken as an indicator of sidelobe resistance. A larger value indicates higher sidelobe resistance. Incidentally, a pit-like surface roughness slightly observed between contact holes is a sidelobe exposed due to leakage light and was observed in the overexposed area.

### (Coatability (Wafer In-Plane Uniformity))

The thickness at 30 points in the wafer plane of the obtained resist pattern on a 8-inch silicon wafer was measured by an optical film thickness meter (VM-3110 (manufactured by Dainippon Screen Mfg. Co., Ltd.)). A value obtained by subtracting the average film thickness from a film thickness farthest from the average value was taken as the wafer in-plane uniformity. A smaller numerical value indicates higher uniformity.

### (Number of Blob Defects)

With respect to the obtained contact hole pattern, the film surface state in the unexposed area was measured using a defect inspection apparatus, KLA2360 (trade name), manufactured by KLA Tencor Ltd. in a random mode by setting the pixel size of the defect inspection apparatus to 0.16 μm and the threshold value to 20. Development defects extracted from differences generated by superimposition between a comparative image and the pixel unit were detected, and the number of development defects per unit area (1 cm²) was calculated. At the calculation, SEM observation of defects was performed by SEMVisionG3 (manufactured by Applied Materials Japan, Inc.), and the number of blob defects was determined by visually classifying the defects.

TABLE 2-3

| | | | | | Number of |
|---|---|---|---|---|---|
| | | | | | Blob |
| | | | | | Defects |
| | | Side Wall | Sidelobe | Coatability | (pieces/ |
| | EDW | Verticality | Resistance | (nm) | cm²) |
| Example 2-1 | 0.38 | A | 1.55 | 2 | 2.0 |
| Example 2-2 | 0.38 | A | 1.55 | 3 | 2.0 |
| Example 2-3 | 0.40 | A | 1.60 | 2 | 1.5 |
| Example 2-4 | 0.40 | A | 1.60 | 2 | 1.5 |
| Example 2-5 | 0.38 | A | 1.55 | 2 | 2.0 |
| Example 2-6 | 0.37 | A | 1.55 | 3 | 2.5 |
| Example 2-7 | 0.40 | A | 1.60 | 7 | 1.5 |
| Example 2-8 | 0.40 | A | 1.60 | 8 | 1.5 |
| Example 2-9 | 0.36 | A | 1.50 | 3 | 3.5 |
| Example 2-10 | 0.36 | A | 1.50 | 3 | 3.0 |
| Example 2-11 | 0.35 | A | 1.45 | 2 | 3.5 |
| Example 2-12 | 0.39 | A | 1.60 | 7 | 1.5 |
| Example 2-13 | 0.39 | A | 1.60 | 3 | 1.5 |
| Example 2-14 | 0.38 | A | 1.60 | 9 | 2.0 |
| Example 2-15 | 0.35 | A | 1.60 | 3 | 3.0 |
| Example 2-16 | 0.38 | A | 1.55 | 2 | 2.0 |
| Comparative | 0.22 | D | 1.20 | 13 | 12.5 |
| Example 2-1 | | | | | |
| Comparative | 0.20 | C | 1.15 | 15 | 11.0 |
| Example 2-2 | | | | | |

As apparent from the results shown in Table 2-3, in both of Comparative Examples 2-1 and 2-2 where the basic compound (C2) according to the present invention is not used, the performance is poor in all of EDW, side wall verticality, sidelobe resistance, coatability and number of blob defects.

On the other hand, in Examples 2-1 to 2-16 where the basic compound (C2) according to the present invention is used, the performance is excellent in all of EDW, side wall verticality, sidelobe resistance, coatability and number of blob defects. In particular, it is seen that in Examples 2-1 to 2-6, 2-9 to 2-11, 2-13, 2-15 and 1-16 where a mixed solvent of PGMEA and EEP is used, the coatability is excellent.

Also, it is presumed that by applying the basic compound of the present invention, which is weakly basic, the generated acid effectively uniformly acts in the film compared with a case of using a strongly basic compound, and the acid is not allowed to act unevenly in the vicinity of the film surface, as a result, the sidelobe resistance is improved.

The third invention of the present invention is described in greater detail below by referring to Examples, but the present invention should not be construed as being limited thereto.

### Synthesis Example 3-1

### Synthesis of Resin 6

Resin 6 was synthesized in the same manner as in Synthesis Example 2-1.

### Synthesis Example 3-2

### Synthesis of Resin 10

Resin 10 was synthesized in the same manner as in Synthesis Example 2-2.

Resins shown in Table 3-1 having structures illustrated below were synthesized in the same manner as in Synthesis Examples 3-1 and 3-2 except for changing the monomers used. The compositional ratio, weight average molecular weight and polydispersity of the resin can be appropriately adjusted by the charge ratio of monomers, the charge amount of initiator, the reaction temperature or the like based on the target values. The compositional ratio of the resin determined by ¹H-NMR and ¹³C-NMR, and the weight average molecular weight (Mw) and molecular weight polydispersity (Mw/Mn) determined by GPC similarly to the above, are shown in Table 3-1. The compositional ratio (by mol) is the compositional ratio of repeating units starting from the left in the resin denoted by the symbol in Table 3-1.

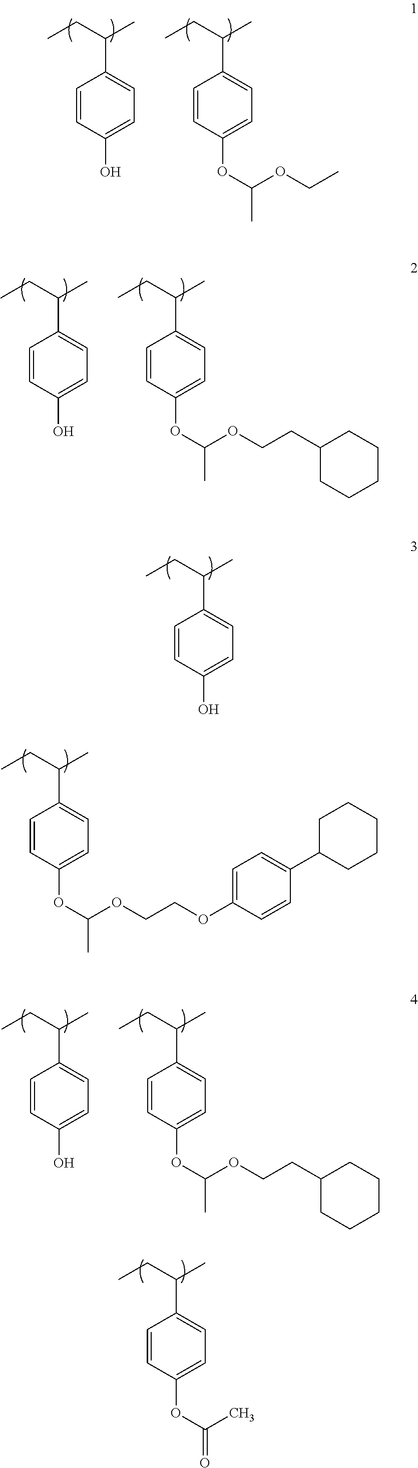

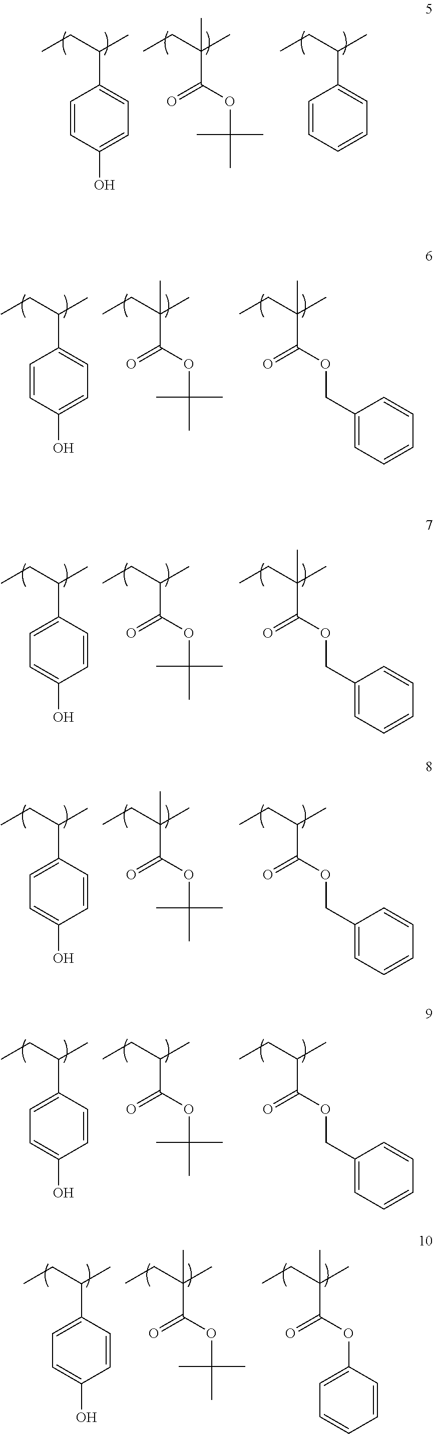

TABLE 3-1

| | | | | Weight Average | |
|---|---|---|---|---|---|
| | Compositional | | | Molecular | Polydispersity |
| Resin | Ratio (mol %) | | | Weight (Mw) | (Mw/Mn) |
| 1 | 60 | 40 | — | 12000 | 1.16 |
| 2 | 70 | 30 | — | 12000 | 1.16 |
| 3 | 80 | 20 | — | 18000 | 1.16 |
| 4 | 65 | 25 | 10 | 18000 | 1.15 |
| 5 | 60 | 30 | 10 | 23000 | 1.51 |
| 6 | 65 | 25 | 10 | 24500 | 1.49 |
| 7 | 65 | 25 | 10 | 23500 | 1.50 |
| 8 | 70 | 20 | 10 | 23000 | 1.51 |
| 9 | 70 | 20 | 10 | 24000 | 1.51 |
| 10 | 65 | 25 | 10 | 23500 | 1.50 |

### [Preparation of Chemical Amplification Resist Composition]

The resin, the acid generator, the basic compound, the sugar derivative and the surfactant shown in Table 3-2 below were dissolved in a single solvent of propylene glycol monomethyl ether acetate (another name: 1-methoxy-2-acetoxypropane, hereinafter simply referred to as “PGMEA”) or a mixed solvent of PGMEA and propylene glycol monomethyl ether (another name: 1-methoxy-2-propanol, hereinafter simply referred to as “PGME”), ethyl lactate (hereinafter simply referred to as “EL”) or ethyl-3-ethoxypropionate (hereinafter simply referred to as “EEP”) to prepare a solution having a solid content concentration of 10.0 mass %, and the obtained solution was microfiltered through a membrane filter having a pore size of 0.1 μm to obtain a positive resist solution (a chemical amplification resist composition).

The resist solutions used in the evaluation are shown in Table 3-2 below. Here, the amount added (mass %) of each component except for solvents means mass % based on the solid content excluding solvents. As for the solvent, a mixing ratio (mass %) of PGMEA, PGME, EL and EEP is shown.

TABLE 3-2

| | | | | Sugar | | | | | |
|---|---|---|---|---|---|---|---|---|---|
| | | Acid | Basic Compound | Derivative | | Solvent (F) | | | |
| | Resin (A3) | Generator (B) | (C3) | (G) | Surfactant (E) | PGMEA | PGME | EL | EEP |
| | (mass %) | (mass %) | (mass %) | (mass %) | (mass %) | (mass %) | (mass %) | (mass %) | (mass %) |
| Example 3-1 | 1 (97.86) | B-5 (2.0) | C3-3 (0.1) | — | E-2 (0.04) | 80 | 0 | 0 | 20 |
| Example 3-2 | 2 (94.86) | B-5 (2.0) | C3-3 (0.1) | S-38 (3.0) | E-2 (0.04) | 80 | 0 | 0 | 20 |
| Example 3-3 | 6 (97.86) | B-1 (2.0) | C3-3 (0.1) | — | E-2 (0.04) | 80 | 0 | 0 | 20 |
| Example 3-4 | 6 (97.86) | B-1 (2.0) | C3-3 (0.1) | — | E-2 (0.04) | 80 | 0 | 0 | 20 |
| Example 3-5 | 3 (94.86) | B-1 (2.0) | C3-1 (0.1) | S-38 (3.0) | E-2 (0.04) | 80 | 0 | 0 | 20 |
| Example 3-6 | 4 (94.86) | B-5 (2.0) | C3-2 (0.1) | S-38 (3.0) | E-2 (0.04) | 80 | 0 | 0 | 20 |
| Example 3-7 | 6 (97.86) | B-1 (2.0) | C3-9 (0.1) | — | E-2 (0.04) | 80 | 20 | 0 | 0 |
| Example 3-8 | 6 (97.86) | B-1 (2.0) | C3-12 (0.1) | — | E-2 (0.04) | 80 | 0 | 20 | 0 |
| Example 3-9 | 6 (97.86) | B-1 (2.0) | C3-16 (0.1) | | E-2 (0.04) | 80 | 0 | 20 | 0 |
| Example 3-10 | 6 (97.86) | B-1 (2.0) | C3-14 (0.1) | — | E-2 (0.04) | 80 | 0 | 20 | 0 |
| Example 3-11 | 6 (97.86) | B-1 (2.0) | C3-16 (0.1) | — | E-2 (0.04) | 80 | 0 | 20 | 0 |
| Example 3-12 | 6 (97.86) | B-5 (2.0) | C3-4 (0.1) | — | E-1 (0.04) | 100 | 0 | 0 | 0 |
| Example 3-13 | 6 (97.86) | B-5 (2.0) | C3-3/BS-11 | — | E-2 (0.04) | 80 | 0 | 0 | 20 |
| | | | (0.07/0.03) | | | | | | |
| Example 3-14 | 6 (97.90) | B-5 (2.0) | C3-4 (0.1) | — | — | 80 | 0 | 0 | 20 |
| Example 3-15 | 6 (97.86) | B-5/B-2 | C3-7 (0.1) | — | E-1 (0.04) | 80 | 0 | 0 | 20 |
| | | (1.0/1.0) | | | | | | | |
| Example 3-16 | 5 (97.86) | B-3 (2.0) | C3-1 (0.1) | — | E-1 (0.04) | 80 | 0 | 20 | 0 |
| Example 3-17 | 5 (97.86) | B-4 (2.0) | C3-3 (0.1) | — | E-1 (0.04) | 80 | 0 | 20 | 0 |
| Example 3-18 | 4 (94.86) | B-3 (2.0) | C3-6 (0.1) | S-38 (3.0) | E-1 (0.04) | 80 | 0 | 20 | 0 |
| Example 3-19 | 1/2 (48.93/48.93) | B-5 (2.0) | C3-3 (0.1) | — | E-2 (0.04) | 80 | 0 | 0 | 20 |
| Example 3-20 | 6 (97.86) | B-7 (2.0) | C3-3 (0.1) | — | E-2 (0.04) | 80 | 0 | 0 | 20 |
| Example 3-21 | 6 (97.86) | B-5 (2.0) | C3-17 (0.1) | — | E-1 (0.04) | 80 | 0 | 0 | 20 |
| Example 3-22 | 6 (97.86) | B-3 (2.0) | C3-18 (0.1) | — | E-2 (0.04) | 80 | 0 | 0 | 20 |
| Example 3-23 | 7 (97.86) | B-4 (2.0) | C3-3 (0.1) | — | E-1 (0.04) | 80 | 0 | 20 | 0 |
| Example 3-24 | 8 (97.86) | B-3 (2.0) | C3-1 (0.1) | — | E-3 (0.04) | 80 | 0 | 20 | 0 |
| Example 3-25 | 9 (97.86) | B-6 (2.0) | C3-12 (0.1) | — | E-1 (0.04) | 80 | 0 | 20 | 0 |
| Example 3-26 | 10 (97.86) | B-5 (2.0) | C3-3 (0.1) | — | E-4 (0.04) | 80 | 0 | 20 | 0 |
| Comparative | 1 (97.86) | B-1 (2.0) | BS-11 (0.1) | — | E-2 (0.04) | 100 | 0 | 0 | 0 |
| Example 3-1 | | | | | | | | | |
| Comparative | 6 (94.86) | B-1 (2.0) | BS-11 (0.1) | S-38 (3.0) | E-2 (0.04) | 100 | 0 | 0 | 0 |
| Example 3-2 | | | | | | | | | |

Abbreviations in Table 3-2 are as follows.
(Acid Generator)
B-1 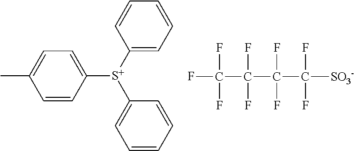
B-2 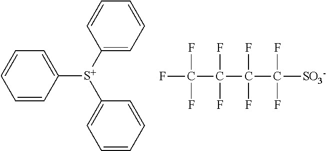
B-3 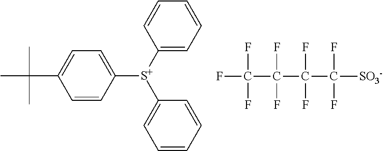
B-4 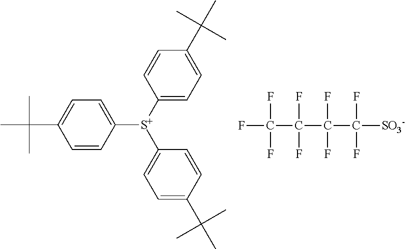
B-5 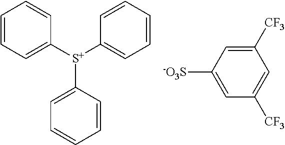
B-6 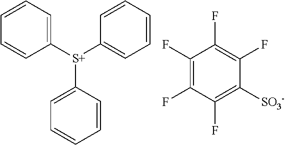
B-7 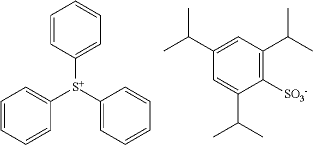
(Basic Compound (C3))
A compound selected from Compounds (C3-1) to (C3-18) was used as the basic compound (C3) for use in the present invention. Also, for comparison, Comparative Compound (BS-11) shown below was used.
BS-11: Dicyclohexylmethylamine
(Sugar Derivative)
A compound selected from Compounds (S-1) to (S-53) was used as the sugar derivative.
(Surfactant)
E-1: PF636 (produced by OMNOVA)
E-2: PF6320 (produced by OMNOVA)
E-3: Megaface F176 (produced by Dainippon Ink & Chemicals, Inc.)
E-4: Florad FC430 (produced by Sumitomo 3M Inc.)

### [Production and Evaluation of Pattern]

The positive resist solution prepared above was uniformly applied on a silicon wafer having provided thereon a 60 nm-thick antireflection layer (DUV42, produced by Brewer Science, Inc.), by using a spin coater, Mark 8, manufactured by Tokyo Electron Ltd. and dried under heating at 130° C. over 60 seconds to form a positive resist film having a thickness of 0.40 μm.

This film stack was then exposed through a contact hole pattern mask (diameter: 150 nm (pitch: 1:1)) by using a KrF excimer laser scanner (PAS5500/850C, manufactured by ASML, wavelength: 248 nm) under the exposure conditions of NA=0.68 and 6=0.60. The resist film after exposure was baked at 140° C. over 60 seconds and the film after baking was dipped in an aqueous 2.38 mass % tetramethylammonium hydroxide (TMAH) solution over 60 seconds. After this development processing, the film was rinsed with pure water for 30 seconds and dried to obtain a contact hole pattern (pitch: 1:1) with a diameter of 150 nm. The obtained pattern was evaluated by the following methods. The results are shown in Table 3-3.

### (EDW)

The exposure dose for forming a contact hole pattern (pitch: 1:1) with a diameter of 150 nm obtained in the same manner as above was taken as an optimal exposure dose. The exposure dose range allowing for a ±10% tolerance on the hole diameter when changing the exposure dose was determined using a scanning electron microscope (SEM) (S-8840, manufactured by Hitachi, Ltd.), and the value obtained by dividing the determined value by the optimal exposure dose was expressed in percentage and taken as the value of exposure latitude (EL). On the other hand, the focus for a contact hole pattern (pitch: 1:1) with a diameter of 150 nm was taken as an optimal focus, and the focus range allowing for a ±10% tolerance on the hole diameter when changing the focus (defocusing) while keeping the exposure dose at the optimal exposure dose was taken as the defocus latitude (DOF). From the results of the exposure latitude (EL) and the defocus latitude (DOF), the numerical value of EDW was computed using Propata (produced by KLA Tencor Ltd.). As the numerical value is larger, the margin is greater and the performance is higher.

### (Side Wall Verticality)

The cross-sectional profile of a contact hole pattern (pitch: 1:1) with a diameter of 150 nm obtained in the same manner as above was observed by cross-sectional SEM, and the verticality was rated A when the side surface was rising almost vertically, rated B when slightly tapered, rated C when significantly tapered, and rated D when reversely tapered.

### (Sidelobe Resistance)

The exposure dose for forming a contact hole pattern (pitch: 1:1) with a diameter of 150 nm was taken as an optimal exposure dose, and the film surface state in the unexposed area around a contact hole at this exposure dose was observed by a scanning electron microscope (S-8840, manufactured by Hitachi, Ltd.).

A value obtained by dividing the exposure dose immediately before a sidelobe was observed when changing the exposure dose from the optimal exposure dose, by the optimal exposure dose was taken as an indicator of sidelobe resistance. A larger value indicates higher sidelobe resistance. Incidentally, a pit-like surface roughness slightly observed between contact holes is a sidelobe exposed due to leakage light and was observed in the overexposed area.

### (Coatability (Wafer In-Plane Uniformity))

The thickness at 30 points in the wafer plane of a contact hole pattern obtained in the same manner as above on a 12-inch silicon wafer was measured by an optical film thickness meter (VM-3110 (manufactured by Dainippon Screen Mfg. Co., Ltd.)). The absolute value of a value obtained by subtracting the average film thickness from a film thickness farthest from the average value was taken as the wafer in-plane uniformity. A smaller numerical value indicates higher uniformity.

(Aging Stability (Number of Particles and Increase in Number of Particles after Aging and Storage)

With respect to the positive resist solution (coating solution) prepared above, the number of particles therein was counted immediately after the preparation of the solution (initial value of particles) and after leaving the solution for one month at 35° C. (number of particles after aging) by using a particle counter manufactured by Rion Co., Ltd. The initial value of particles and the increase in the number of particles calculated by (number of particles after aging)-(initial value of particles) were evaluated. As for the particle, the number of particles having a diameter of 0.25 μm or more in 1 ml of the resist composition solution was counted. As the numerical value is smaller, the positive resist solution is less changed with aging and the aging stability is better.

TABLE 3-3

| | | | | | | Initial |
|---|---|---|---|---|---|---|
| | | | | | Increase | Value |
| | | | | | of | of |
| | | Side | | | Particles | Particles |
| | | Wall | | Coat- | (Δnumber | (number |
| | | Verti- | Sidelobe | ability | of | of |
| | EDW | cality | Resistance | (nm) | particles) | particles) |
| Example 3-1 | 0.39 | A | 1.55 | 2 | 0 | 3 |
| Example 3-2 | 0.38 | A | 1.60 | 2 | 1 | 2 |
| Example 3-3 | 0.41 | A | 1.65 | 2 | 0 | 3 |
| Example 3-4 | 0.41 | A | 1.65 | 2 | 0 | 3 |
| Example 3-5 | 0.38 | A | 1.55 | 2 | 0 | 2 |
| Example 3-6 | 0.37 | A | 1.55 | 2 | 1 | 1 |
| Example 3-7 | 0.42 | A | 1.65 | 11 | 0 | 2 |
| Example 3-8 | 0.41 | A | 1.65 | 6 | 0 | 1 |
| Example 3-9 | 0.41 | A | 1.65 | 6 | 0 | 3 |
| Example | 0.41 | A | 1.65 | 6 | 0 | 2 |
| 3-10 | | | | | | |
| Example | 0.41 | A | 1.65 | 6 | 1 | 3 |
| 3-11 | | | | | | |
| Example | 0.38 | A | 1.65 | 8 | 0 | 2 |
| 3-12 | | | | | | |
| Example | 0.42 | A | 1.65 | 2 | 0 | 3 |
| 3-13 | | | | | | |
| Example | 0.38 | A | 1.65 | 2 | 0 | 3 |
| 3-14 | | | | | | |
| Example | 0.41 | A | 1.65 | 2 | 1 | 2 |
| 3-15 | | | | | | |
| Example | 0.38 | A | 1.55 | 6 | 0 | 1 |
| 3-16 | | | | | | |
| Example | 0.38 | A | 1.60 | 6 | 0 | 3 |
| 3-17 | | | | | | |
| Example | 0.39 | A | 1.60 | 6 | 0 | 2 |
| 3-18 | | | | | | |
| Example | 0.39 | A | 1.55 | 2 | 0 | 3 |
| 3-19 | | | | | | |
| Example | 0.39 | A | 1.65 | 2 | 0 | 3 |
| 3-20 | | | | | | |
| Example | 0.38 | A | 1.55 | 2 | 0 | 3 |
| 3-21 | | | | | | |
| Example | 0.38 | A | 1.55 | 2 | 0 | 3 |
| 3-22 | | | | | | |
| Example | 0.39 | A | 1.65 | 6 | 0 | 3 |
| 3-23 | | | | | | |
| Example | 0.38 | A | 1.65 | 6 | 0 | 3 |
| 3-24 | | | | | | |
| Example | 0.39 | A | 1.65 | 6 | 0 | 3 |
| 3-25 | | | | | | |
| Example | 0.39 | A | 1.65 | 6 | 0 | 2 |
| 3-26 | | | | | | |
| Comparative | 0.22 | D | 1.20 | 17 | 19 | 11 |
| Example 3-1 | | | | | | |
| Comparative | 0.20 | C | 1.15 | 19 | 17 | 13 |
| Example 3-2 | | | | | | |

As apparent from the results shown in Table 3-3, in Comparative Examples where the basic compound (C3) according to the present invention is not used, the performance is poor in all of EDW, side wall verticality, sidelobe resistance and aging stability compared with Examples where the basic compound (C3) according to the present invention is used. The basic compound represented by formula (3-IV) of the present invention is weakly basic, and it is presumed that the cohesive force of the compound itself or with a polymer or the like is weak and therefore, the aging stability is improved (that is, the increase of particles in the resist solution after aging and storage is significantly reduced). Also, thanks to weak basicity, diffusion of the generated acid is promoted and this is expected to lead to improvement of side wall verticality and enlargement of EDW at the formation of a contact hole pattern. Furthermore, it is considered that by applying the basic compound of the present invention, which is weakly basic, the generated acid effectively uniformly acts in the film compared with a case of using a strongly basic compound, and the acid is not allowed to act unevenly in the vicinity of the film surface, as a result, the sidelobe resistance is improved. It is also seen that in Examples 3-1 to 3-6, 3-13 to 3-15 and 3-19 to 3-22 where a mixed solvent of PGMEA and EEP is used, the coatability is excellent.

According to the first invention, an actinic ray-sensitive or radiation-sensitive resin composition containing a specific acid-decomposable resin and a specific basic compound, thereby ensuring that at the formation of a contact hole pattern, the side wall verticality is improved, the EDW is widened, the sidelobe resistance is enhanced, and the number of blob defects is reduced, and a resist film and a pattern forming method each using the composition, can be provided. Also, an actinic ray-sensitive or radiation-sensitive resin composition improved in the coatability by appropriately selecting the solvent in the composition can be provided. The actinic ray-sensitive or radiation-sensitive resin composition of the first invention of the present invention is suitable as a positive resist composition.

According to the second invention, an actinic ray-sensitive or radiation-sensitive resin composition containing an acid-decomposable resin and a specific basic compound, thereby ensuring that at the formation of a contact hole pattern, the side wall verticality is improved, a wide EDW is secured, the sidelobe resistance is increased, and the number of blob defects is reduced, and a resist film and a pattern forming method each using the composition, can be provided. Also, an actinic ray-sensitive or radiation-sensitive resin composition improved in the coatability by appropriately selecting the solvent in the composition can be provided. The actinic ray-sensitive or radiation-sensitive resin composition of the second invention of the present invention is suitable as a positive resist composition.

According to the third invention, a chemical amplification resist composition containing a benzimidazole-based basic compound having a sulfur atom-containing specific structure, thereby ensuring that at the formation of a contact hole pattern, the side wall verticality of pattern is improved, the EDW is widened, the sidelobe resistance is enhanced, and the increase of particles in the resist solution after aging and storage is remarkably reduced, and a resist film and a pattern forming method each using the composition, can be provided. Also, a chemical amplification resist composition improved in the coatability by appropriately selecting the solvent in the composition can be provided. The chemical amplification resist composition of the third invention of the present invention is suitable as a positive chemical amplification resist composition.

This application is based on Japanese patent applications JP 2010-104567, filed on Apr. 28, 2010, JP 2010-138513, filed on Jun. 17, 2010, and JP 2010-138514, filed on Jun. 17, 2010, the entire contents of which are hereby incorporated by reference, the same as if set forth at length.

What is claimed is:

1. An actinic ray-sensitive or radiation-sensitive resin composition, comprising:
(A1) a resin capable of increasing a solubility of the resin (A1) for an alkali developer by an action of an acid, the resin containing a repeating unit represented by the following formula (1-I), a repeating unit represented by the following formula (1-II) and a repeating unit represented by the following formula (1-III);
(B) a compound capable of generating an acid upon irradiation with an actinic ray or radiation; and
(C1) a basic compound represented by the following formula (1-IV): 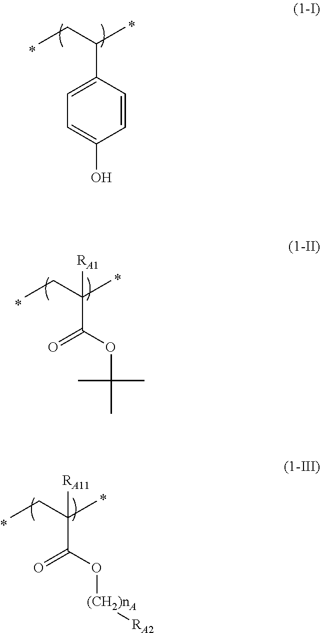
wherein each of R_{A1} and R_{A11} independently represents a hydrogen atom or a methyl group;
R_{A2} represents a phenyl group or a cyclohexyl group; and
n_{A} represents an integer of 0 to 2: 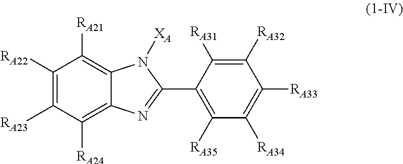
wherein each of R_{A21}, R_{A22}, R_{A23}, R_{A24}, R_{A31}, R_{A32}, R_{A33}, R_{A34} and R_{A35} independently represents a hydrogen atom, an alkyl group, an alkoxy group or an aralkyl group; and
X_{A} represents a hydrogen atom, an alkyl group, an aryl group or an aralkyl group.

2. The actinic ray-sensitive or radiation-sensitive resin composition according to claim 1,
wherein the contents of the repeating unit represented by formula (1-I), the repeating unit represented by formula (1-II) and the repeating unit represented by formula (1-III) in the resin (A1) are from 30 to 80 mol %, from 15 to 50 mol % and from 5 to 20 mol %, respectively, based on all repeating units in the resin (A1) and a total content of the repeating units represented by formulae (1-I) to (1-III) in the resin (A1) is 100 mol % based on all repeating units in the resin (A1).

3. The actinic ray-sensitive or radiation-sensitive resin composition according to claim 1, further comprising:
(G) a sugar derivative capable of decomposing by an action of an acid to generate an alcoholic hydroxyl group.

4. The actinic ray-sensitive or radiation-sensitive resin composition according to claim 1,
wherein in formula (1-IV), X_{A} is a hydrogen atom.

5. The actinic ray-sensitive or radiation-sensitive resin composition according to claim 1,
wherein in formula (1-IV), each of R_{A21}, R_{A22}, R_{A23}, R_{A24}, R_{A31}, R_{A32}, R_{A33}, R_{A34} and R_{A35} independently represents a hydrogen atom or an alkyl group.

6. The actinic ray-sensitive or radiation-sensitive resin composition according to claim 1, further comprising:
a mixed solvent of an alkylene glycol monoalkyl ether carboxylate and an alkyl alkoxy carboxylate.

7. The actinic ray-sensitive or radiation-sensitive resin composition according to claim 6,
wherein the mixed solvent is a mixed solvent of a propylene glycol monoalkyl ether carboxylate and an alkyl alkoxy propionate.

8. The actinic ray-sensitive or radiation-sensitive resin composition according to claim 1, which is used for exposure to KrF excimer laser, electron beam, X-ray or extremely-ultraviolet ray.

9. A resist film, which is formed of the actinic ray-sensitive or radiation-sensitive resin composition according to claim 1.

10. A pattern forming method, comprising:
exposing and developing the resist film according to claim 9.

11. An actinic ray-sensitive or radiation-sensitive resin composition, comprising:
(A2) a resin capable of increasing a solubility of the resin (A2) for an alkali developer by an action of an acid;
(B) a compound capable of generating an acid upon irradiation with an actinic ray or radiation; and
(C2) a basic compound represented by the following formula (2-IV): 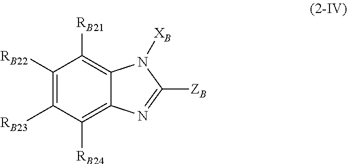
wherein each of R_{B21}, R_{B22}, R_{B23} and R_{B24} independently represents a hydrogen atom, an alkyl group, an alkoxy group or an aralkyl group;
X_{B} represents a hydrogen atom, an alkyl group or an aryl group; and
Z_{B} represents a heterocyclic group.

12. The actinic ray-sensitive or radiation-sensitive resin composition according to claim 11,
wherein the resin (A2) contains a repeating unit stable to an acid, represented by the following formula (V): 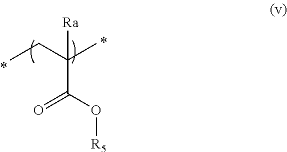
wherein R₅ represents a non-acid-decomposable hydrocarbon group; and
Ra represents a hydrogen atom, an alkyl group or a —CH₂—O—Ra₂ group, wherein Ra₂ represents a hydrogen atom or an alkyl group.

13. The actinic ray-sensitive or radiation-sensitive resin composition according to claim 11,
wherein the resin (A2) contains a repeating unit represented by the following formula (2I), a repeating unit represented by the following formula (2-II) and a repeating unit represented by the following formula (2-III): 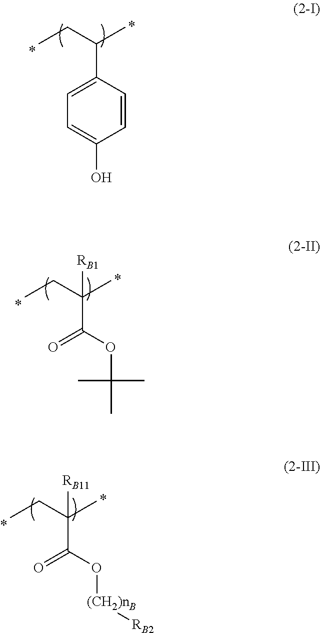
wherein each of R_{B1} and R_{B11} independently represents a hydrogen atom or a methyl group which may have a substituent;
R_{B2} represents a phenyl group which may have a substituent, or a cyclohexyl group which may have a substituent; and
n_{B} represents an integer of 0 to 2.

14. The actinic ray-sensitive or radiation-sensitive resin composition according to claim 13,
wherein the contents of the repeating unit represented by formula (2-I), the repeating unit represented by formula (2-II) and the repeating unit represented by formula (2-III) are from 45 to 80 mol %, from 15 to 50 mol % and from 5 to 20 mol %, respectively, based on all repeating units in the resin (A2).

15. The actinic ray-sensitive or radiation-sensitive resin composition according to claim 11,
wherein the heterocyclic group represented by Z_{B} in formula (2-IV) is a 5- or 6-membered nitrogen-containing heterocyclic ring.

16. The actinic ray-sensitive or radiation-sensitive resin composition according to claim 11, further comprising:
(G) a sugar derivative capable of decomposing by an action of an acid to generate an alcoholic hydroxyl group.

17. The actinic ray-sensitive or radiation-sensitive resin composition according to claim 11, further comprising:
a mixed solvent of an alkylene glycol monoalkyl ether carboxylate and an alkyl alkoxy carboxylate.

18. The actinic ray-sensitive or radiation-sensitive resin composition according to claim 11, which is used for exposure to KrF excimer laser light, electron beam, X-ray or high-energy ray at a wavelength of 50 nm or less.

19. A resist film, which is formed using the actinic ray-sensitive or radiation-sensitive resin composition according to claim 11.

20. A pattern forming method, comprising:
exposing the resist film according to claim 19, so as to form an exposed film; and
developing the exposed film.

21. A chemical amplification resist composition, comprising:
(A3) a resin capable of increasing a solubility of the resin (A3) for an alkali developer by an action of an acid;
(B) a compound capable of generating an acid upon irradiation with an actinic ray or radiation; and
(C3) a basic compound represented by the following formula (3-IV): 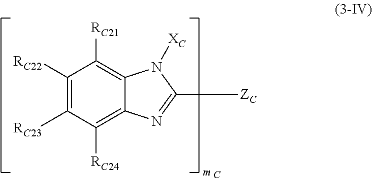
wherein each of R_{C21}, R_{C22}, R_{C23} and R_{C24} independently represents a hydrogen atom, an alkyl group, a cycloalkyl group, an alkoxy group or an aralkyl group, and when a plurality of R_{C21}'s, R_{C22}'s, R_{C23}'s or R_{C24}'s are present, each R_{C21}, R_{C22}, R_{C23} or R_{C24} may be the same as or different from every other R_{C21}, R_{C22}, R_{C23} or R_{C24};
X_{C} represents a hydrogen atom, an alkyl group, an aryl group or an aralkyl group, and when a plurality of X_{C}'s are present, each X_{C} may be the same as or different from every other X_{C};
m_{C} represents 1 or 2; and
Z_{C} represents a mercapto group when m_{C} is 1, and represents a sulfide group or a disulfide group when m_{C} is 2.

22. The chemical amplification resist composition according to claim 21,
wherein the resin (A3) contains a repeating unit stable to an acid, represented by the following formula (V): 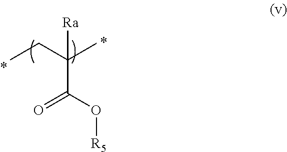
wherein R₅ represents a non-acid-decomposable hydrocarbon group;
Ra represents a hydrogen atom, an alkyl group or a —CH₂—O—Ra₂ group; and
Ra₂ represents a hydrogen atom or an alkyl group.

23. The chemical amplification resist composition according to claim 21,
wherein the resin (A3) contains a repeating unit represented by the following formula (3-I), a repeating unit represented by the following formula (3-II) and a repeating unit represented by the following formula (3-III): 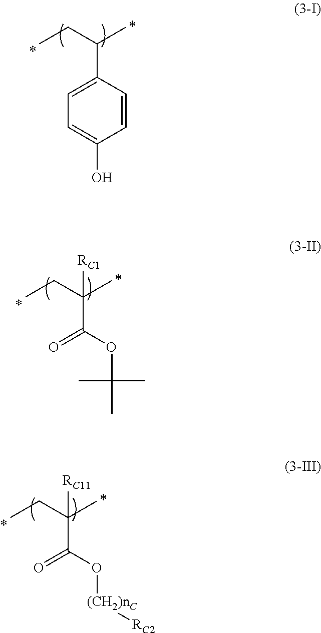
wherein each of R_{C1} and R_{C11} independently represents a hydrogen atom or a methyl group which may have a substituent;
R_{C2} represents a phenyl group which may have a substituent, or a cyclohexyl group which may have a substituent; and
n_{C} represents an integer of 0 to 2.

24. The chemical amplification resist composition according to claim 23,
wherein the contents of the repeating unit represented by formula (3-I), the repeating unit represented by formula (3-II) and the repeating unit represented by formula (3-III) in the resin (A3) are from 45 to 80 mol %, from 15 to 50 mol % and from 5 to 20 mol %, respectively, based on all repeating units in the resin (A3).

25. The chemical amplification resist composition according to claim 21, further comprising:
(G) a sugar derivative capable of decomposing by an action of an acid to generate an alcoholic hydroxyl group.

26. The chemical amplification resist composition according to claim 21,
wherein in formula (34V), X_{C} represents a hydrogen atom, an alkyl group or an aryl group.

27. The chemical amplification resist composition according to claim 21,
wherein in formula (3-IV), each of R_{C21}, R_{C22}, R_{C23} and R_{C24} is a hydrogen atom.

28. The chemical amplification resist composition according to claim 23,
wherein a total content of the repeating units represented by formulae (3-I) to (3-III) in the resin (A3) is 100 mol % based on all repeating units in the resin (A3).

29. The chemical amplification resist composition according to claim 21, further comprising:
a mixed solvent of an alkylene glycol monoalkyl ether carboxylate and an alkyl alkoxy carboxylate.

30. The chemical amplification resist composition according to claim 29,
wherein the mixed solvent is a mixed solvent of a propylene glycol monoalkyl ether carboxylate and an alkyl alkoxy propionate.

31. The chemical amplification resist composition according to claim 21, which is used for exposure to KrF excimer laser ray, electron beam, X-ray or high-energy ray at a wavelength of 50 nm or less.

32. A resist film, which is formed of the chemical amplification resist composition according to claim 21.

33. A pattern forming method, comprising:
exposing and developing the resist film according to claim 32.
